(19) United States
(12) Patent Application Publication
(10) Pub. No.: US 2017/0194578 A1
(43) Pub. Date: Jul. 6, 2017

(54) PLATINUM COMPLEX AND OLED USING THE SAME

(71) Applicant: National Tsing Hua University, Hsinchu City (TW)

(72) Inventors: Yun Chi, Hsinchu City (TW); Kiet Tuong Ly, Hsinchu City (TW)

(21) Appl. No.: 15/160,747

(22) Filed: May 20, 2016

(30) Foreign Application Priority Data
Dec. 31, 2015 (TW) 104144573

(51) Int. Cl. H01L 51/00; C07F 15/00; C09K 11/06

(52) U.S. Cl. CPC H01L 51/0087; C09K 11/06; C07F 15/0093; C09K 2211/185; C09K 2211/1044; C09K 2211/1007

(57) ABSTRACT

A platinum complex represented by general formula (I) or general formula (II) and an organic light-emitting diode using the same are provided.

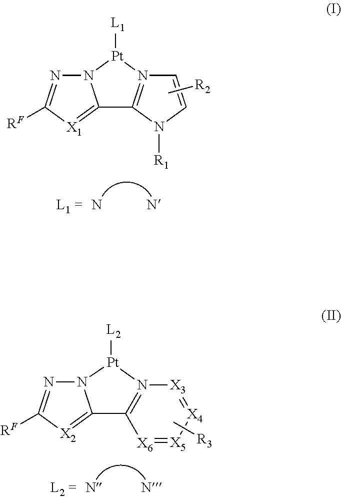

In general formulae (I) and (II), L₁ and L₂ are nitrogen-containing heterocyclic bidentate ligands; R₁ is a substituted or unsubstituted C₁-C₁₂ alkyl group, or a substituted or unsubstituted C₆-C₁₂ aryl group; R₂ is hydrogen, halogen, a substituted or unsubstituted C₁-C₁₂ alkyl group, or a substituted or unsubstituted C₆-C₁₂ aryl group; R₃ is hydrogen, a substituted or unsubstituted C₁-C₁₂ alkyl group, or a substituted or unsubstituted C₆-C₁₂ aryl group; R^{F} is —CₘF₂ₘ₊₁, m is an integer of 1 to 3; X₁ to X₆ are independently carbon or nitrogen; provided that when X₆ is nitrogen and X₃, X₄, and X₅ are carbon, R₃ is not hydrogen.

### CROSS-REFERENCE TO RELATED APPLICATION

This application claims the priority benefit of Taiwan application serial no. 104144573, filed on Dec. 31, 2015. The entirety of the above-mentioned patent application is hereby incorporated by reference herein and made a part of this specification.

### BACKGROUND OF THE INVENTION

Field of the Invention

The invention relates to a platinum complex and an organic light-emitting diode (OLED) using the same, and more particularly, to a platinum complex having a nitrogen-containing heterocyclic bidentate ligand structure and an OLED using the same.

Description of Related Art

The organic-light emitting diode (OLED) device has received much attention in the display industry, in particular the flat panel display industry since the OLED device can be operated under low driving voltage and can generate high luminous efficiency, and the range of light emission covers the visible light region and the near infra-red light region.

To develop a flat panel display having full color, the development of a stable color light-emitting material having high luminous efficiency is the main object of current OLED research. The current tetracoordinated platinum complex has good light emission properties, the device efficiency can reach 39%, and the color thereof is orange-red. Therefore, the development of a novel light-emitting material of different colors and having high luminous efficiency is an important current object.

### SUMMARY OF THE INVENTION

The invention provides a platinum complex. The luminous efficiency of an organic light-emitting diode (OLED) can be effectively increased when the platinum complex is used in the light-emitting layer of the OLED.

The invention provides an OLED using the platinum complex.

The invention provides a platinum complex represented by general formula (I) or (II) below:

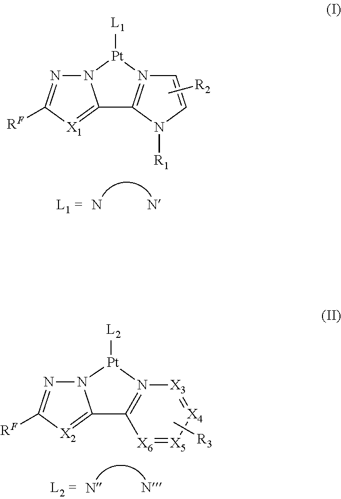

wherein L₁ and L₂ are nitrogen-containing heterocyclic bidentate ligands;
R₁ is a substituted or unsubstituted C₁-C₁₂ alkyl group, or a substituted or unsubstituted C₆-C₁₂ aryl group;
R₂ is hydrogen, halogen, a substituted or unsubstituted C₁-C₁₂ alkyl group, or a substituted or unsubstituted C₆-C₁₂ aryl group;
R₃ is hydrogen, a substituted or unsubstituted C₁-C₁₂ alkyl group, or a substituted or unsubstituted C₆-C₁₂ aryl group;
R^{F} is —CₘF₂ₘ₊₁, m is an integer of 1 to 3; and
X₁ to X₆ are independently carbon or nitrogen, provided that when X₆ is nitrogen and X₃, X₄, and X₅ are carbon, R₃ is not hydrogen.

The invention provides an OLED including two electrodes and a light-emitting layer disposed between the two electrodes, wherein the light-emitting layer contains the platinum complex.

In the platinum complex of the invention, the nitrogen-containing heterocyclic bidentate ligand having a specific structure can maintain strong nitrogen-platinum bonding and adjust the transition energy levels, and has enhanced emission quantum yields and significantly shortened phosphorescence emission lifetime. As a result, blue, green, to red light emitting materials having high luminous efficiency can be obtained, and the range can even be extended to a near infra-red region. Moreover, the platinum complex of this invention can be used in the light-emitting layer of an OLED to increase the external quantum efficiency and the radiance of the OLED.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a phosphorescence spectrum of the platinum complexes synthesized in examples 1 to 3 of the invention.

FIG. 2 shows a phosphorescence spectrum of the platinum complexes synthesized in examples 4 and 6 of the invention.

FIG. 3 shows a phosphorescence spectrum of the platinum complexes synthesized in examples 7 to 11 of the invention.

FIG. 4 shows a phosphorescence spectrum of the platinum complexes synthesized in examples 12 to 14 of the invention.

FIG. 5 is a cross-sectional schematic of an organic light-emitting diode according to an example of the invention.

FIG. 6 shows a current density-external quantum efficiency curve of the organic light-emitting diodes of experimental example 15 and experimental example 16.

FIG. 7 shows a voltage-radiation curve of the organic light-emitting diodes of experimental example 15 and experimental example 16.

### DESCRIPTION OF THE EMBODIMENTS

In the following, examples are provided to further describe the invention, but the examples are only exemplary and are not intended to limit the scope of the invention.

### [Structure of Platinum Complex of the Invention]

The structure of the platinum complex according to an example of the invention can be as shown in general formula (I) or general formula (II) below:

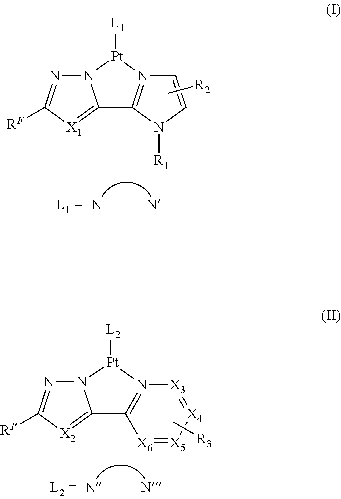

In particular, L₁ and L₂ are nitrogen-containing heterocyclic bidentate ligands. R₁ is a substituted or unsubstituted C₁-C₂ alkyl group, or a substituted or unsubstituted C₆-C₁₂ aryl group. R₂ is hydrogen, halogen, a substituted or unsubstituted C₁-C₁₂ alkyl group, or a substituted or unsubstituted C₆-C₁₂ aryl group. R₃ is hydrogen, a substituted or unsubstituted C₁-C₁₂ alkyl group, or a substituted or unsubstituted C₆-C₁₂ aryl group. R^{F} is —CₘF₂ₘ₊₁, m is an integer of 1 to 3. X₁ to X₆ are independently carbon or nitrogen, provided that when X₆ is nitrogen and X₃, X₄, and X₅ are carbon, R₃ is not hydrogen.

Moreover, the nitrogen-containing heterocyclic bidentate ligand in the platinum complex structure represented by general formula (I) is, for instance, obtained by removing the N—H proton of the nitrogen-containing heterocyclic compound (1′) below and can be represented by general formula (1) below.

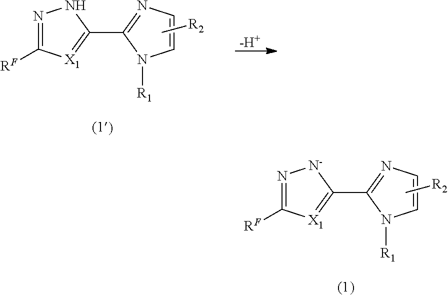

The nitrogen-containing heterocyclic bidentate ligand in the platinum complex structure represented by general formula (II) is, for instance, obtained by removing the N—H proton of the nitrogen-containing heterocyclic compound (2′) below and can be represented by general formula (2) below.

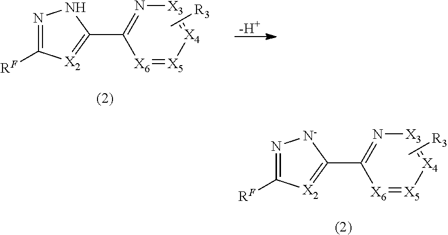

In an example of the invention, at most one in X₃ to X₆ is nitrogen.

In an example of the invention, L₁ can be a first nitrogen-containing heterocyclic bidentate ligand containing two five-membered rings or a second nitrogen-containing heterocyclic bidentate ligand containing one five-membered ring and one six-membered ring.

In an example of the invention, when L₁ is the first nitrogen-containing heterocyclic bidentate ligand containing two five-membered rings and X₁ is carbon, actual examples of the platinum complex satisfying general formula (I) include: the platinum complex represented by either one of formulas (I-1) to (I-9), hereinafter compound (I-1), (I-2) . . . . The abbreviation also applies to platinum complexes represented by other chemical structures in the following.

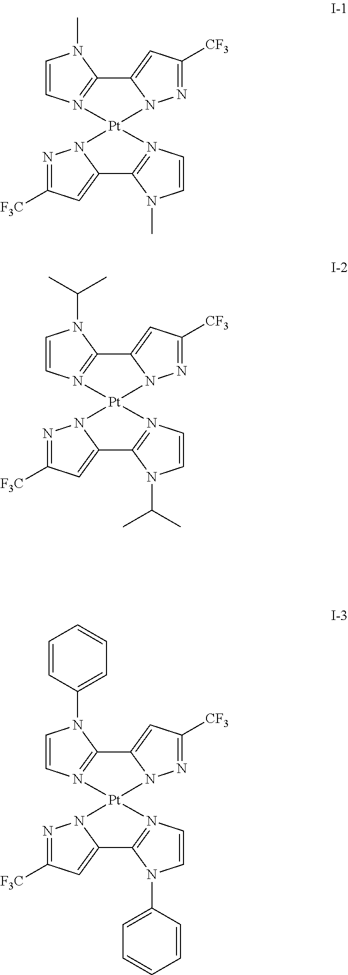

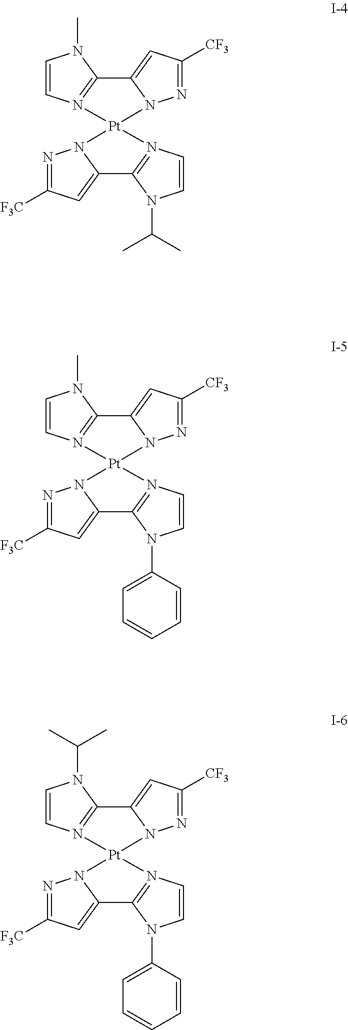

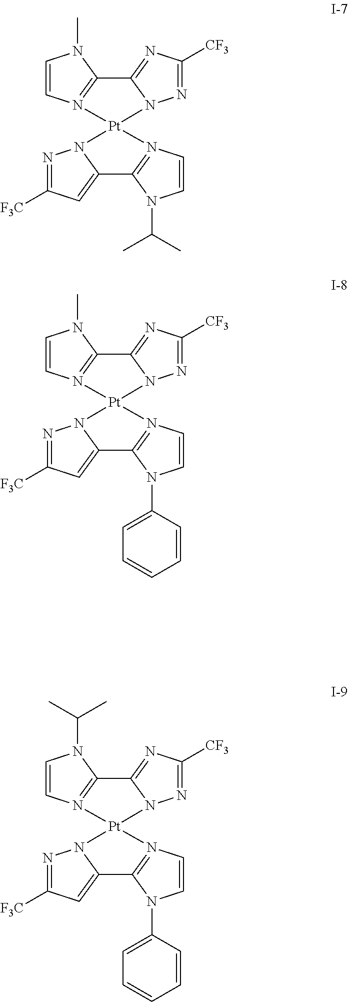

In another example of the invention, when L₁ is the first nitrogen-containing heterocyclic bidentate ligand containing two five-membered rings and X₁ is nitrogen, actual examples of the platinum complex satisfying general formula (I) include: the platinum complex represented by either one of formulas (I-10) to (I-21).

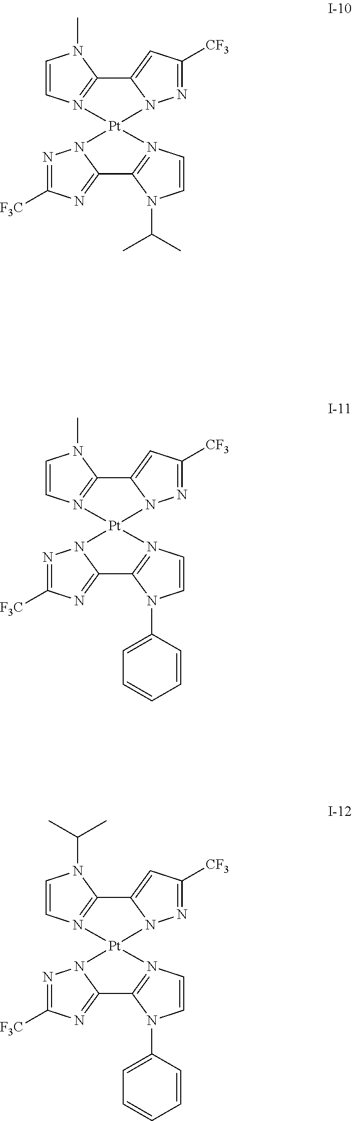

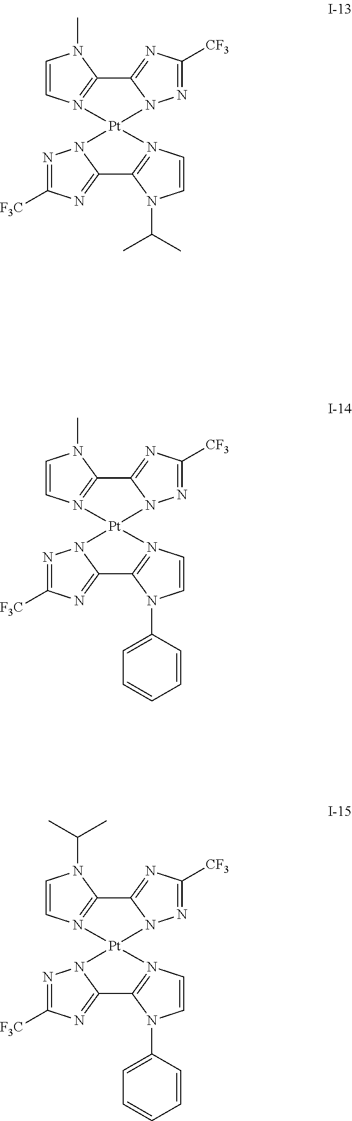

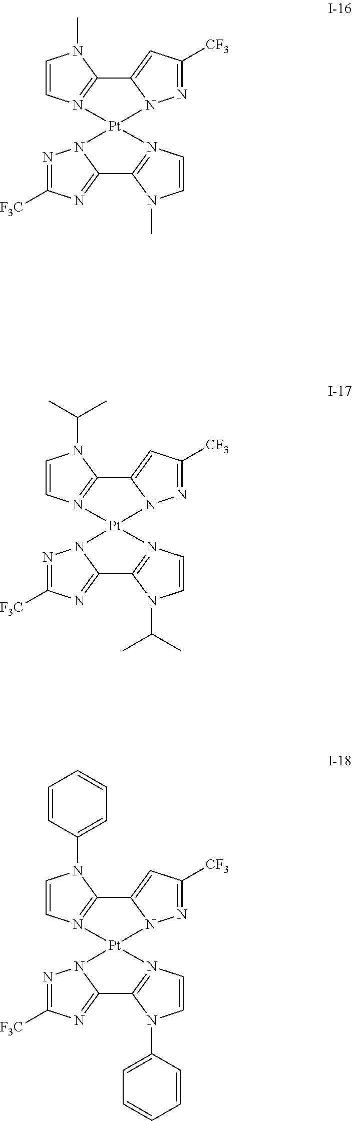

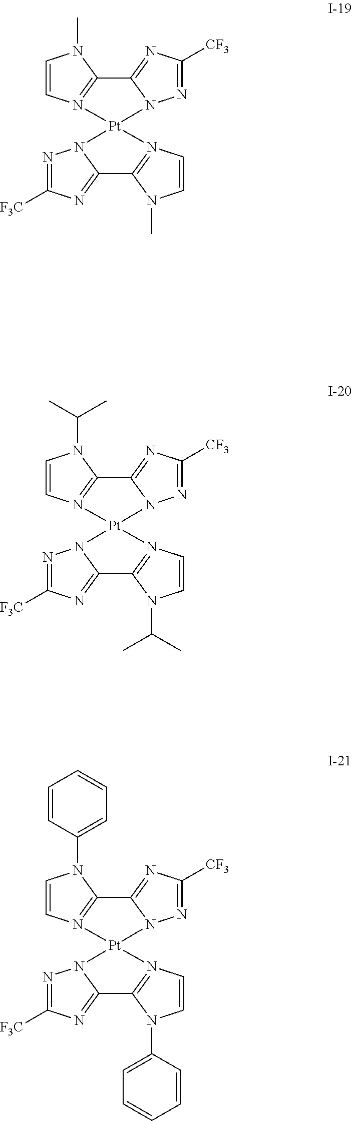

In an example of the invention, when L₁ is the second nitrogen-containing heterocyclic bidentate ligand containing one five-membered ring and one six-membered ring and X₁ is carbon, actual examples of the platinum complex satisfying general formula (I) include: the platinum complex represented by either one of formulas (I-22) to (I-75).

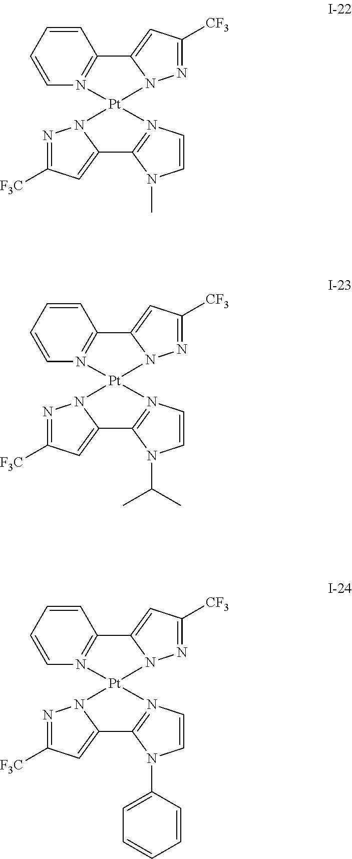

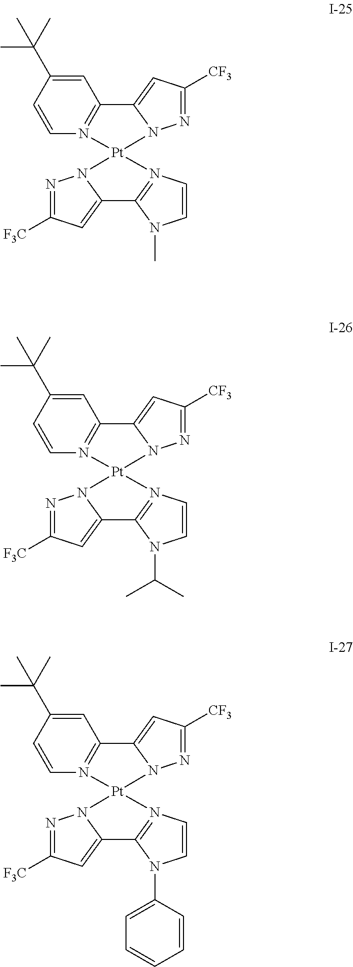

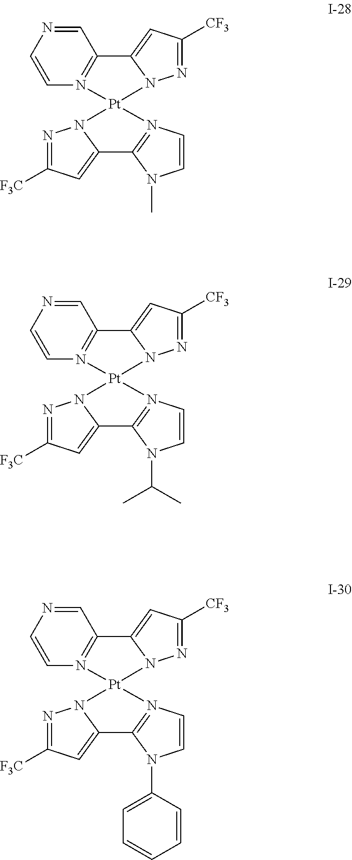

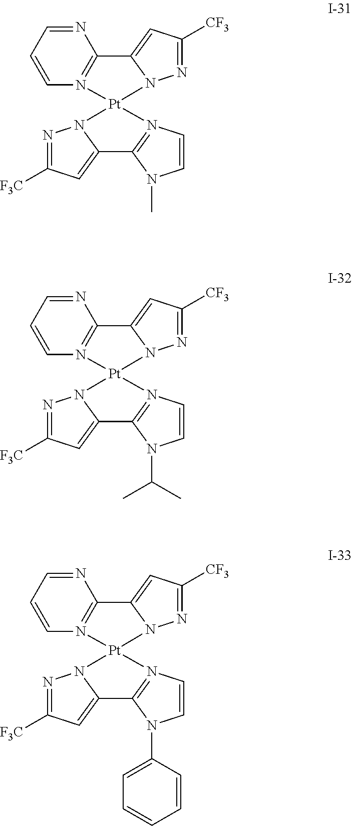

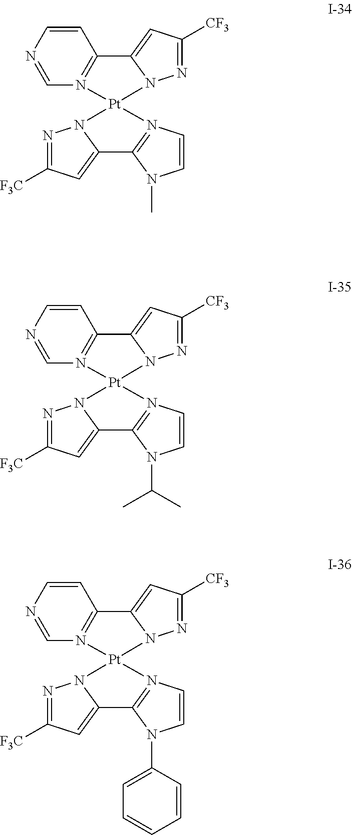

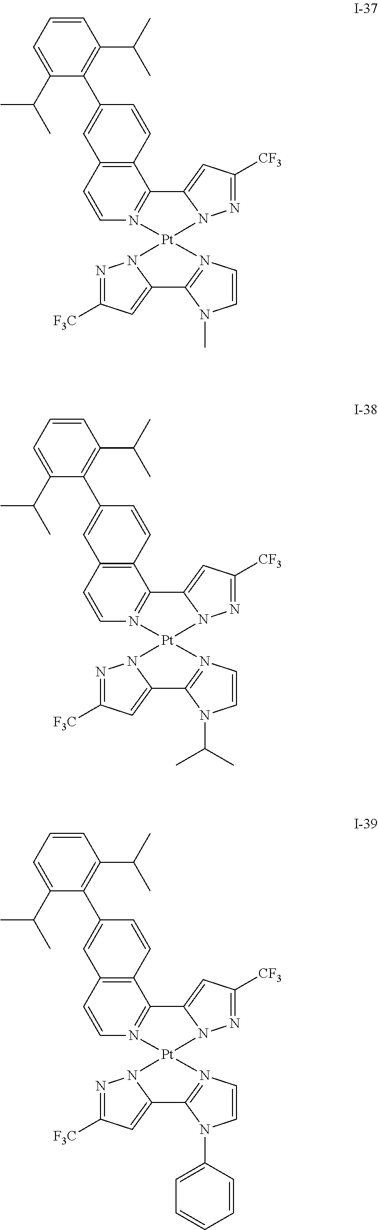

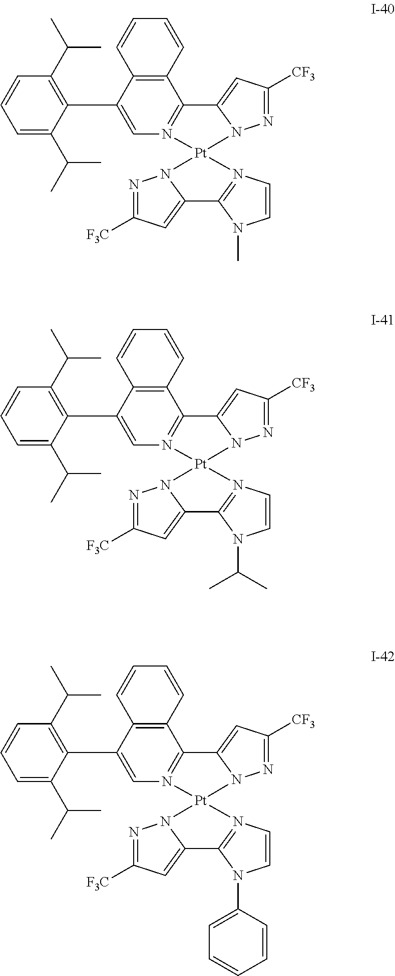

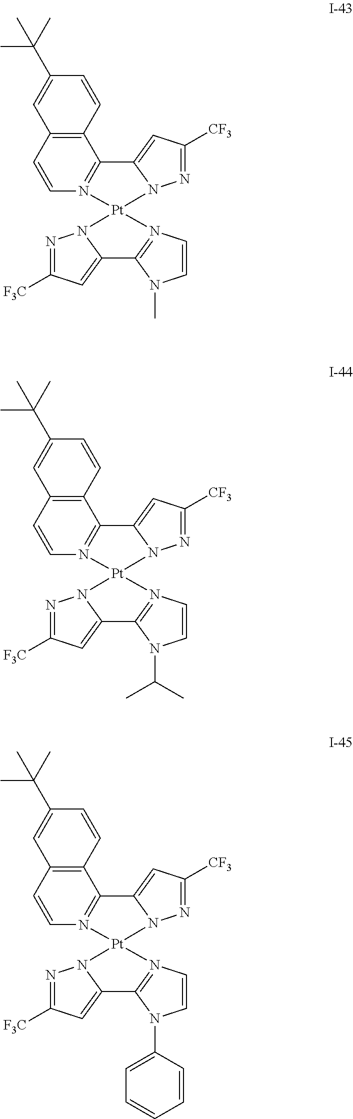

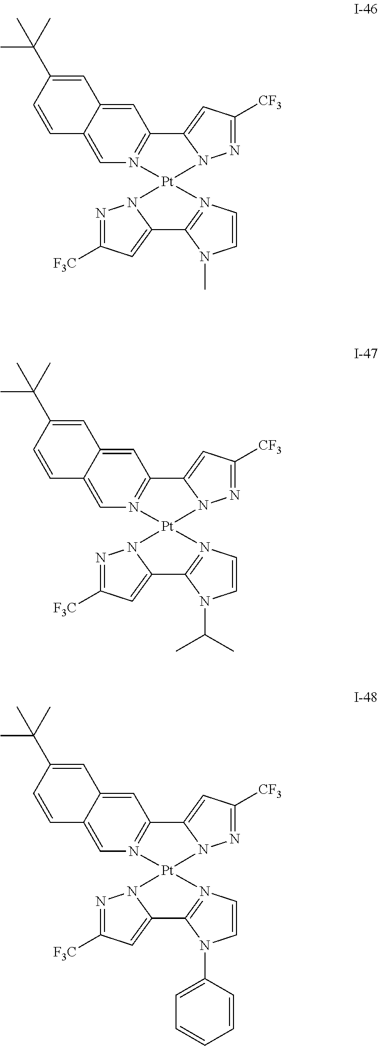

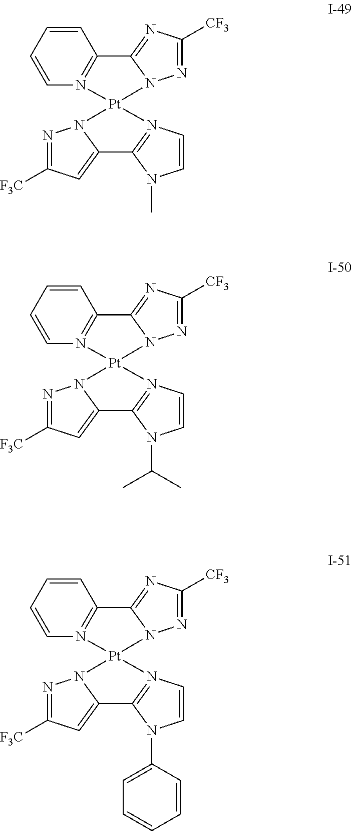

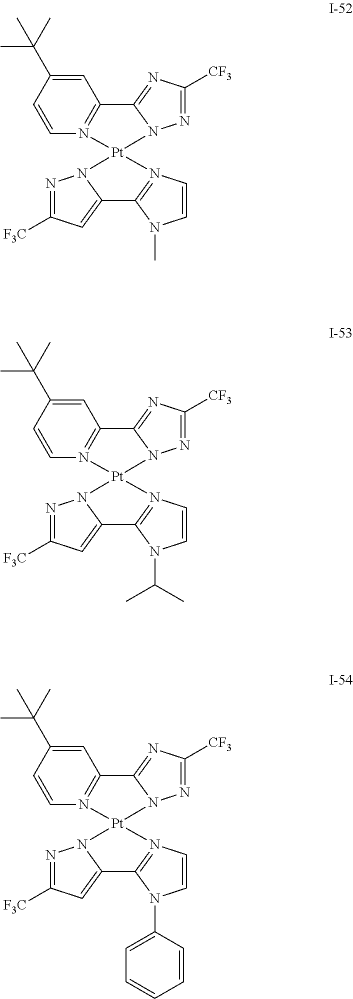

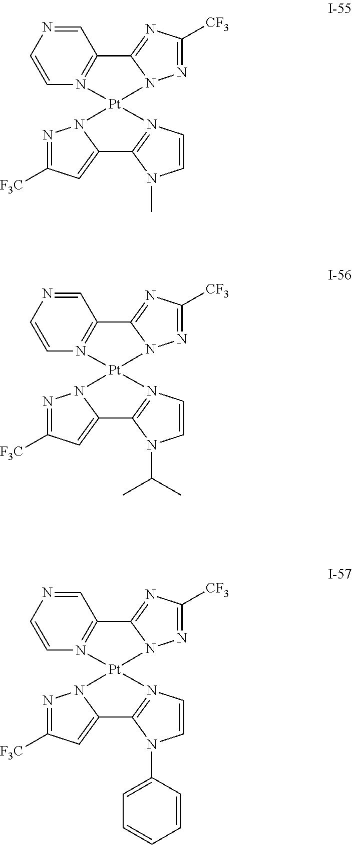

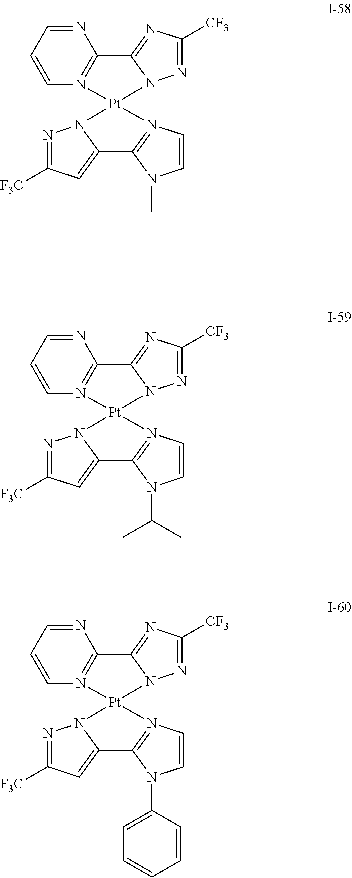

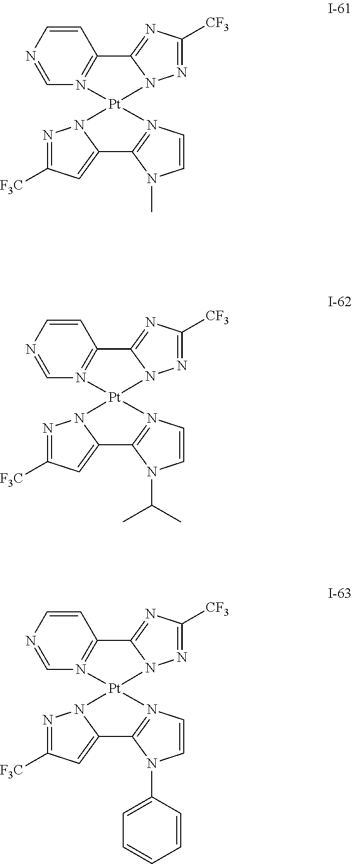

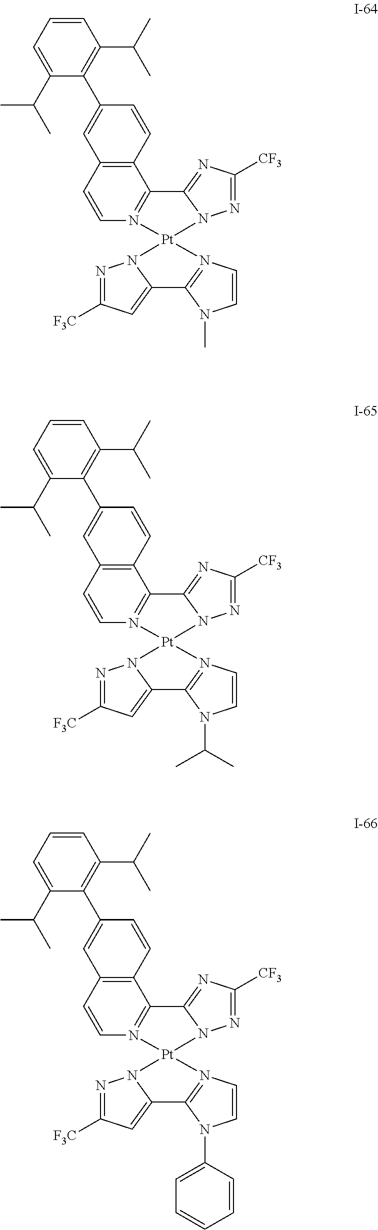

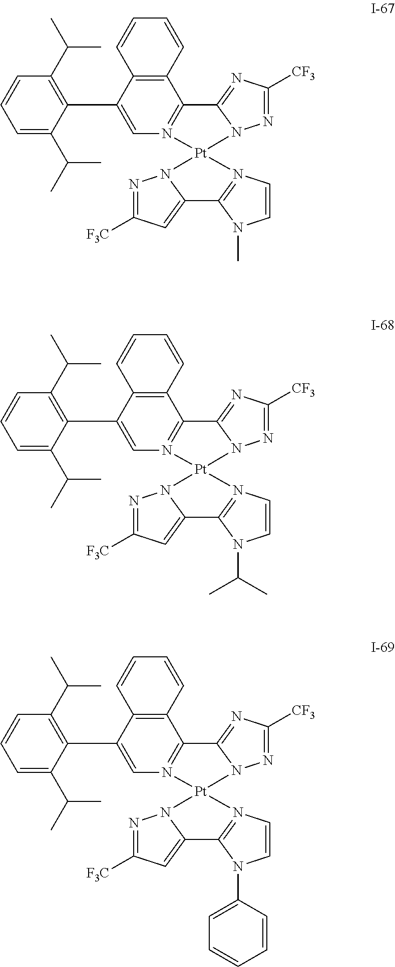

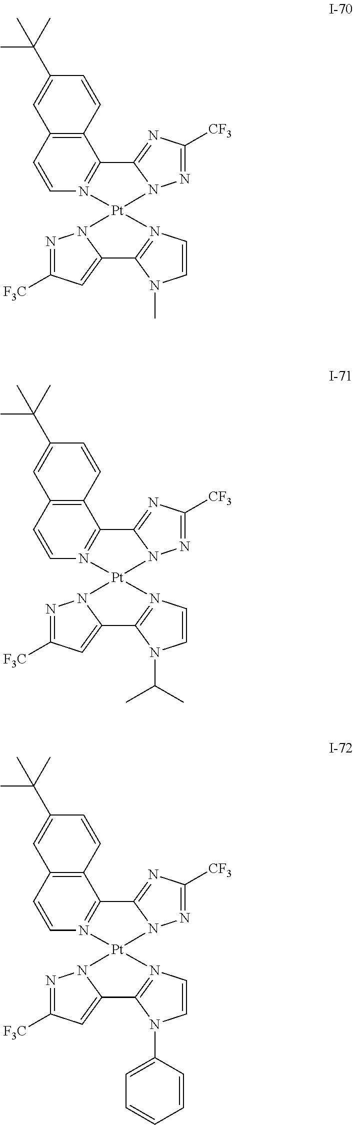

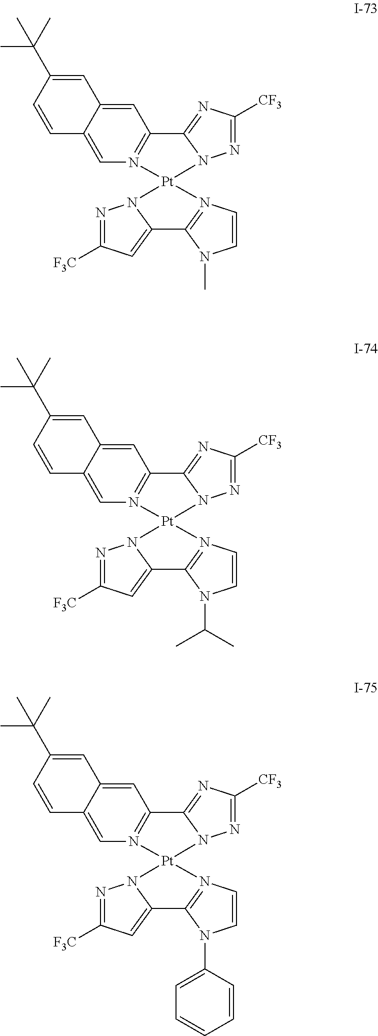

In another example of the invention, when L₁ is the second nitrogen-containing heterocyclic bidentate ligand containing one five-membered ring and one six-membered ring and X₁ is nitrogen, actual examples of the platinum complex satisfying general formula (I) include: the platinum complex represented by either one of formulas (I-76) to (I-129).

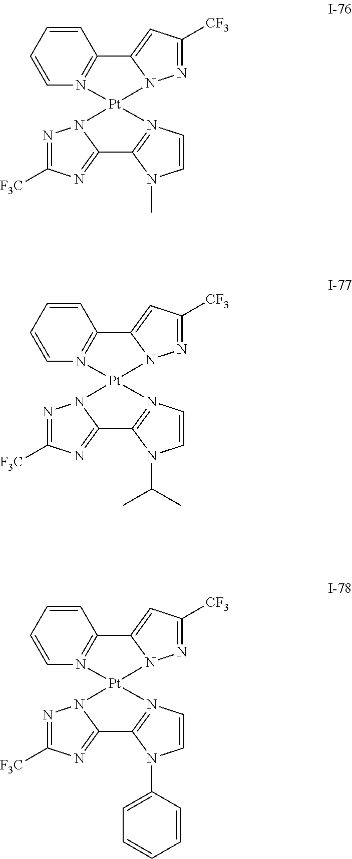

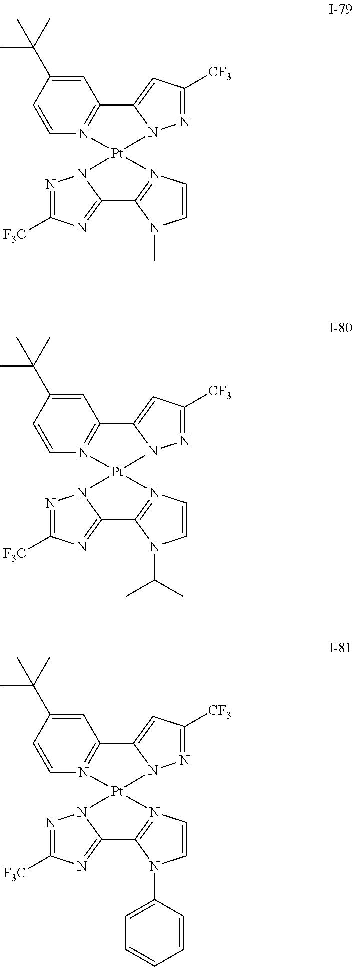

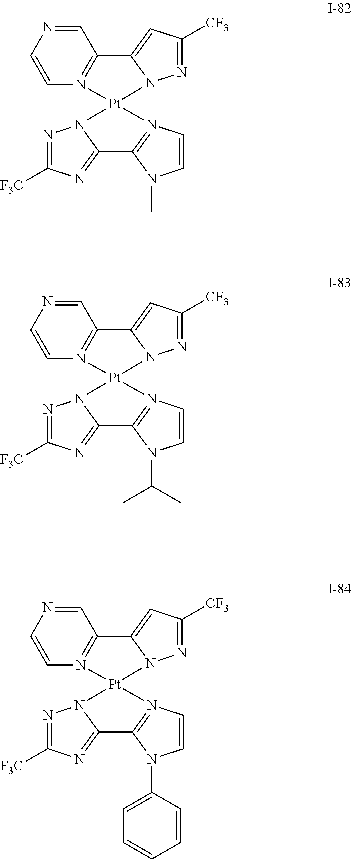

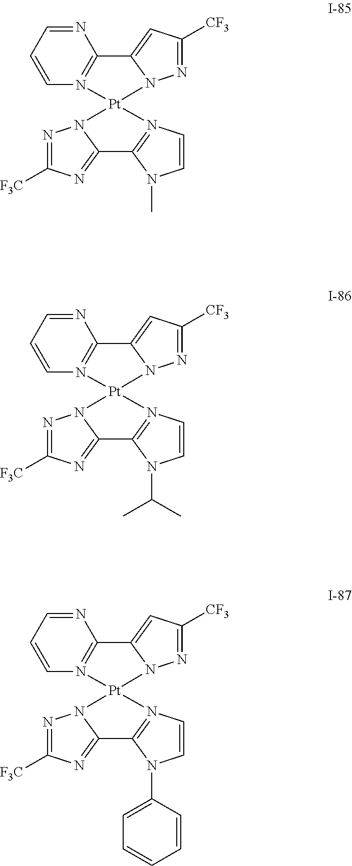

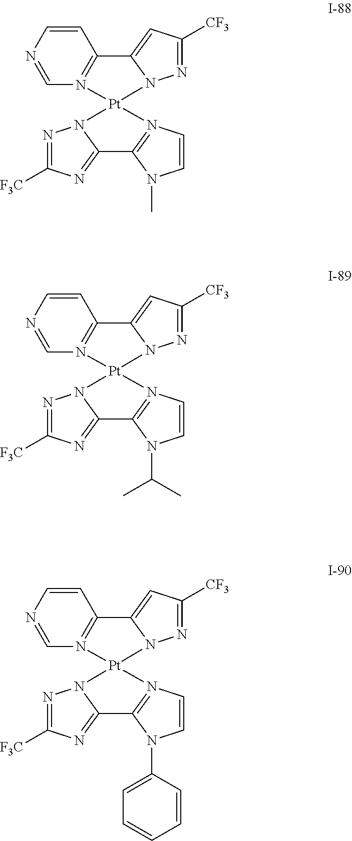

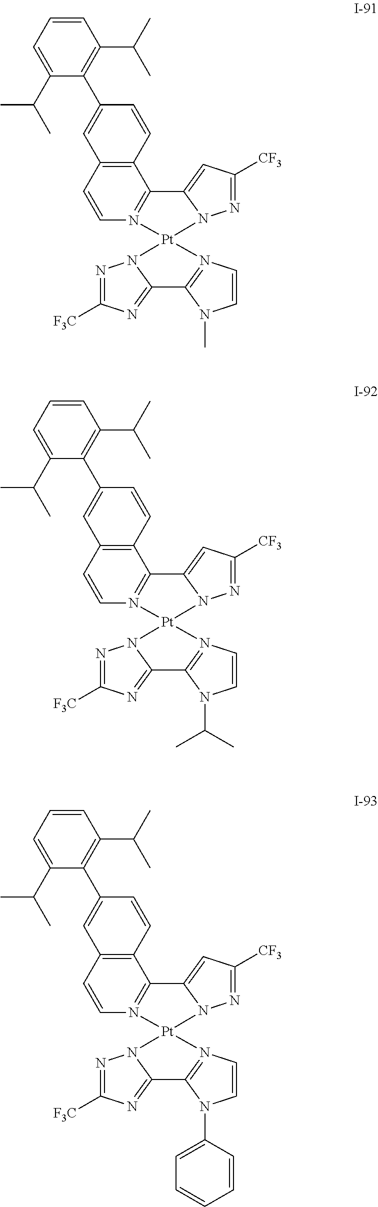

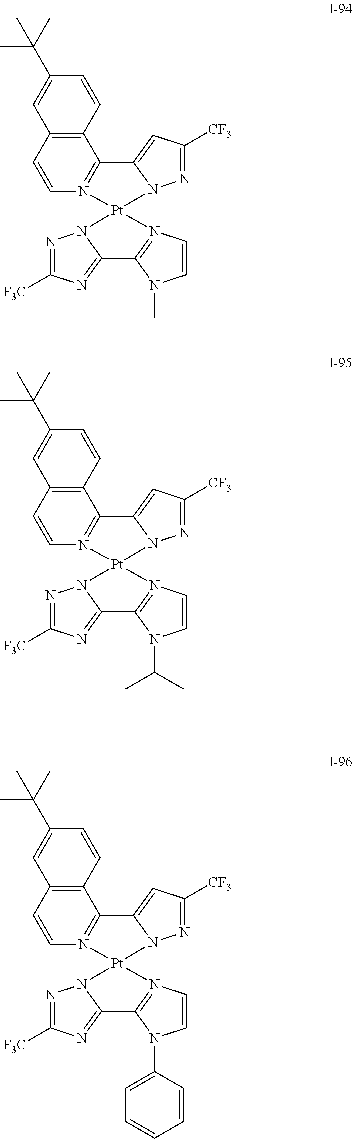

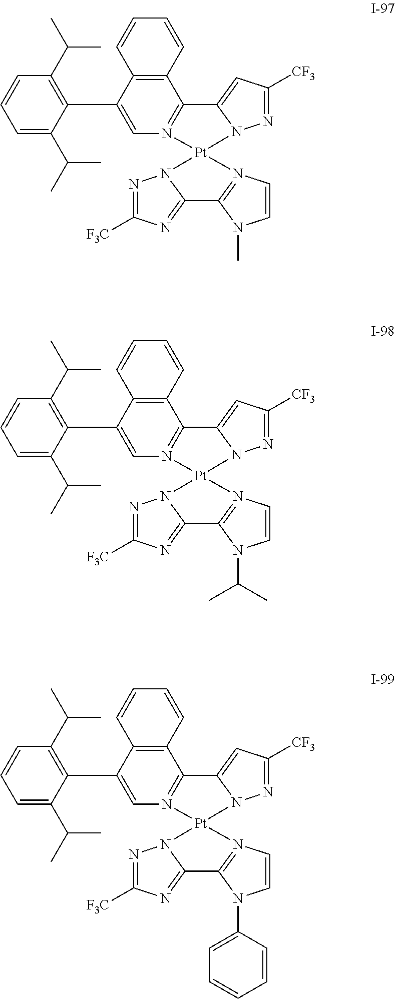

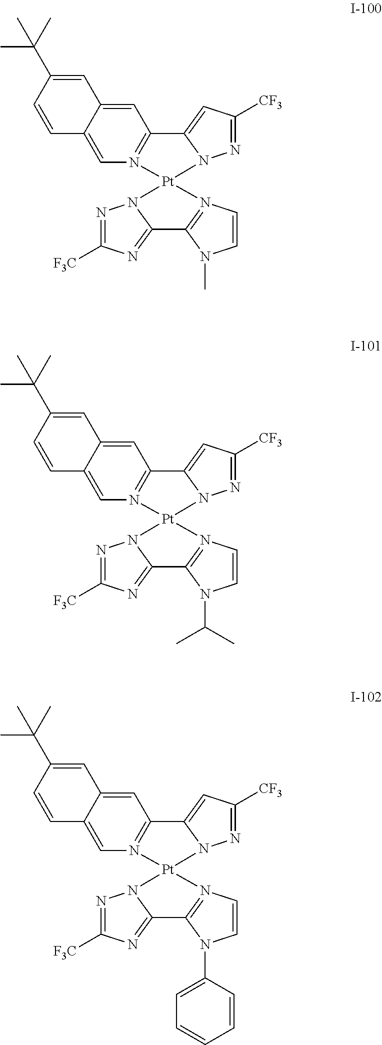

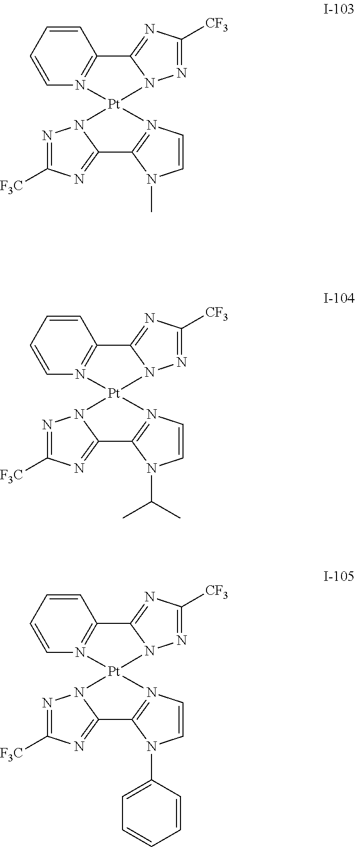

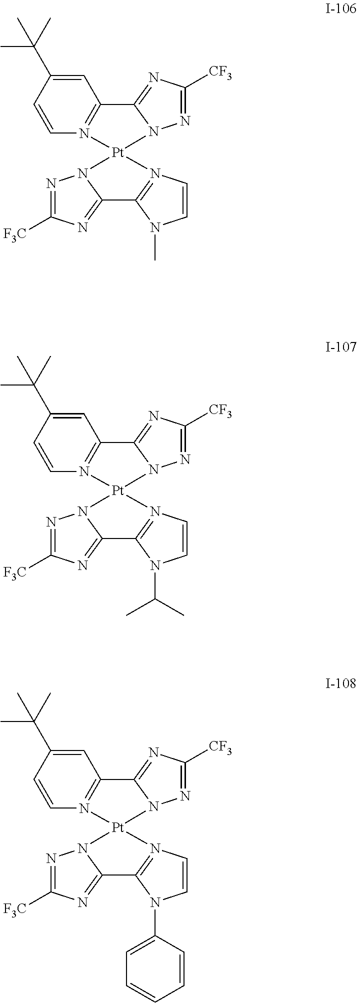

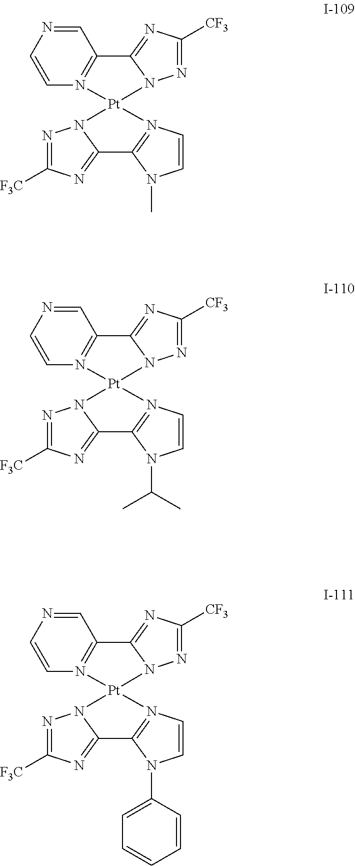

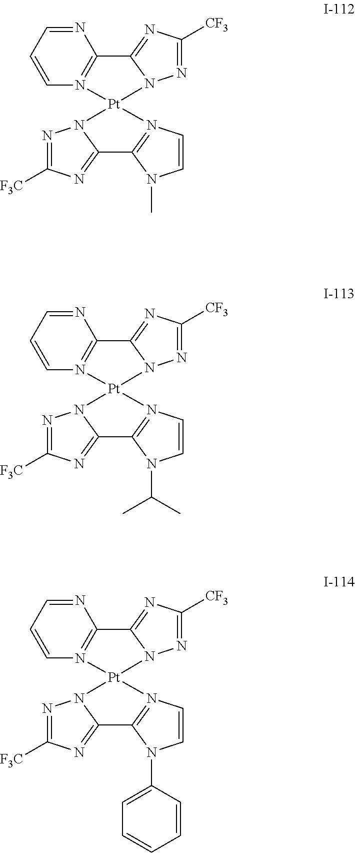

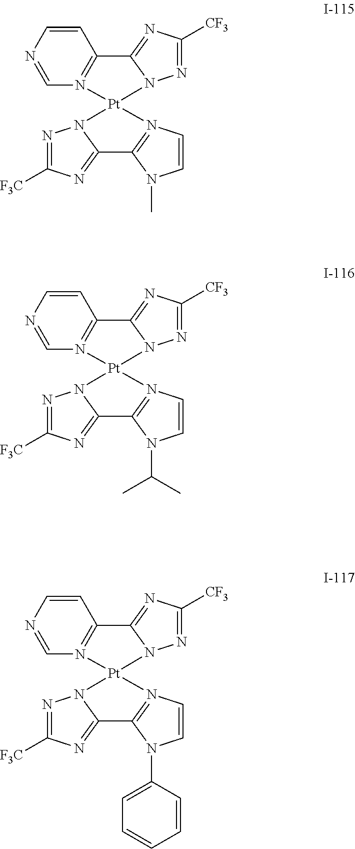

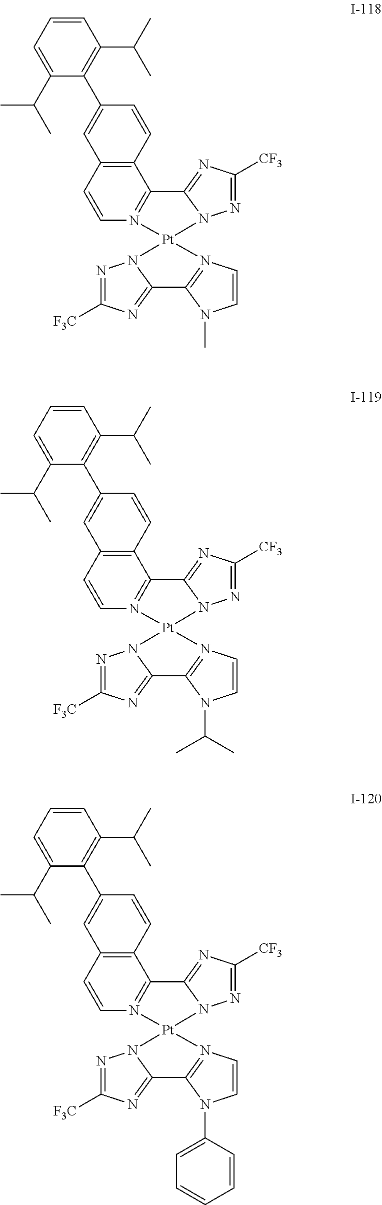

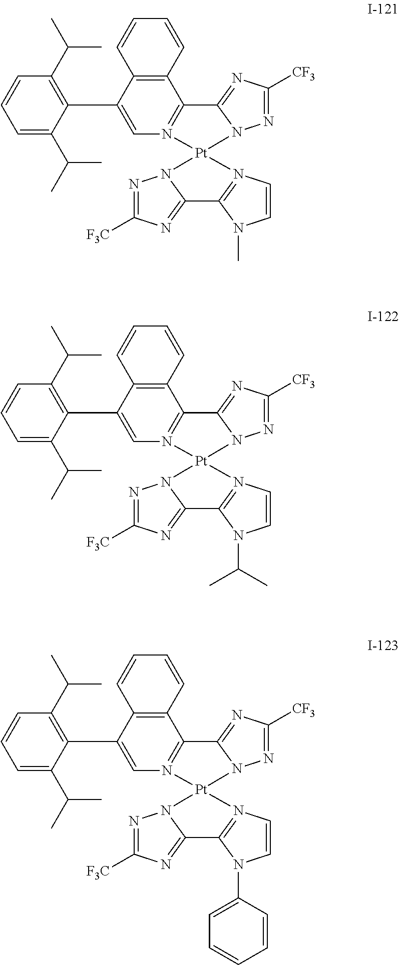

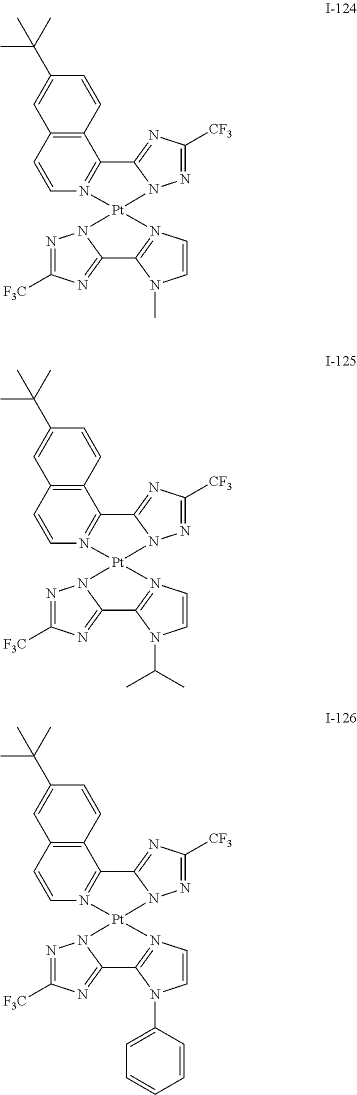

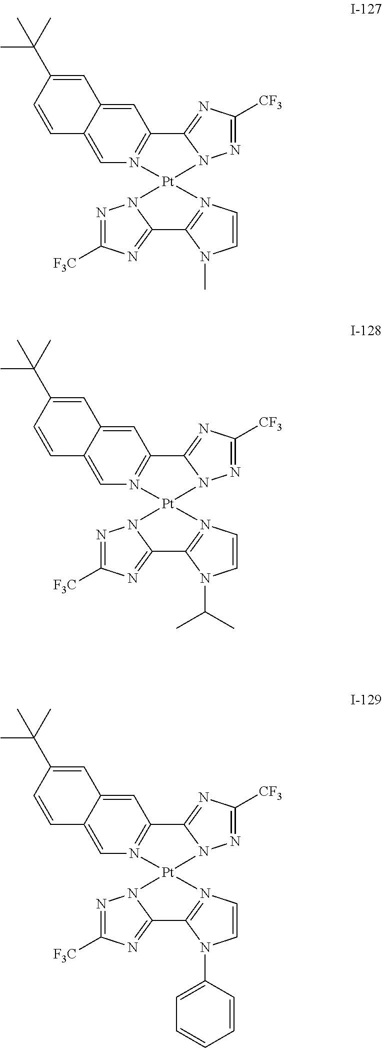

L₂ is, for instance, a third nitrogen-containing heterocyclic bidentate ligand containing one five-membered ring and one six-membered ring.

In an example of the invention, when L₂ is the third nitrogen-containing heterocyclic bidentate ligand containing one five-membered ring and one six-membered ring and the number of nitrogen atoms on L₂ is 3 or less, actual examples of the platinum complex satisfying general formula (II) include: the platinum complex represented by either one of formulas (II-1) to (II-35).

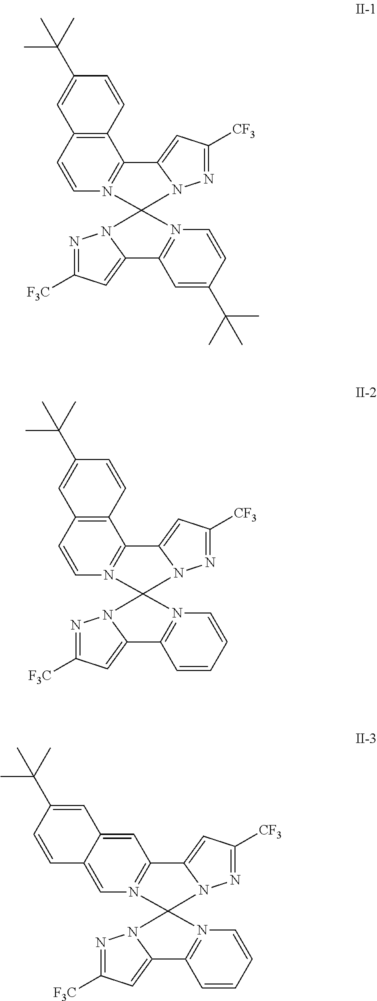

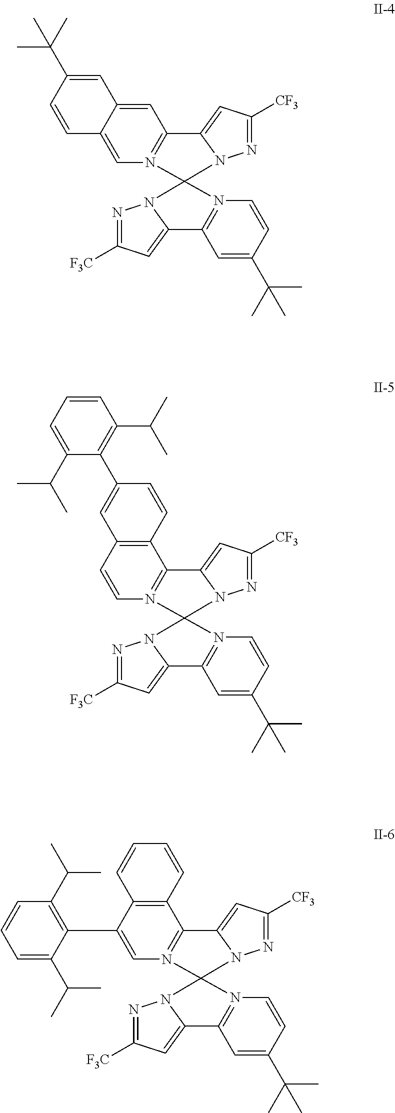

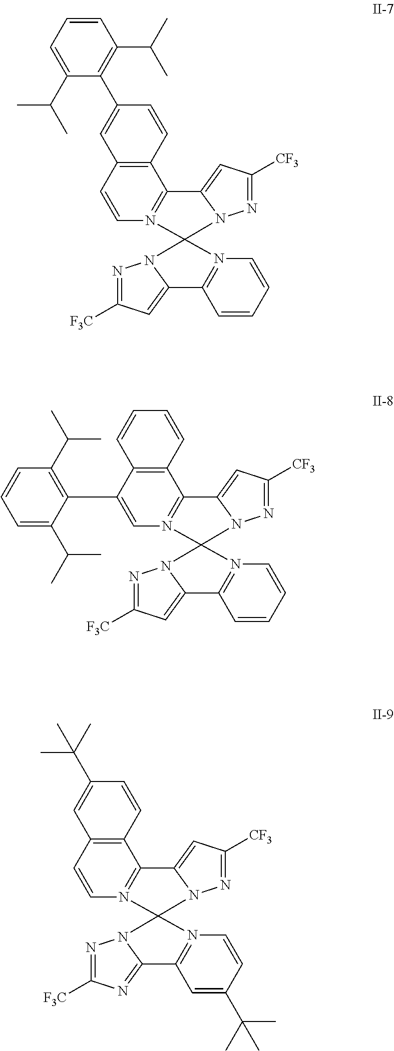

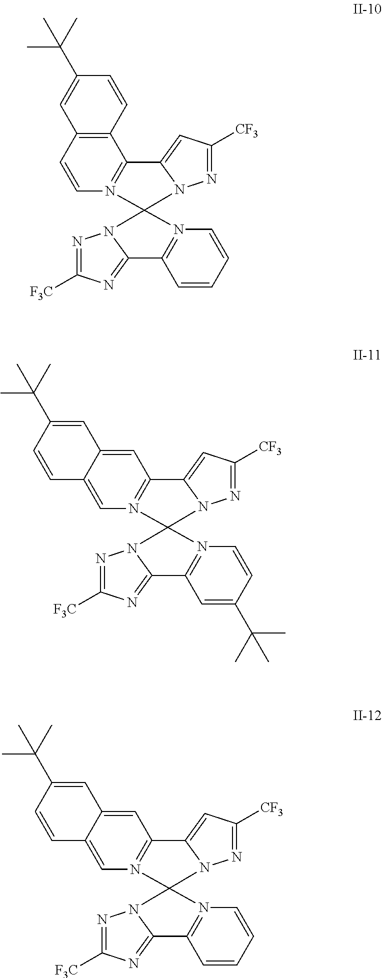

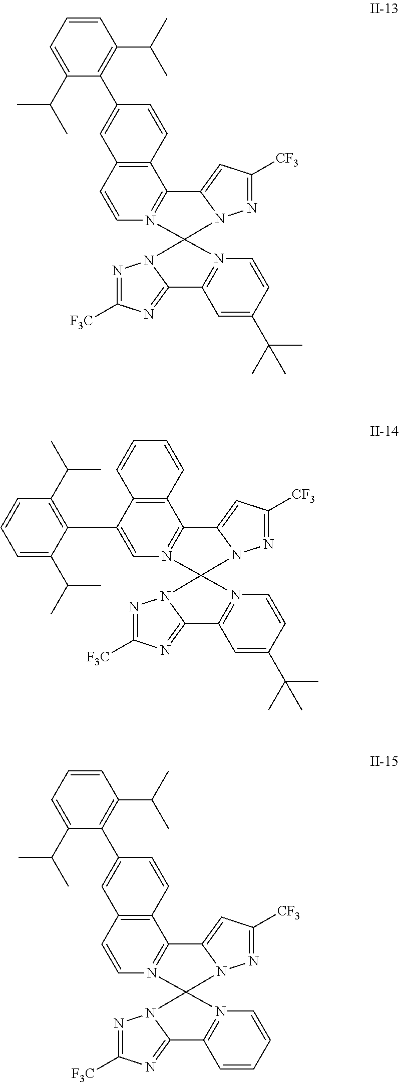

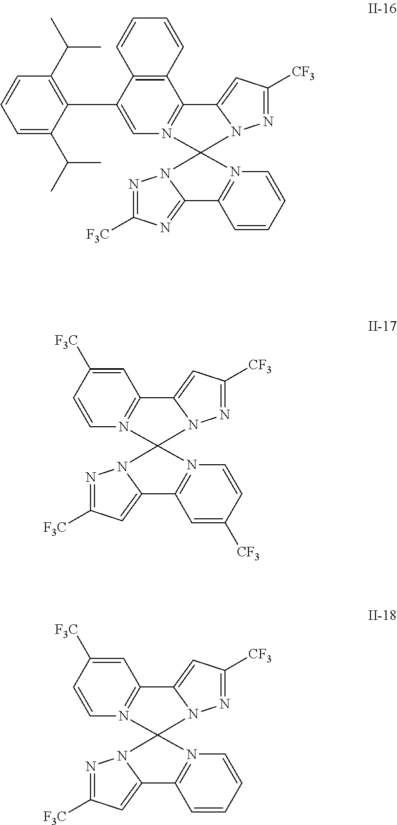

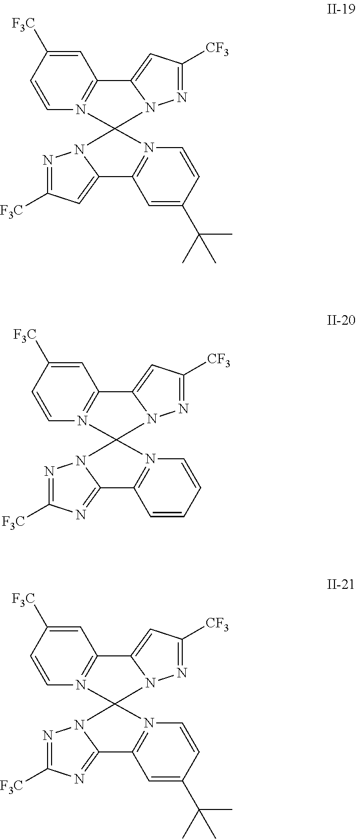

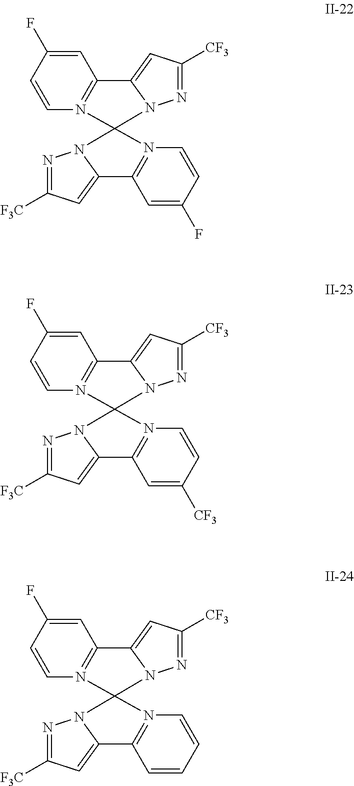

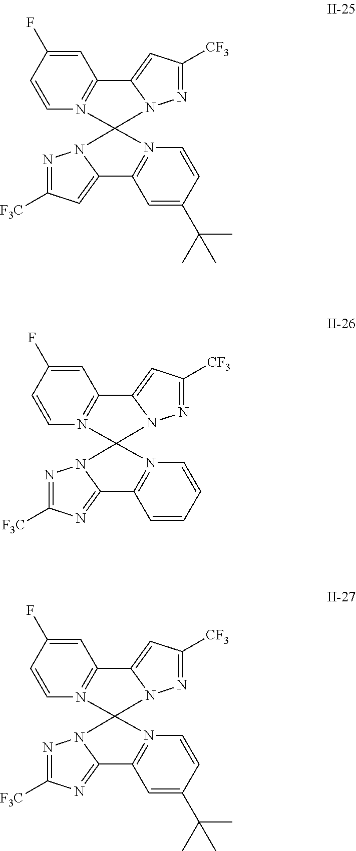

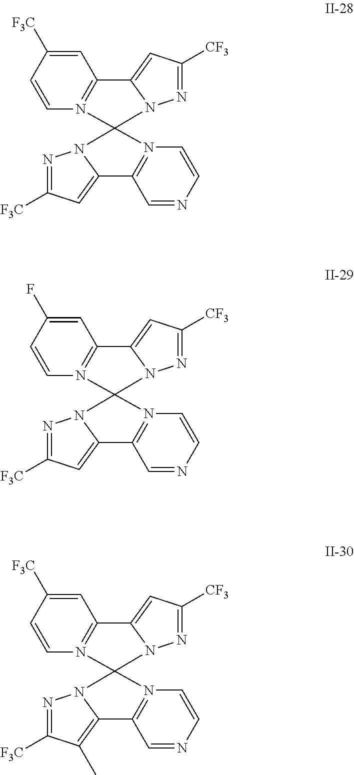

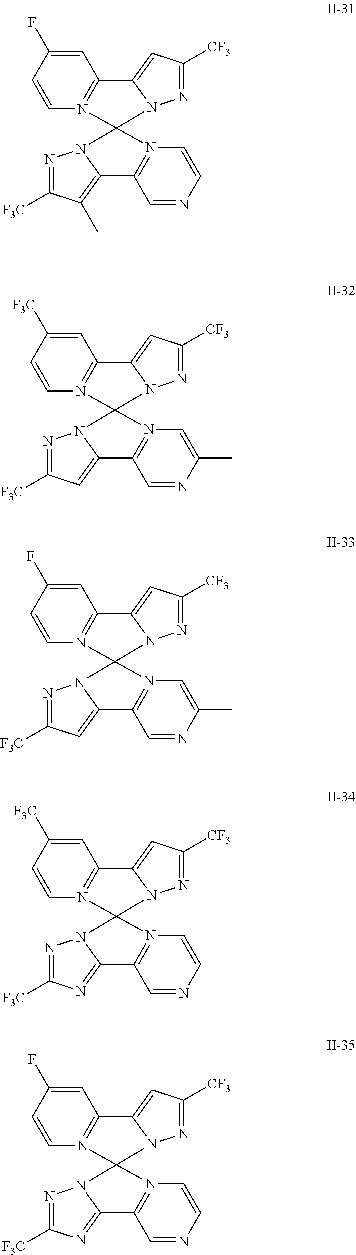

In an example of the invention, when L₂ is the third nitrogen-containing heterocyclic bidentate ligand containing one five-membered ring and one six-membered ring and the number of nitrogen atoms on L₂ is 4 or more, actual examples of the platinum complex satisfying general formula (II) include: the platinum complex represented by either one of formulas (II-36) to (II-115).

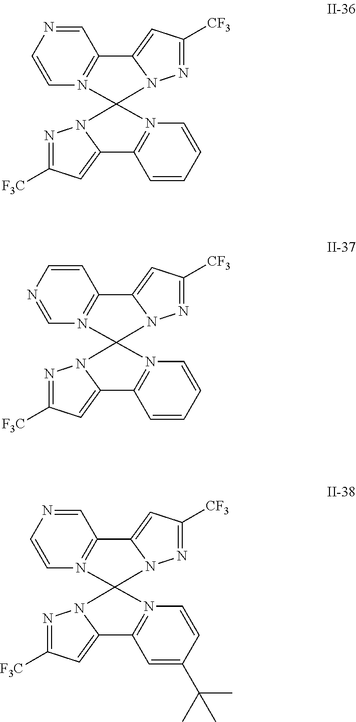

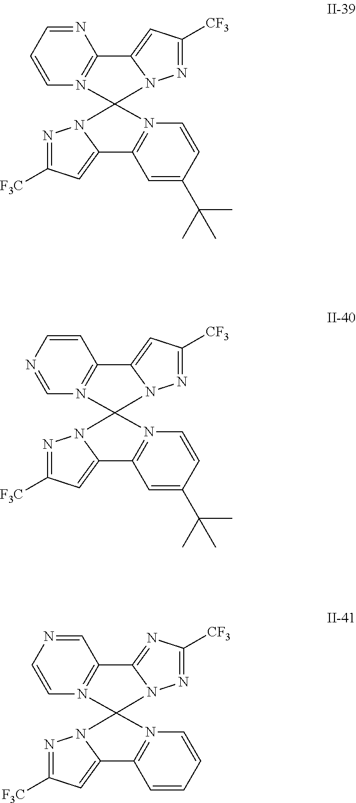

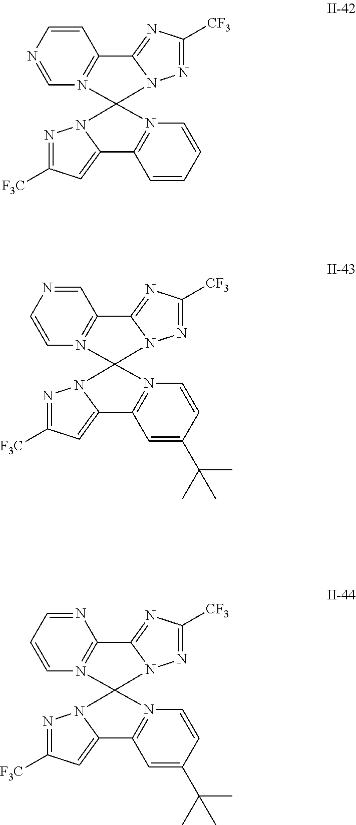

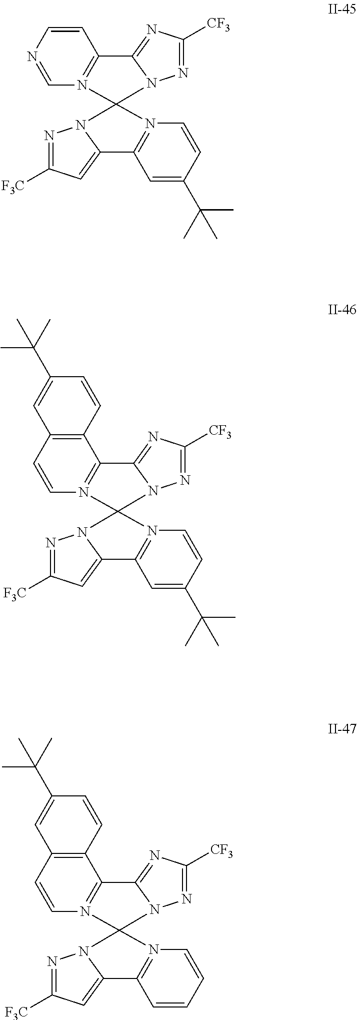

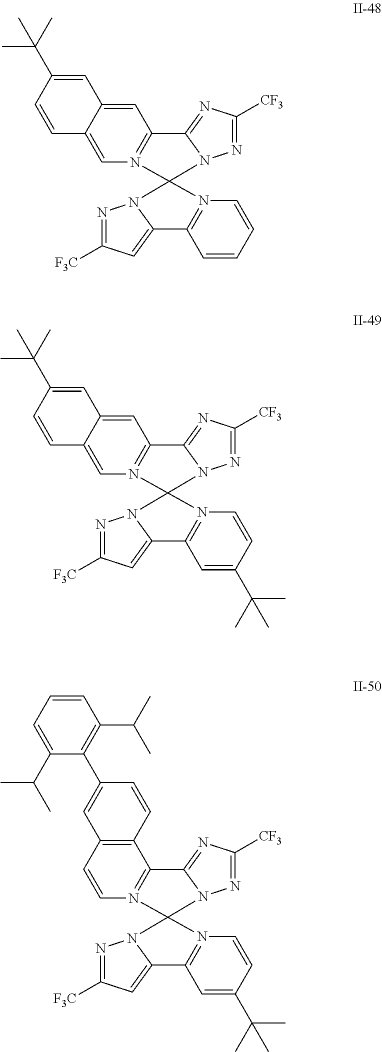

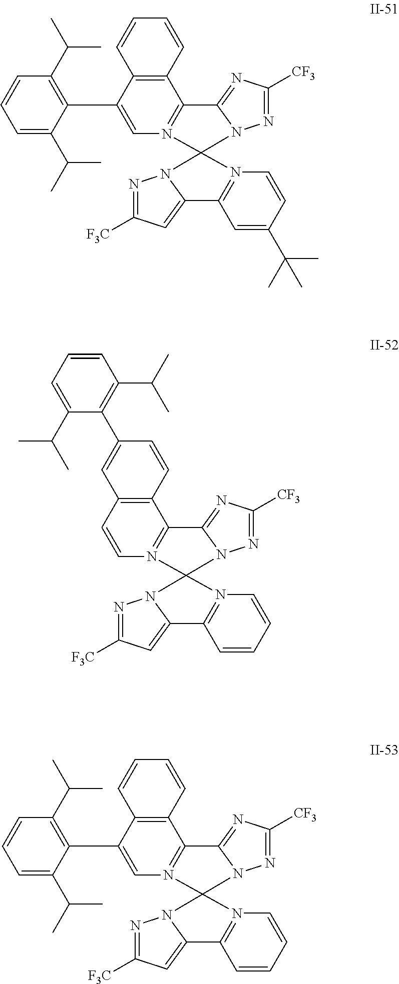

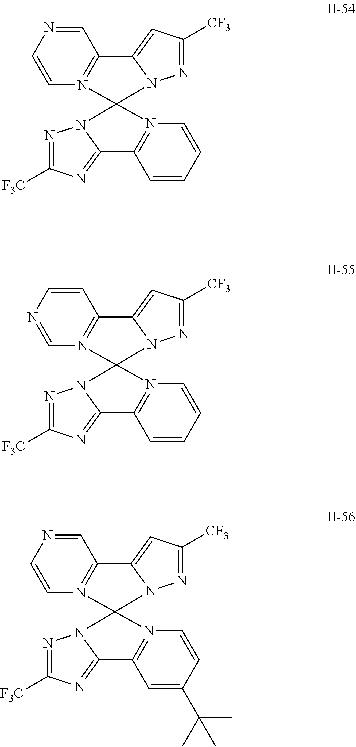

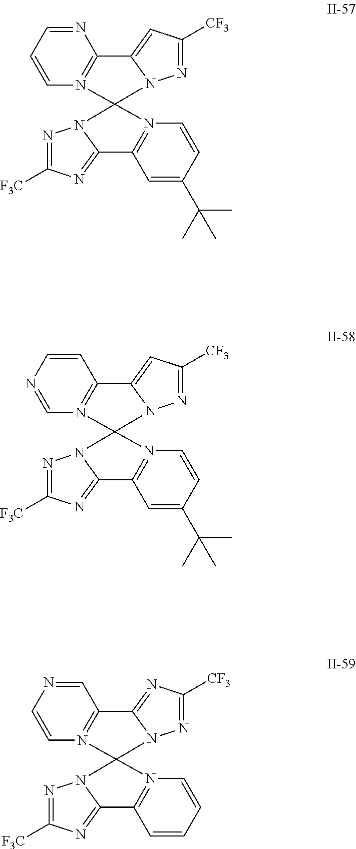

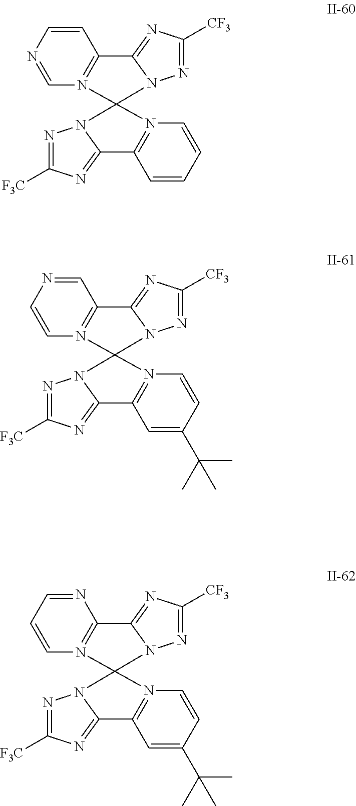

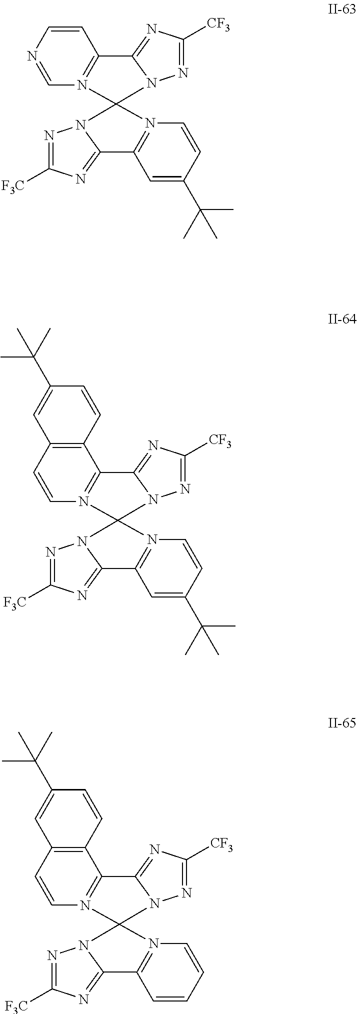

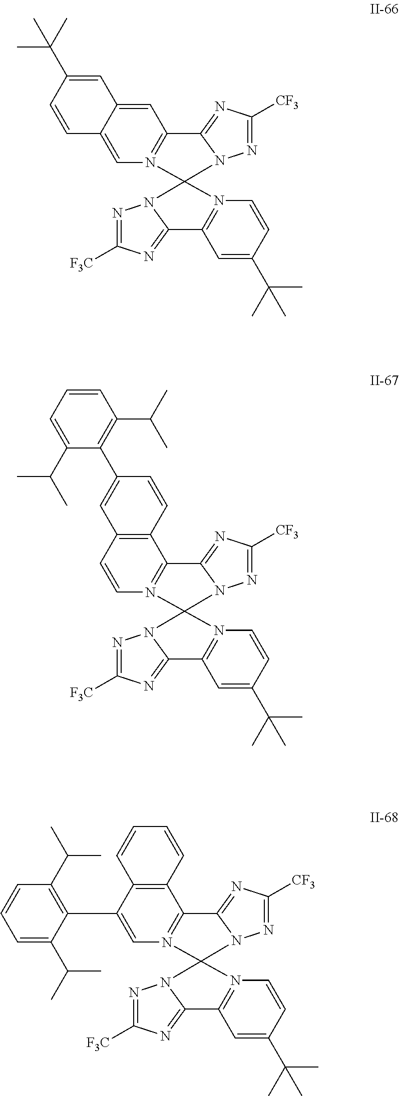

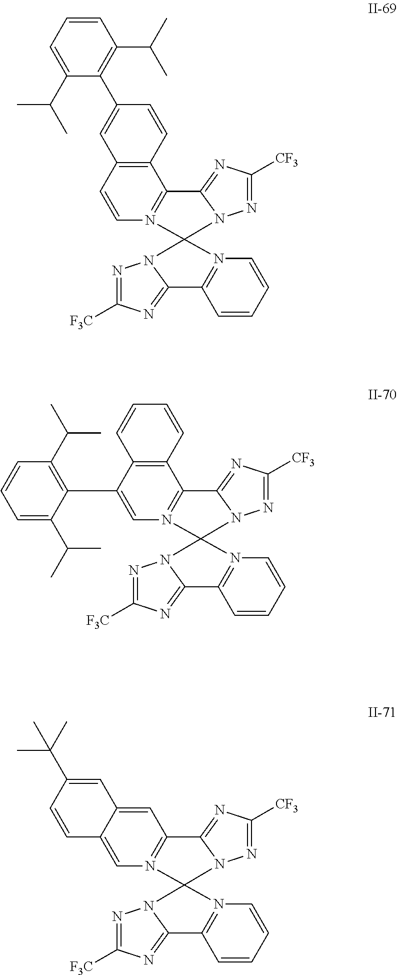

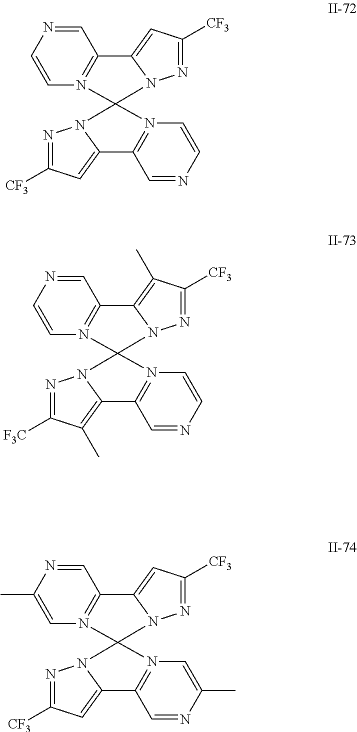

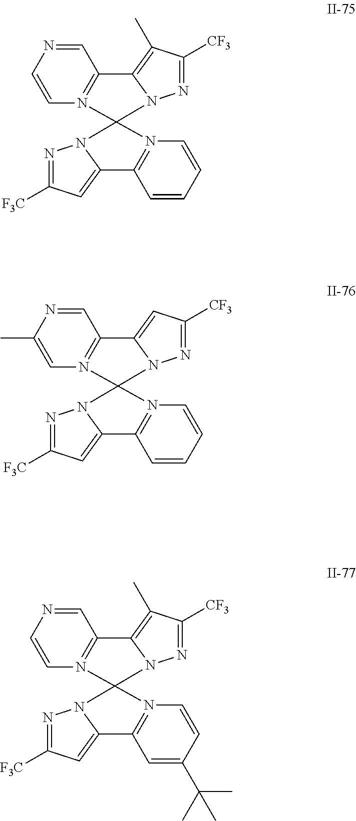

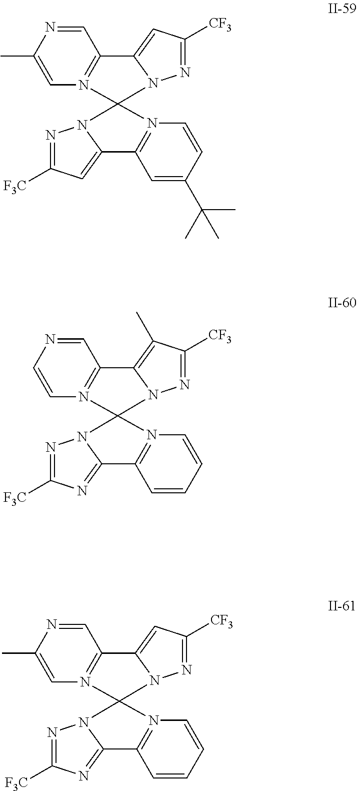

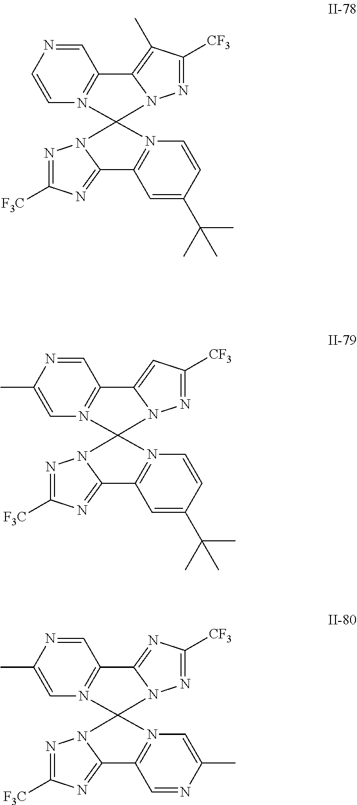

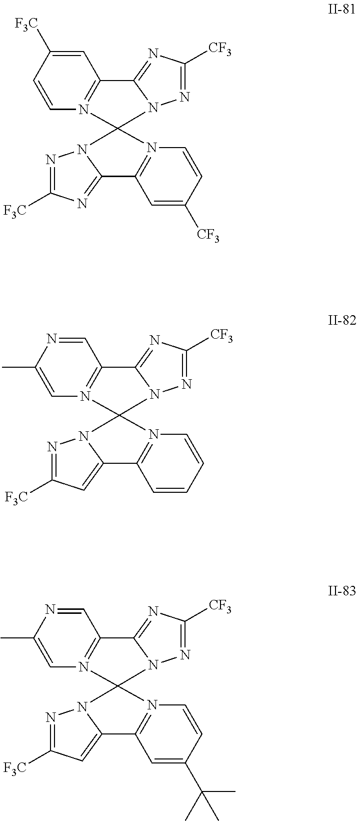

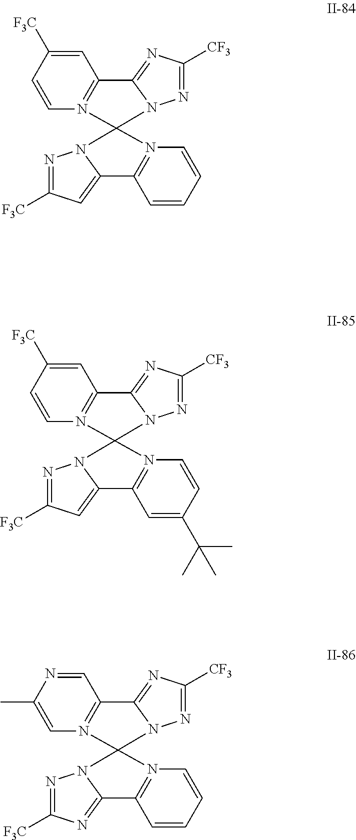

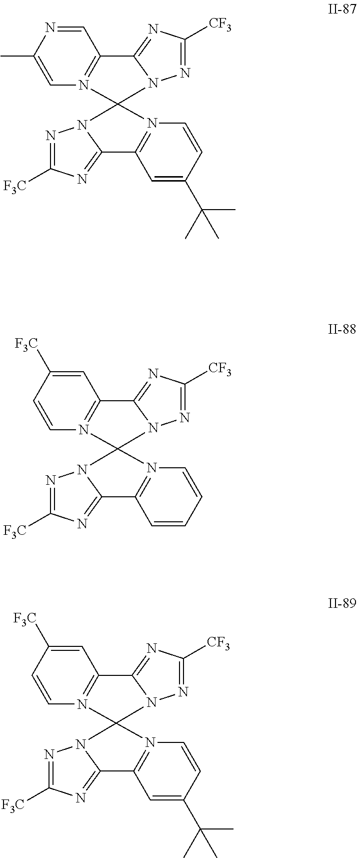

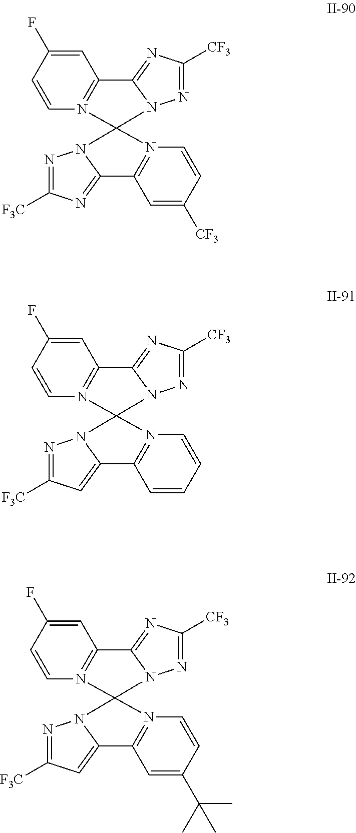

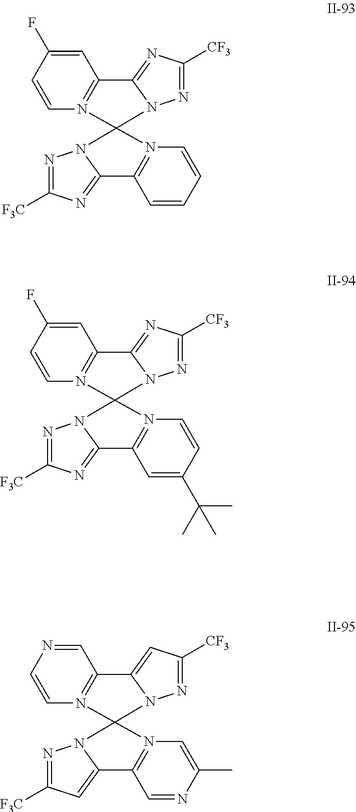

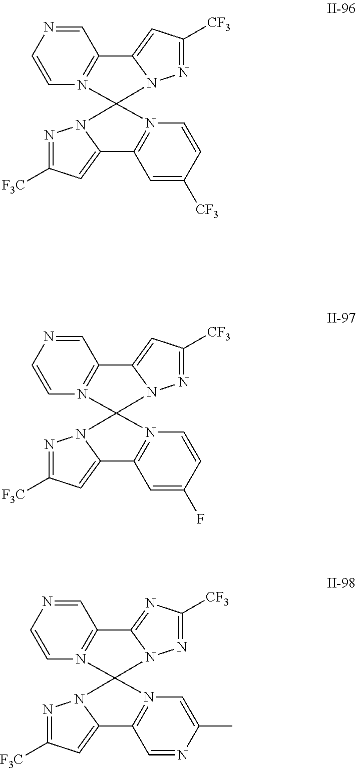

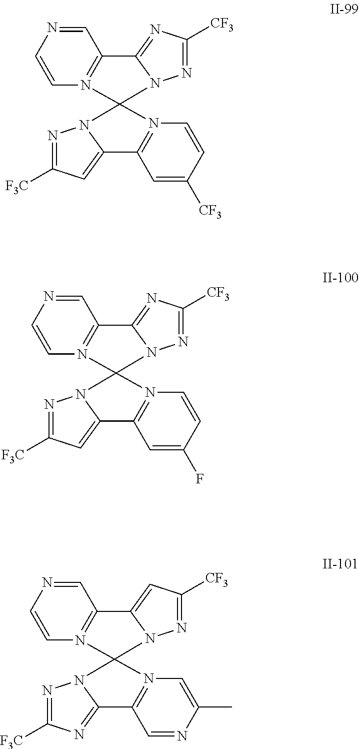

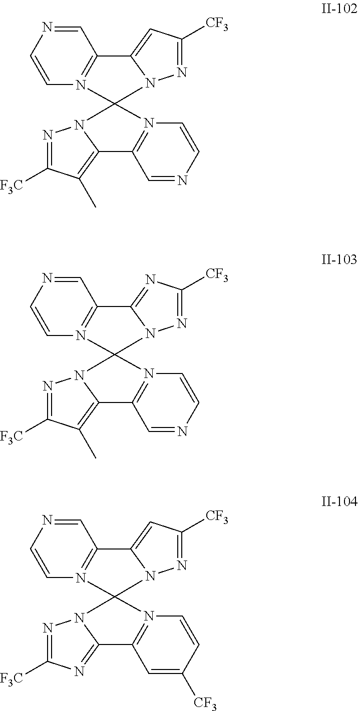

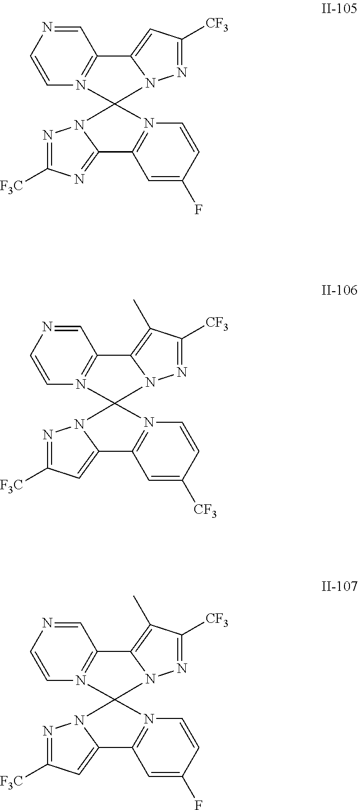

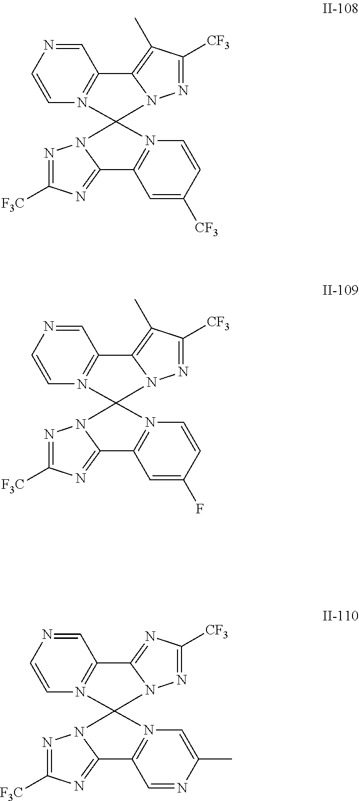

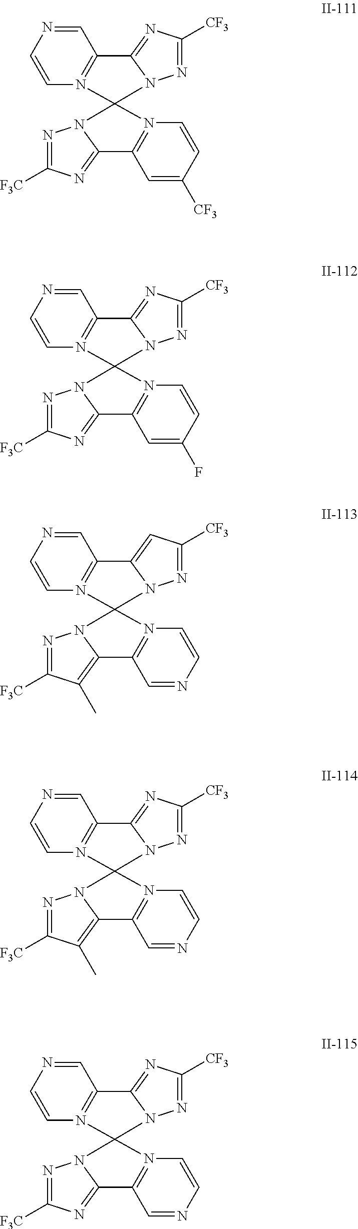

Since the platinum complex having the above structure contains pyrazole or a triazole group and a fluoroalkyl group having electron-withdrawing capability, the energy level of the platinum complex can be more readily adjusted, such that the difference between the HOMO energy level and the LUMO energy level meets requirements. Moreover, the rigidity of the platinum complex is maintained, and after excitation, red to blue color light can be emitted via the mechanism of charge transfer from the metal-metal bonding orbital to the anti-bonding orbital of chelating ligand. As a result, the platinum complex having the above structure has good luminous efficiency and can be applied to the fabrication of an organic light-emitting diode (OLED).

The OLED of the invention includes two electrodes and a light-emitting layer disposed between the two electrodes, and the light-emitting layer contains the platinum complex. The material of each of the two electrodes can be selected from materials commonly used in the field, and other functional layers can also be disposed between each electrode and light-emitting layer via a known technique in the art, such as an electron-transport layer, a hole-transport layer, or an electron-blocking layer. The OLED can be manufactured on a substrate, such as a glass substrate.

### [Forming Method of Platinum Complex of the Invention]

### [Synthesis of Ligand Precursor]

Two examples of the precursor of the nitrogen-containing heterocyclic bidentate ligand represented by general formula (1) can be formed by, for instance, the reaction sequences shown below.

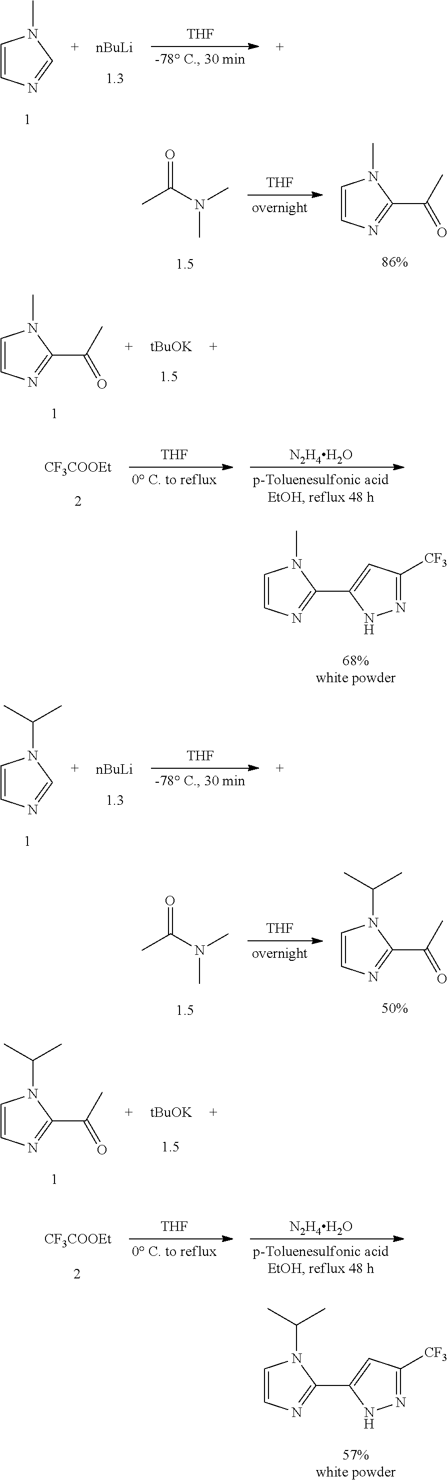

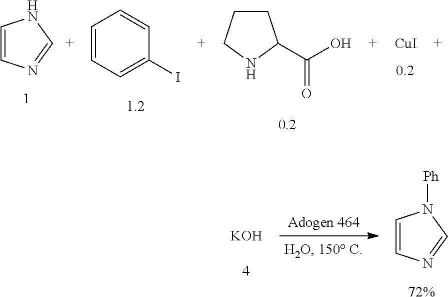

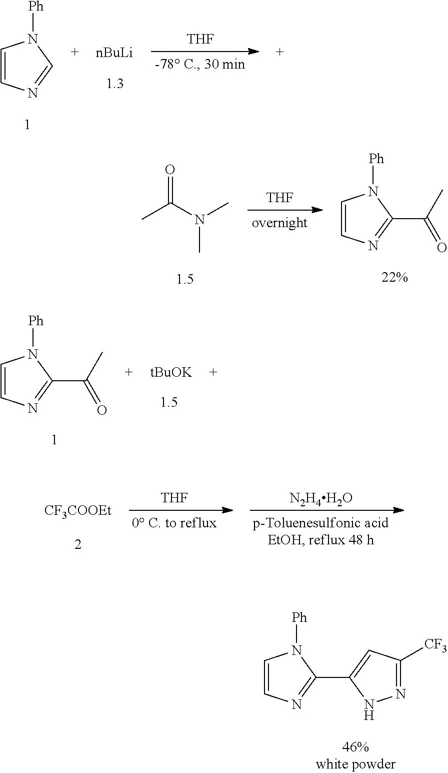

One example of the precursor of the nitrogen-containing heterocyclic bidentate ligand represented by general formula (2) can be formed by, for instance, the reaction sequences shown below.

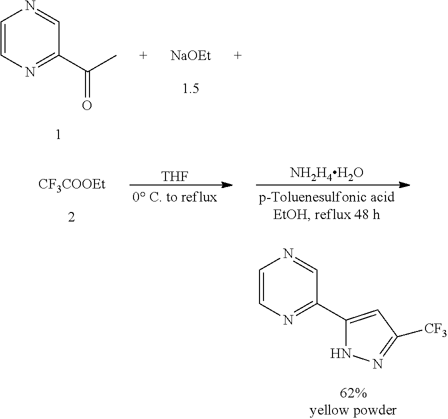

The ligand used in the platinum complex of the invention can be prepared by adopting suitable reactants and reaction conditions according to changes of each ligand, and the reaction preparation method can be modified based on a known technique in the art.

The preparation method of the platinum complex of the invention can be a one-step method or a two-step method.

The one-step method contains the following steps: mixing a ligand, a platinum source, and other desired reagents to obtain the platinum complex of the invention.

The two-step method contains the following reaction sequences: mixing the precursor of a first ligand (such as the nitrogen-containing heterocyclic bidentate ligand represented by general formula (1) or general formula (2)), a platinum source, and other desired reagents to obtain an intermediate product containing platinum metal, and then mixing the resulting intermediate product containing platinum metal, the precursor of a second ligand (such as L₁ or L₂), and other desired reagents to obtain the platinum complex of the invention. The order of bonding the first and second ligands to a platinum atom can also be reversed. That is, a platinum atom and the precursor of the second ligand are reacted first, and then the product and the precursor of the first ligand are reacted.

### [Synthesis of Intermediate Product Containing Platinum Metal]

Synthesis of Intermediate Product Pt(Hfppz)Cl₂

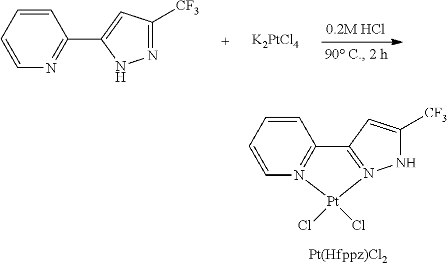

5-(2-pyridyl)-3-trifluoromethylpyrazole (fppzH, 800 mg, 3.8 mmol) and K₂PtCl₄ (1.6 g, 3.9 mmol) were placed in a reaction flask, then 0.2 M HCl (250 mL) was added, and then the temperature was heated to 90° C. After 2 hours, the reaction was completed and the flask was allowed to cool to room temperature. After suction and filtering, washing was performed using diethylether to obtain a yellow intermediate product Pt(Hfppz)Cl₂ (1.5 g, yield: 81%).

Spectral information of Pt(Hfppz)Cl₂: MS (FAB, ¹⁹⁵Pt): m/z 479.3 [M⁺]; ¹H NMR (400 MHz, d₆-acetone, 298K): δ 9.45 (d, J=6.0 Hz, 1H), 8.38 (dd, J=7.6, 7.2 Hz, 1H), 8.30 (d, J=7.6 Hz, 1H), 7.88 (s, 1H), 7.77 (dd, J=7.2, 6.0 Hz, 1H). ¹⁹F NMR (376 MHz, d₆-acetone, 298K): δ −61.12 (s, 3F).

Synthesis of intermediate product Pt(Hfprpz)Cl₂:

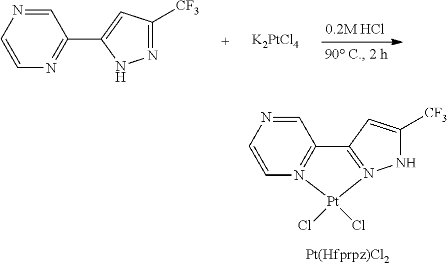

5-(2-pyrazinyl)-3-trifluoromethylpyrazole) (250 mg, 1.2 mmol) and K₂PtCl₄ (580 mg, 1.4 mmol) were placed in a reaction flask, then 0.2 M HCl (250 mL) was added, and then the flask was heated to 90° C. After 2 hours, the reaction was completed and the temperature was lowered to room temperature. After suction and filtering, washing was performed using diethylether to obtain a yellow intermediate product Pt(Hfprpz)Cl₂ (426 mg, yield: 76%).

Spectral information of Pt(Hfprpz)Cl₂: ¹H NMR (700 MHz, d₈-THF, 323K): δ 11.49 (br, 1H), 10.37 (d, J=3 Hz, 1H), 9.20 (s, 1H), 8.71 (d, J=3 Hz, 1H), 7.19 (s, 1H), ¹⁹F NMR (600 MHz, d₈-THF, 323K): δ −61.81 (s, CF₃).

Synthesis of Intermediate Product Pt(^{t}Bu-Hfppz)Cl₂

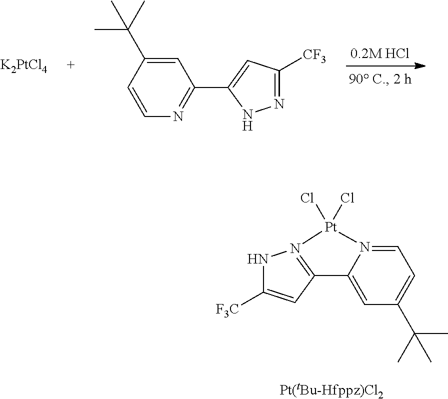

5-(2-pyridyl-4-tert-butyl)-3-trifluoromethylpyrazole) (568 mg, 21.17 mmol) and K₂PtCl₄ (800 mg, 17.74 mmol) were placed in a reaction flask, then 0.2 M HCl (250 mL) was added, and then the flask was heated to 90° C. After 2 hours, the reaction was completed and the temperature was lowered to room temperature. After suction and filtering, washing was performed using diethylether to obtain a yellow intermediate product Pt(^{t}Bu-Hfppz)Cl₂ (870 mg, yield: 84%).

Spectral information of Pt(^{t}Bu-Hfppz)Cl₂: ¹H NMR (400 MHz, CDCl₃, 298K): δ 9.45 (d, J=6.0 Hz, 1H), 8.38 (dd, J=7.6, 7.2 Hz, 1H), 7.88 (s, 1H), 7.77 (dd, J=7.2, 6.0 Hz, 1H), 1.35 (s, 9H). ¹⁹F NMR (376 MHz, d₆-acetone, 298K): δ −61.12 (s, 3F).

In the following, several examples are provided to further describe the invention, but the examples are only exemplary and are not intended to limit the scope of the invention.

### EXAMPLES

### Example 1

Preparation of Compound (I-1):

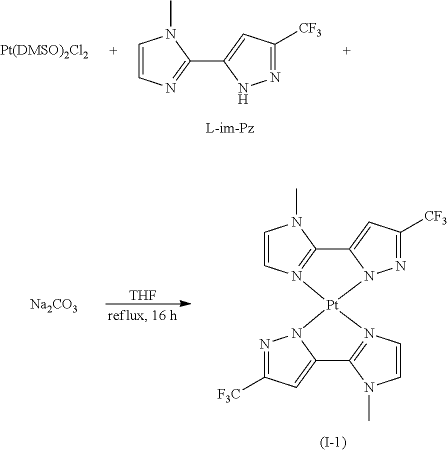

Pt(DMSO)₂Cl₂ (490 mg, 1.2 mmol), L-im-Pz (500 mg, 2.3 mmol), and Na₂CO₃ (490 mg, 4.7 mmol) were placed in a 50 mL round-bottomed flask, and then THF (20 mL) was added. Then, the mixture was heated until boiling. After reacting for 16 hours, the temperature was lowered to room temperature, and after the reaction was completed, deionized water was added, the mixture was filtered, washing was performed using diethylether and ethyl acetate, the precipitate was collected, and after the precipitate was sublimed and purified, a white powder (810 mg, yield: 95%) was obtained.

Spectral data of compound (I-1): MS (FAB, ¹⁹⁵Pt): m/z 625.1 [M⁺]; ¹H NMR (400 MHz, d₆-acetone, 298K): δ 7.93 (d, J=1.6 Hz, 2H), 7.39 (d, J=1.6 Hz, 2H), 6.97 (s, 2H), 4.11 (s, 6H). ¹⁹F NMR (376 MHz, d₆-acetone, 298K): δ −61.07 (s, 6F). Anal. Calcd. for Cl₆H₁₂F₆N₈Pt: C, 30.73; H, 1.93; N, 17.92. Found: C, 30.61; H, 2.27; N, 17.42.

### Example 2

Preparation of Compound (I-2):

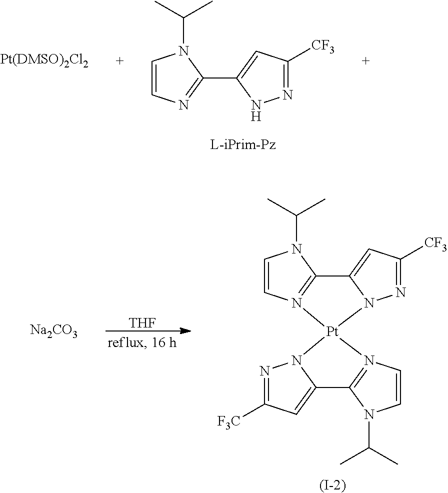

Pt(DMSO)₂Cl₂ (200 mg, 0.6 mmol), L-iPrim-Pz (237 mg, 1 mmol), and Na₂CO₃ (502 mg, 4.74 mmol) were placed in a 50 mL round-bottomed flask, and after THF (20 mL) was added to dissolve the reactants, and the mixture was heated to reflux for 16 hours. After the reaction was completed, the temperature was lowered to room temperature, and deionized water was added and the mixture was filtered, then washed using diethylether and ethyl acetate, and then the precipitate was collected. After the precipitate was sublimed and purified, a white powder (187 mg, yield: 58%) was obtained.

Spectral data of compound (I-2): ¹H NMR (400 MHz, d₆-DMSO, 298K): δ 7.79 (d, J=1.6 Hz, 2H), 7.70 (d, J=1.6 Hz, 2H), 7.21 (s, 2H), 4.94˜4.88 (m, 2H), 1.48 (d, J=6.4 Hz, 6H); ¹⁹F NMR (400 MHz, d₆-DMSO, 298K): δ −59.11 (s, 6F).

### Example 3

Preparation of Compound (I-3):

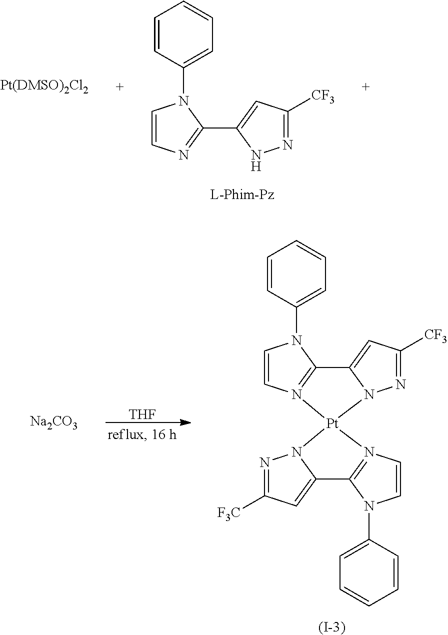

Pt(DMSO)₂Cl₂ (200 mg, 0.6 mmol), L-Phim-Pz (270 mg, 1 mmol), and Na₂CO₃ (502 mg, 4.74 mmol) were placed in a 50 mL round-bottomed flask, and after THF (25 mL) was added, and the mixture was heated to reflux for 16 hours. After the reaction was completed, the temperature was lowered to room temperature, and deionized water was added and the mixture was filtered, then washed using diethylether and ethyl acetate, and then the precipitate was collected. After the precipitate was sublimed and purified, a creamy-white powder (190 mg, yield: 53%) was obtained.

Spectral data of compound (I-3): ¹H NMR (400 MHz, d₆-DMSO, 298K): δ 7.89 (t, J=1.4 Hz, 2H), 7.80 (t, J=1.4 Hz, 2H), 7.72˜7.64 (m, 10H), 6.01 (s, 2H); ¹⁹F NMR (376 MHz, d₆-DMSO, 298K): δ −59.14 (s, 6F).

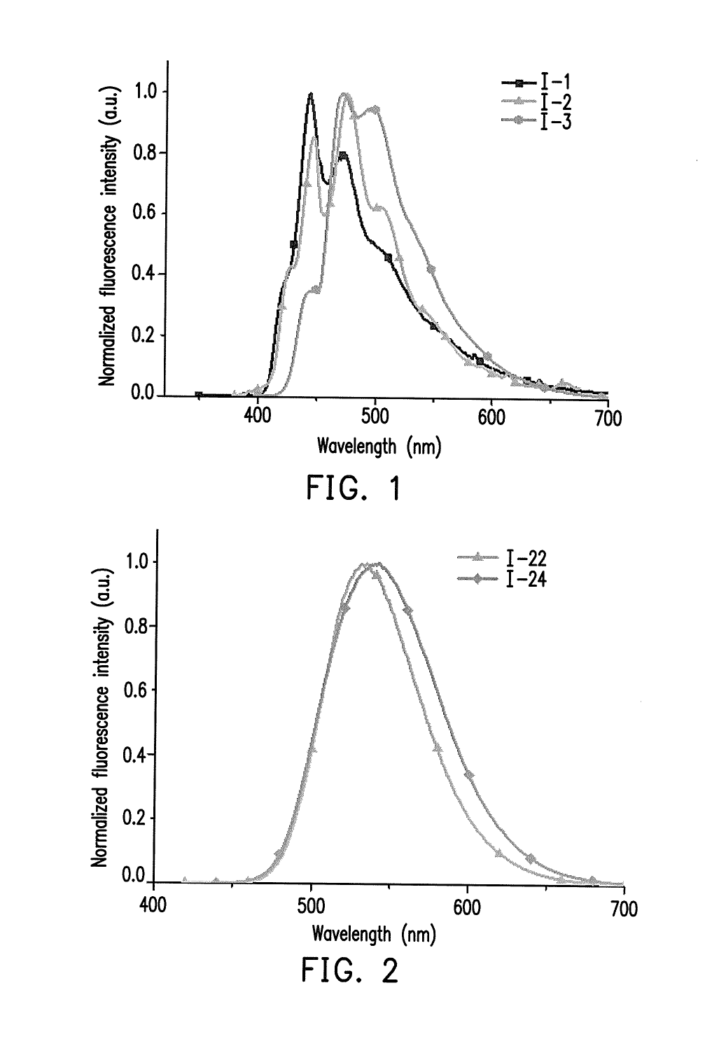

The phosphorescence spectrum of the platinum complexes synthesized in examples 1 to 3 (i.e., compound (I-1), compound (I-2), and compound (I-3)) is shown in FIG. 1, and the emission peak location (em λₘₐₓ), the quantum yield (φ), and the phosphorescence lifetime (τ) are listed in the following Table 1.

TABLE 1

| Compound | em λₘₐₓ (nm) | φ(%) | τ(ns) |
|---|---|---|---|
| (I-1) | 442 | 31 | 6026 |
| (I-2) | 474 | 45 | 3875 |
| (I-3) | 471 | 39 | 3142 |

It can be known from FIG. 1 and Table 1 that, the three compounds have excellent luminous efficiency in the wavelength range of blue light, between about 31% to 45%.

### Example 4

Preparation of Compound (I-22):

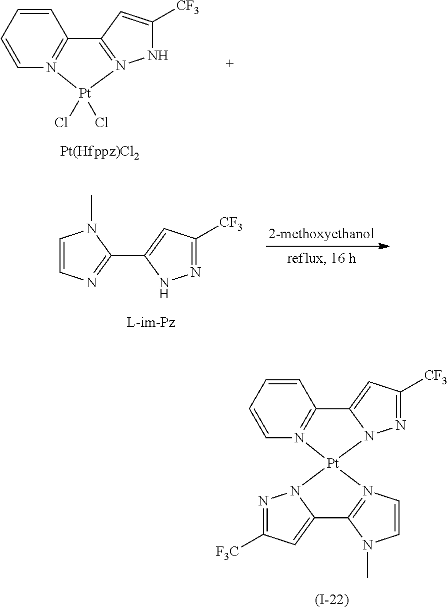

Pt(Hfppz)Cl₂ (295 mg, 0.6 mmol) and L-im-Pz (200 mg, 0.9 mmol) were placed in a 50 mL round-bottomed flask, and then 2-methoxyethanol (20 mL) was added. Then, the mixture was heated until boiling. After reacting for 16 hours, the temperature was lowered to room temperature, and after the reaction was completed, deionized water was added, the mixture was filtered, washing was performed using diethylether and ethyl acetate, the precipitate was collected, and after sublimation, a yellow powder was obtained (223 mg, yield: 58%).

Spectrum data of compound (I-22): MS (FAB, ¹⁹⁵Pt): m/z 622.7 [M⁺]; ¹H NMR (400 MHz, d₆-acetone, 298K): δ 10.10 (d, J=8.0 Hz, 1H), 8.14 (t, J=8.0 Hz, 1H), 7.88˜7.84 (m, 2H), 7.42 (t, J=7.6 Hz, 1H), 7.28 (d, J=1.6 Hz, 1H), 6.97 (s, 1H), 6.86 (s, 1H), 4.04 (s, 3H). ¹⁹F NMR (376 MHz, d₆-acetone, 298K): δ −60.92 (s, 3F), −61.14 (s, 3F).

### Example 5

Preparation of Compound (I-23):

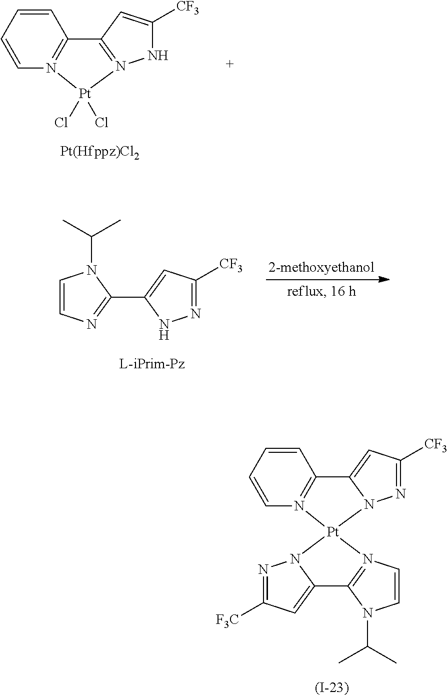

Pt(Hfppz)Cl₂ (295 mg, 0.6 mmol) and L-iPrim-Pz (226 mg, 0.9 mmol) were placed in a 50 mL round-bottomed flask, and then 2-methoxyethanol (20 mL) was added. Then, the mixture was heated until boiling. After reacting for 16 hours, the temperature was lowered to room temperature, and after the reaction was completed, deionized water was added, the mixture was filtered, washing was performed using diethylether and ethyl acetate, the precipitate was collected, and after sublimation, a yellow powder was obtained (248 mg, yield: 62%).

### Example 6

Preparation of Compound (I-24):

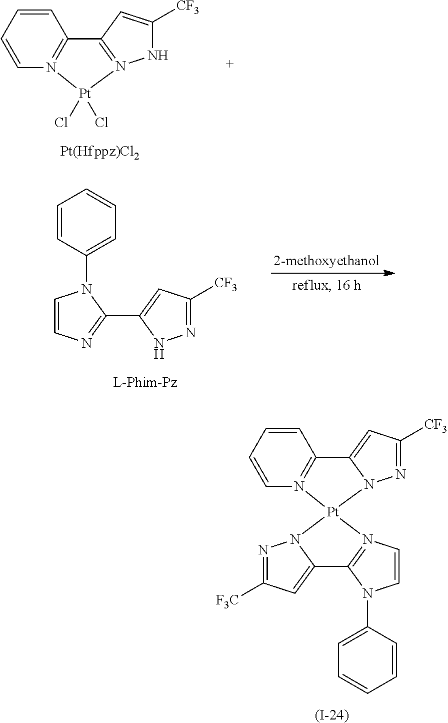

Pt(Hfppz)Cl₂ (295 mg, 0.6 mmol) and L-Phim-Pz (258 mg, 0.9 mmol) were placed in a 50 mL round-bottomed flask, and then 2-methoxyethanol (20 mL) was added. Then, the mixture was heated until boiling. After reacting for 16 hours, the temperature was lowered to room temperature, and after the reaction was completed, deionized water was added, the mixture was filtered, washing was performed using diethylether and ethyl acetate, the precipitate was collected, and after sublimation, a yellow-green solid was obtained (308 mg, yield: 73%).

Spectral data of compound (I-24): ¹H NMR (400 MHz, d₆-DMSO, 298K): δ 9.8 (d, J=6 Hz, 1H), 8.10 (tt, J=7.6 Hz, 1.6 Hz, 1H), 7.89 (d, J=6 Hz, 1H), 7.86 (t, J=1.6 Hz 1H), 7.68˜7.64 (m, 5H), 7.39 (tt, J=7.6 Hz, 1.6 Hz, 1H), 7.10 (s, 1H), 5.90 (s, 1H); ¹⁹F NMR (376 MHz, d₆-DMSO, 298K): δ −59.39 (s, 3F), −59.44 (s, 3F).

The phosphorescence spectrum of the platinum complexes synthesized in examples 4 and 6 (i.e., compound (I-22) and compound (I-24)) is shown in FIG. 2, and the emission peak location (em λₘₐₓ), the quantum yield (φ), and the phosphorescence lifetime (τ) are listed in the following Table 2.

TABLE 2

| Compound | em λₘₐₓ (nm) | φ(%) | τ(ns) |
|---|---|---|---|
| (I-22) | 531 | 91 | 432 |
| (I-24) | 541 | 89 | 530 |

It can be known from FIG. 2 and Table 2 that, the three compounds have excellent luminous efficiency in the wavelength range of green light of between about 91% to 89%, and the phosphorescence life cycle thereof shorter than that of the general phosphorescent compound helps to reduce the occurrence of triple-state quenching, thus increasing the luminous efficiency of an OLED.

### Example 7

Preparation of Compound (I-28):

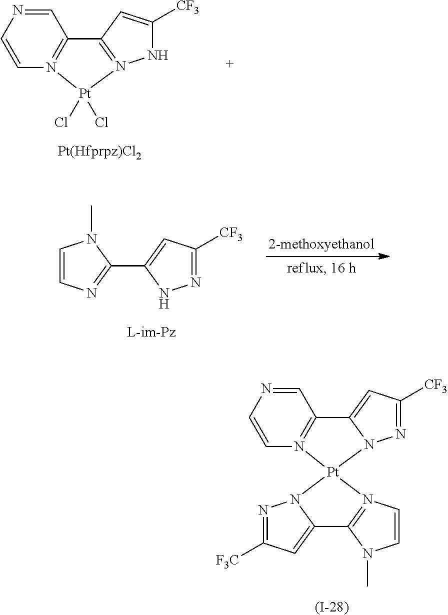

Pt(Hfprpz)Cl₂ (150 mg, 0.31 mmol) and L-im-Pz (70.7 mg, 0.33 mmol) were placed in a 25 mL round-bottomed flask, and then 2-methoxyethanol (15 mL) was added. Then, the mixture was heated until boiling. After reacting for 16 hours, the temperature was lowered to room temperature, and after the reaction was completed, deionized water was added, the mixture was filtered, washing was performed using diethylether and ethyl acetate, the precipitate was collected, and after sublimation, an orange-red powder was obtained (135 mg, yield: 69%).

Spectral information of compound (I-28): ¹H NMR (400 MHz, d₆-acetone, 298K): δ 10.10 (d, J=8.0 Hz, 1H), 8.14 (t, J=8.0 Hz, 1H), 7.88˜7.84 (m, 2H), 7.42 (t, J=7.6 Hz, 1H), 7.28 (d, J=1.6 Hz, 1H), 6.97 (s, 1H), 6.86 (s, 1H), 4.04 (s, 3H). ¹⁹F NMR (376 MHz, d₆-acetone, 298K): δ −60.92 (s, 3F), −61.14 (s, 3F).

### Example 8

Preparation of Compound (II-36):

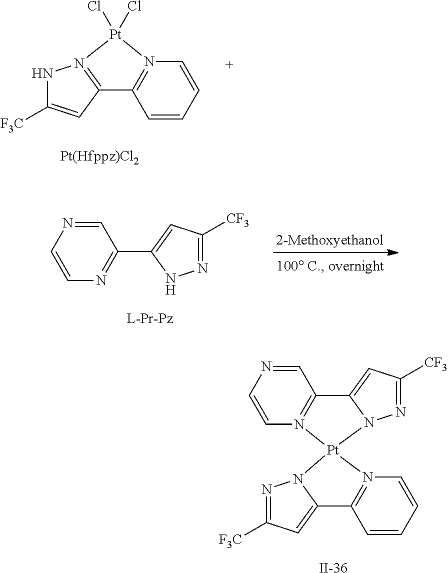

Pt(Hfppz)Cl₂ (295 mg, 0.6 mmol) and L-Pr-Pz (258 mg, 0.9 mmol) were placed in a 50 mL round-bottomed flask, and then 2-methoxyethanol (20 mL) was added. Then, the mixture was heated until boiling. After reacting for 16 hours, the temperature was lowered to room temperature, and after the reaction was completed, deionized water was added, the mixture was filtered, washing was performed using diethylether and ethyl acetate, the precipitate was collected, and after sublimation, a yellow-green solid (308 mg, yield: 73%) was obtained.

Spectral information of compound (I-36): ¹H NMR (700 MHz, d₈-THF, 323K): δ 10.42 (d, J=3.5 Hz, 1H), 10.40 (d, J=6.3 Hz, 1H), 9.12 (s, 1H), 8.63 (d, J=3.5 Hz, 1H), 8.06 (t, J=9.1 Hz, 1H), 7.83 (d, J=9.1 Hz, 1H), 7.44 (t, J=6.3 Hz), 7.11 (s, 1H), 6.98 (s, 1H); ¹⁹F NMR (658 MHz, d₈-THF, 323K): δ −61.71 (s, 3F), −61.76 (s, 3F). Anal. Calcd. for C₁₇H₉F₆N₇Pt: C, 32.91; H, 1.46; N, 15.80. Found: C, 32.93; H, 1.64; N, 15.91.

### Example 9

Preparation of Compound (II-38):

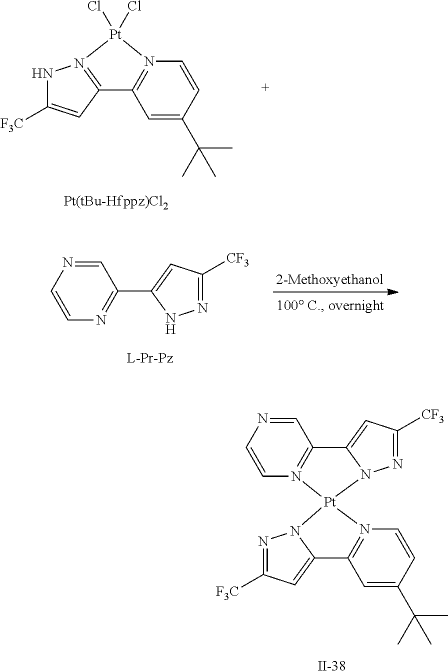

Pt(^{t}Bu-Hfppz)Cl₂ (150 mg, 0.3 mmol) and L-Pr-Pz (68.4 mg, 0.32 mmol) were placed in a 25 mL round-bottomed flask, and then 2-methoxyethanol (15 mL) was added. Then, the mixture was heated until boiling. After leaving the mixture overnight to react, the temperature was lowered to room temperature, and after the reaction was completed, deionized water was added, the mixture was filtered, washing was performed using diethylether and ethyl acetate, the precipitate was collected, and after sublimation, an orange-red powder was obtained (144 mg, yield: 75%).

Spectral information of compound (I-38): ¹H NMR (700 MHz, d₈-THF, 323K): δ 10.37 (dd, J=2.4 Hz, 0.8 Hz, 1H), 10.32 (d, J=4.4 Hz, 1H), 9.09 (d, J=0.8 Hz, 1H), 8.59 (d, J=2.4 Hz, 1H), 7.80 (d, J=1.6 Hz, 1H), 7.49 (dd, J=4.4 Hz, 1.6 Hz, 1H), 7.08 (s, 1H), 6.99 (s, 1H), 1.40 (s, 9H); ¹⁹F NMR (658 MHz, d₈-THF, 323K): δ −61.63 (s, 3F), −61.68 (s, 3F).

### Example 10

Preparation of Compound (II-72):

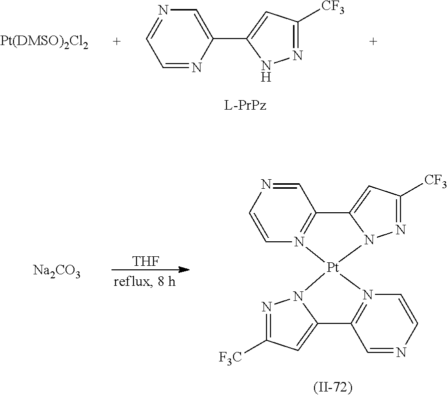

Pt(DMSO)₂Cl₂ (500 mg, 1.2 mmol), L-PrPz (524 mg, 2.5 mmol), and Na₂CO₃ (382 mg, 3.6 mmol) were placed in a 50 mL round-bottomed flask, and then THF (20 mL) was added. Then, the mixture was heated until boiling. After reacting for 8 hours, the temperature was lowered to room temperature, and after the reaction was completed, deionized water was added, the mixture was filtered, washing was performed using diethylether and ethyl acetate, the precipitate was collected, and after sublimation, a dark green powder (715 mg, yield: 96%) was obtained.

Spectral information of compound (I-72): ¹H NMR (600 MHz, d₈-THF, 323K): δ 10.37 (d, J=3 Hz, 2H), 9.20 (s, 2H), 8.72 (d, J=3 Hz, 2H), 7.19 (s, 2H); 19F NMR (564 MHz, d₈-THF, 323K): δ −61.86 (s, 6F). Anal. Calcd. for C₁₆H₈F₆N₈Pt: C, 30.93; H, 1.30; N, 18.03. Found: C, 31.08; H, 1.62; N, 17.82.

### Example 11

Preparation of Compound (II-17):

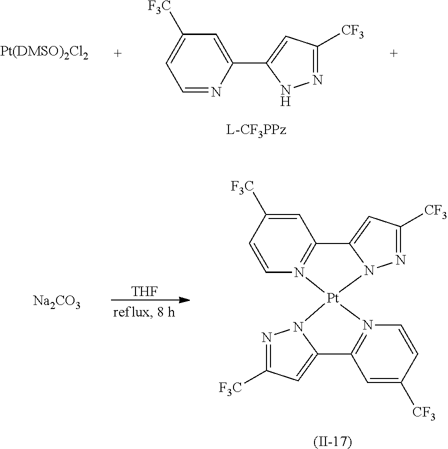

Pt(DMSO)₂Cl₂ (150 mg, 0.36 mmol), L-CF₃PPz (205 mg, 0.73 mmol), and Na₂CO₃ (113 mg, 1.07 mmol) were placed in a 25 mL round-bottomed flask, and then THF (10 mL) was added. Then, the mixture was heated until boiling. After reacting for 8 hours, the temperature was lowered to room temperature, and after the reaction was completed, deionized water was added, the mixture was filtered, washing was performed using diethylether and ethyl acetate, the precipitate was collected, and after sublimation, a dark green powder (173 mg, yield: 65%) was obtained.

¹H NMR (400 MHz, d₈-THF, 298K): δ 12.32 (d, J=8 Hz, 2H), 10.01 (s, 2H), 9.69 (d, J=8 Hz, 2H), 9.00 (s, 2H); 19F NMR (376 MHz, d₈-THF, 298K): δ −59.98 (s, 6F), −64.39 (s, 6F).

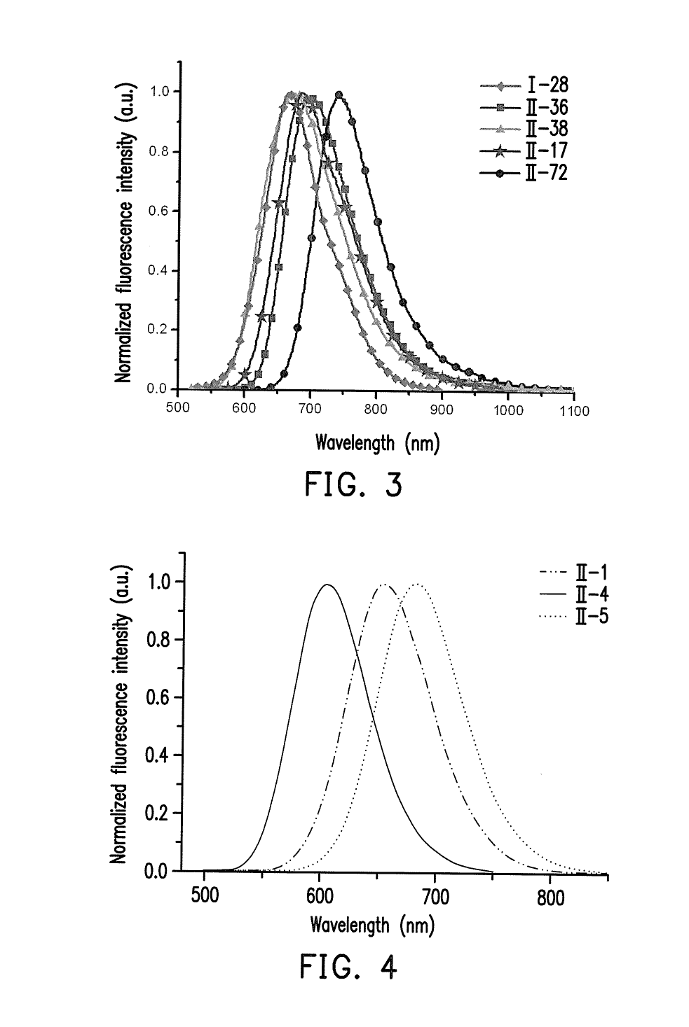

The phosphorescence spectrum of the platinum complexes synthesized in examples 7 to 11 (i.e., compound (I-28), compound (I-36), compound (I-38), compound (II-17), and compound (II-72)) is shown in FIG. 3, and the emission peak location (em λₘₐₓ), the quantum yield (φ), and the phosphorescence lifetime (τ) are listed in the following Table 3.

TABLE 3

| Compound | em λₘₐₓ (nm) | φ(%) | τ(ns) |
|---|---|---|---|
| (I-28) | 663 | 21 | 597 |
| (II-36) | 703 | 52 | 365 |
| (II-38) | 673 | 56 | 309 |
| (II-17) | 683 | 53 | 987 |
| (II-72) | 738 | 81 | 313 |

It can be known from FIG. 3 and Table 3 that, the five compounds have excellent luminous efficiency in the wavelength range of red light and near infra-red region, and the phosphorescence life cycle thereof shorter than that of the general phosphorescent compound helps to reduce the occurrence of triple-state quenching, thus increasing the luminous efficiency of an OLED.

### Example 12

Preparation of Compound (II-5):

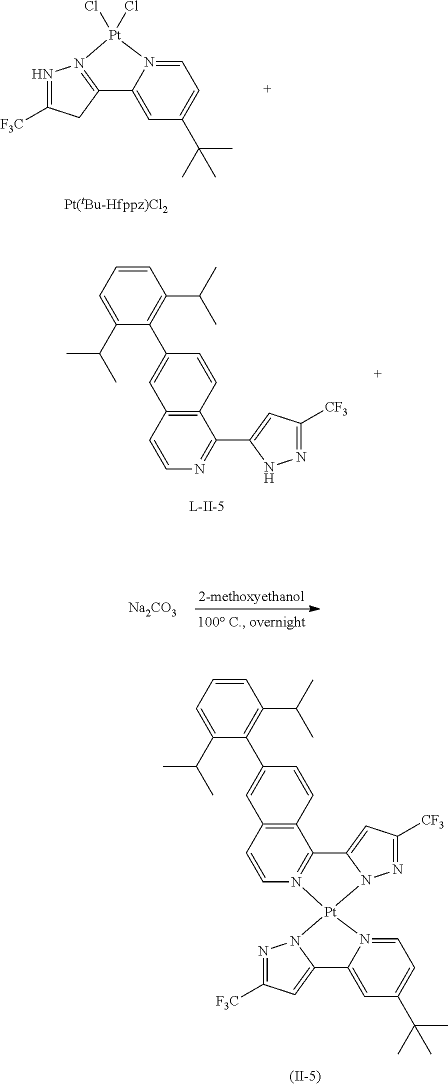

Pt(^{t}Bu-Hfppz)Cl₂ (200 mg, 37.44 mmol), L-II-5 (174 mg, 41.18 mmol), Na₂CO₃ (200 mg, 187.20 mmol), and 60 mL of 2-methoxyethanol were placed in a reaction flask. Then, the flask was heated to 100° C. to react overnight. The temperature was then cooled to room temperature, and a large amount of water was added to extract the solid. The precipitate was filtered, and the crude product was separated via column chromatography (SiO₂, dichloromethane) to obtain a red solid of 225 mg and a yield of 48%.

Spectral information of compound (II-5): ¹H NMR (400 MHz, CDCl₃, 298 K): δ 9.90 (br, 1H), 9.70 (br, 1H), 8.15 (br, 1H), 7.58 (s, 1H), 7.43 (m, 2H), 7.28 (m, 2H), 7.12 (br, 1H), 6.97 (br, 1H), 6.68 (br, 1H), 9.24 (br, 1H), 2.63 (q, J=8.0 Hz, 2H), 1.23 (s, 9H), 1.18 (m, 12H). ¹⁹F NMR (376 MHz, CDCl₃, 298 K): δ −61.7 (s, 3F), −61.8 (s, 3F). MS [FAB], m/z 887.2, M+.

### Example 13

Preparation of Compound (II-1):

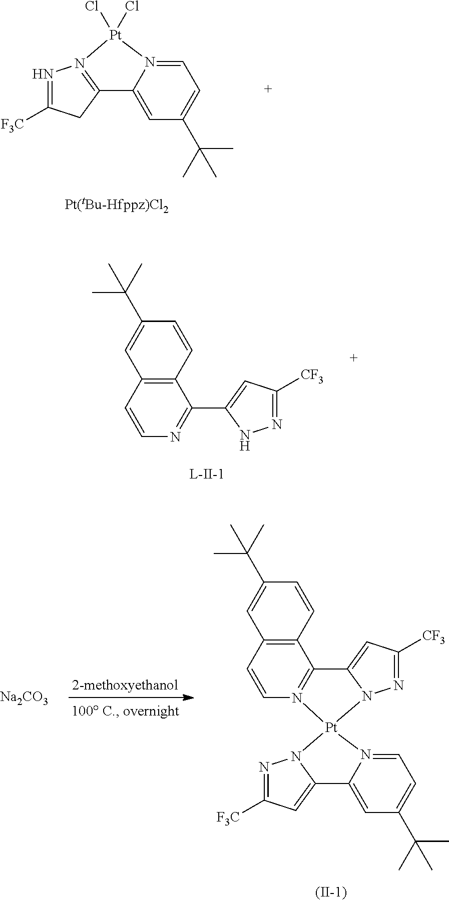

The reaction conditions are similar to the preparation method of compound (II-5), and the difference is that the ligand was changed from L-II-5 to L-II-1. Lastly, separation was performed using column chromatography (SiO₂, dichloromethane) to obtain an orange solid with a yield of 52%.

Spectral information of compound (II-1): ¹H NMR (400 MHz, CDCl₃, 298 K): δ 10.20 (d, J=8.0 Hz, 1H), 10.15 (d, J=4.0 Hz, 1H), 8.29 (d, J=8.0 Hz, 1H), 7.74 (m, 3H), 7.40 (s, 2H), 7.02 (s, 1H), 6.62 (s, 1H), 1.47 (s, 9H), 1.40 (s, 9H). ¹⁹F NMR (376 MHz, CDCl₃, 298 K): δ −60.78 (s, 3F), −61.76 (s, 3F). MS [FAB], m/z 782.9, M⁺.

### Example 14

Preparation of Compound (II-4):

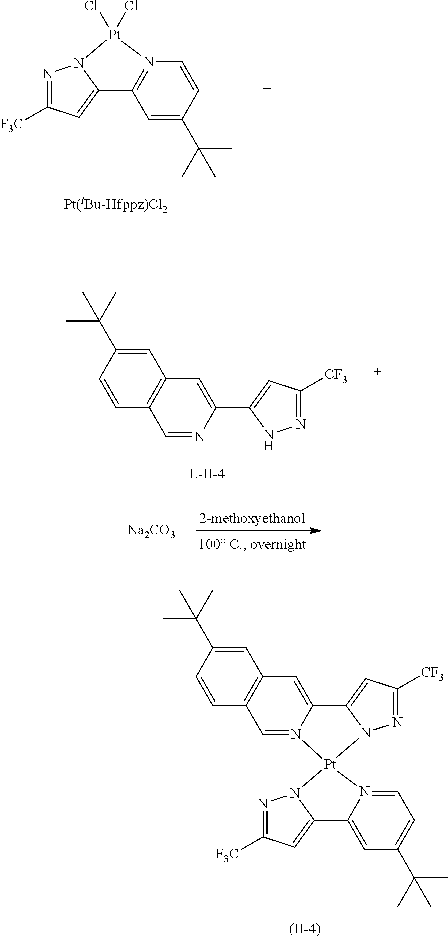

The reaction conditions are similar to the preparation method of compound (II-5), and the difference is that the ligand was changed from L-II-5 to L-II-4. Lastly, separation was performed using column chromatography (SiO₂, ethyl acetate/dichloromethane=1:4) to obtain an orange solid with a yield of 36%.

Spectral information of compound (II-4): ¹H NMR (400 MHz, CDCl₃, 298 K): δ 11.02 (s, 1H), 10.13 (s, 1H), 7.84 (d, J=7.2 Hz, 1H), 7.77 (d, J=9.2 Hz, 2H), 7.67 (d, J=8.0 Hz, 1H), 7.53 (s, 1H), 7.45 (s, 1H), 6.72 (s, 1H), 6.67 (br, 1H), 1.47 (s, 9H), 1.42 (s, 9H). ¹⁹F NMR (376 MHz, CDCl₃, 298 K): δ −60.83 (s, 3F), −61.02 (s, 3F). MS [FAB], m/z 781.9, M⁺.

The phosphorescence spectrum of the platinum complexes synthesized in examples 12 to 14 (i.e., compound (II-1), compound (II-4), and compound (II-5)) is shown in FIG. 4, and the emission peak location (em λₘₐₓ) and the quantum yield (φ) are listed in the following Table 4.

TABLE 4

| Compound | em λₘₐₓ (nm) | φ(%) |
|---|---|---|
| (II-1) | 652 | 54 |
| (II-4) | 604 | 64 |
| (II-5) | 684 | 44 |

It can be known from FIG. 4 and Table 4 that, the three compounds have excellent luminous efficiency in the wavelength range of orange light.

In the following, the OLED of an example of the invention is described with reference to figures.

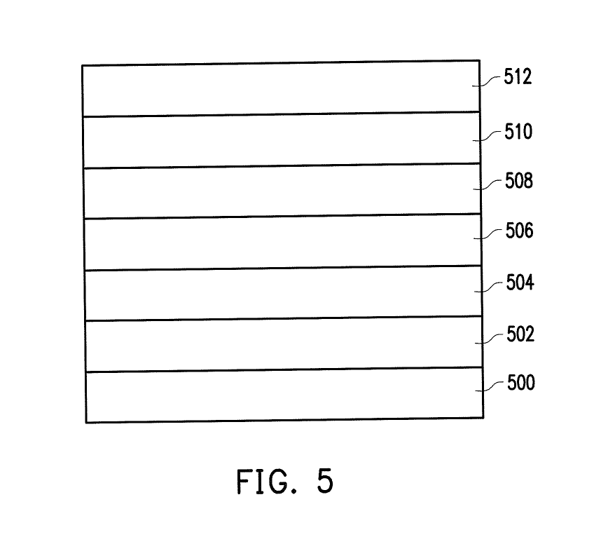

FIG. 5 is a cross-sectional schematic of an OLED according to an example of the invention.

Referring to FIG. 5, the structure thereof includes, from bottom to top, an anode 500, a hole-injection layer 502, a hole-transport layer 504, an electron-blocking layer 506, a light-emitting layer 508, an electron-transport layer 510, and a cathode 512. The material of the anode 500 is ITO, the material of the hole-injection layer 502 is 1,4,5,8,9,11-hexaazatriphenylenehexacarbonitrile (HATCN), the material of the hole-transport layer 504 is N,N′-di(naphthalen-1-yl)-N,N′-diphenylbiphenyl-4,4′-diamine (NPB), the material of the electron-blocking layer 506 is 1,3-bis(N-carbazolyl)benzene (mCP), the material of the light-emitting layer 508 is compound (II-53) of the invention, the material of the electron-transport layer 510 is 1,3,5-tris[2-N-phenylbenzimidazol-z-yl]benzene (TPBi), and the material of the cathode 512 is Liq/Al.

### Example 15

First, HATCN (10 nm) was deposited on ITO used as the anode in order to form a hole-injection layer. Then, NPB (35 nm) was deposited on the hole-injection layer to form a hole-transport layer. Then, mCP (15 nm) was deposited on the hole-transport layer to form an electron-blocking layer. Then, compound (II-53) (20 nm) was deposited on the electron-blocking layer to form a light-emitting layer. Then, TPBi (40 nm) was deposited on the light-emitting layer to form an electron-transport layer. Then, Liq (2 nm) and Al were deposited on the electron-transport layer in order to form a cathode. At this point, the manufacture of the OLED of the present example was complete. The OLED has the following structure: ITO/HATCN (10 nm)/NPB (35 nm)/mCP (15 nm)/compound (II-53) (20 nm)/TPBi (40 nm)/Liq (2 nm)/Al.

### Example 16

The OLED was formed using a similar method to experimental example 15, and the difference thereof is only in that the thickness of TPBi deposition was 50 nm. The OLED has the following structure: ITO/HATCN (10 nm)/NPB (35 nm)/mCP (15 nm)/compound (II-53) (20 nm)/TPBi (50 nm)/Liq (2 nm)/Al.

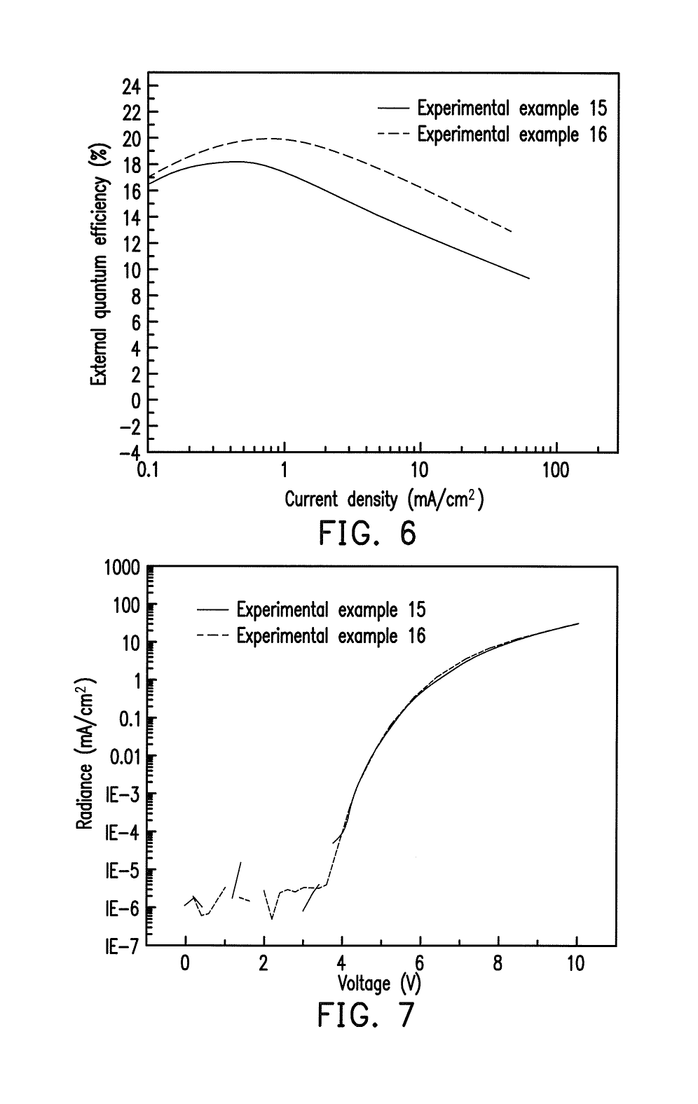

FIG. 6 shows a current density-external quantum efficiency curve of the OLEDs of experimental example 15 and experimental example 16.

It can be known from the results of FIG. 6 that, the maximum external quantum efficiency of the OLEDs of experimental example 15 and experimental example 16 can respectively reach about 18% and 20%, significantly higher than the known OLED (about 14%).

FIG. 7 shows a voltage-radiation curve of the OLEDs of experimental example 15 and experimental example 16.

It can be known from the results of FIG. 7 that, since the OLEDs of experimental example 15 and experimental example 16 have the platinum complex of the invention, the OLEDs of experimental example 15 and experimental example 16 have excellent radiance.

Based on the above, in the platinum complex of the invention, the nitrogen-containing heterocyclic bidentate ligand having a specific structure can maintain nitrogen-platinum bonding and enhance the properties of transition energy levels, and has shorter half life. As a result, blue, green, and red light to near-infrared light materials having high luminous efficiency can be obtained. Moreover, the OLED made from the platinum complex of the invention has excellent external quantum efficiency and radiance.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A platinum complex represented by general formula (I) or general formula (II) below: 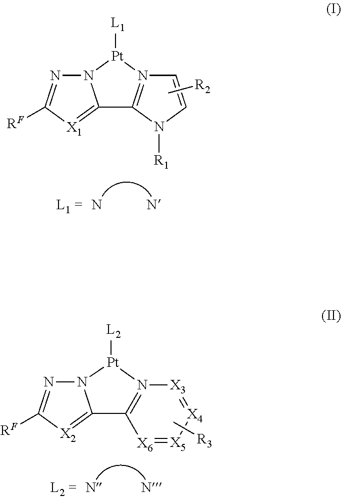
wherein L₁ and L₂ are nitrogen-containing heterocyclic bidentate ligands;
R₁ is a substituted or unsubstituted C₁-C₁₂ alkyl group, or a substituted or unsubstituted C₆-C₁₂ aryl group;
R₂ is hydrogen, halogen, a substituted or unsubstituted C₁-C₁₂ alkyl group, or a substituted or unsubstituted C₆-C₁₂ aryl group;
R₃ is hydrogen, a substituted or unsubstituted C₁-C₁₂ alkyl group, or a substituted or unsubstituted C₆-C₁₂ aryl group;
R^{F} is —CₘF₂ₘ₊₁, m is an integer of 1 to 3; and
X₁ to X₆ are independently carbon or nitrogen, provided that when X₆ is nitrogen and X₃, X₄, and X₅ are carbon, R₃ is not hydrogen.

2. The platinum complex of claim 1, wherein at most one of X₃ to X₆ is nitrogen.

3. The platinum complex of claim 1, wherein L₁ comprises a first nitrogen-containing heterocyclic bidentate ligand containing two five-membered rings or a second nitrogen-containing heterocyclic bidentate ligand containing one five-membered ring and one six-membered ring.

4. The platinum complex of claim 3, wherein L₁ is the first nitrogen-containing heterocyclic bidentate ligand containing two five-membered rings, and X₁ is carbon.

5. The platinum complex of claim 4, wherein a structure thereof is represented by either one of formula (I-1) to formula (I-9):

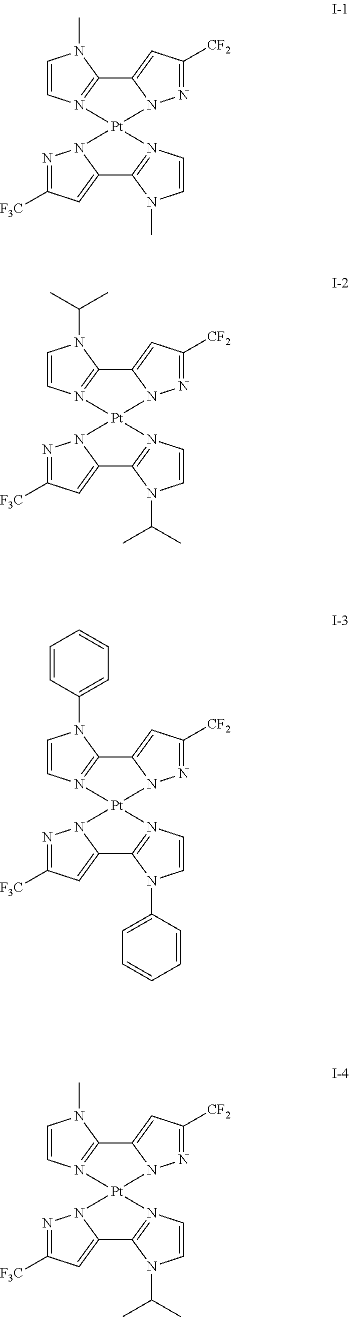

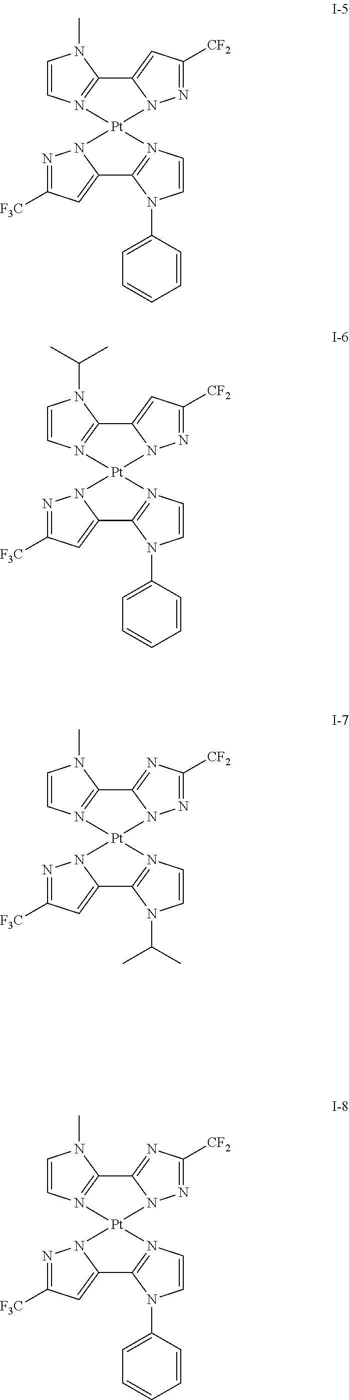

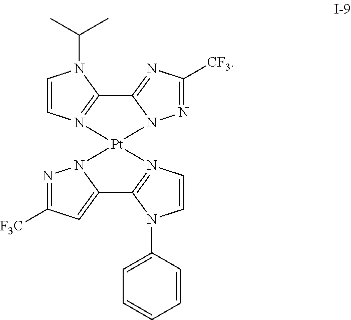

6. The platinum complex of claim 3, wherein L₁ is the first nitrogen-containing heterocyclic bidentate ligand containing two five-membered rings, and X₁ is nitrogen.

7. The platinum complex of claim 6, wherein a structure thereof is represented by either one of formula (I-10) to formula (I-21):

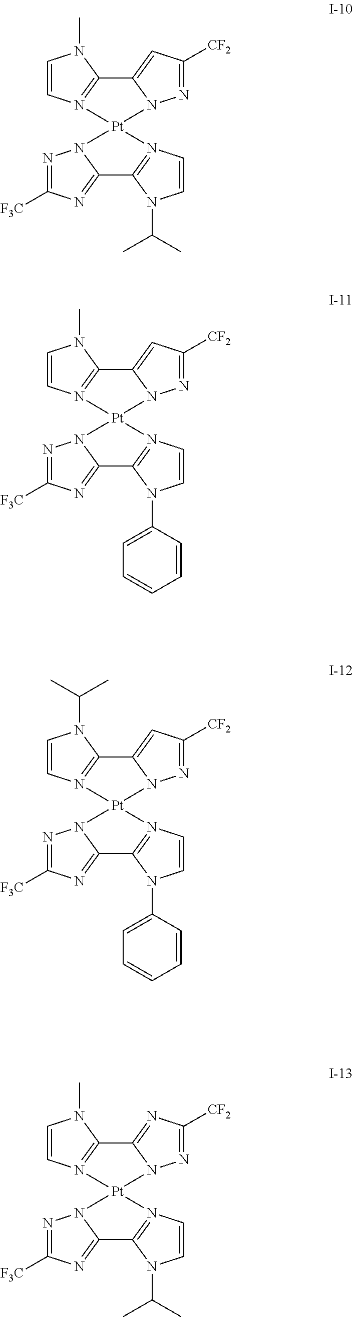

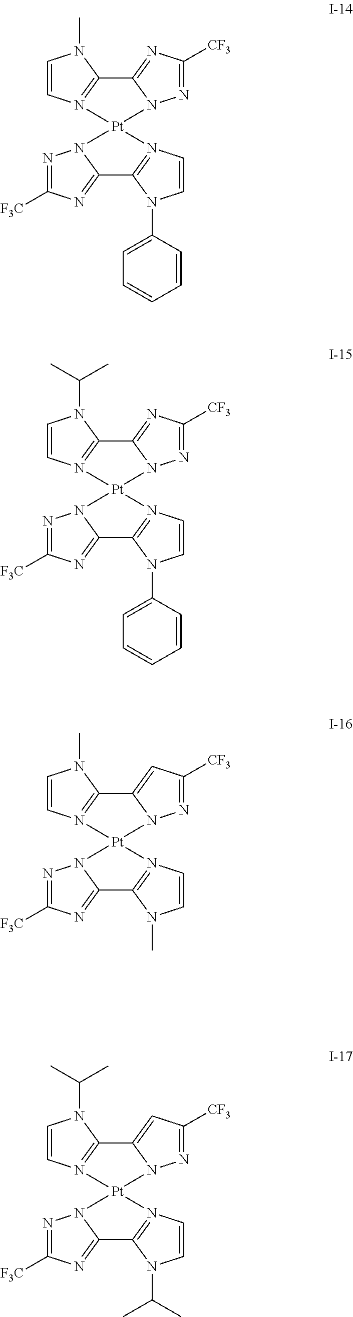

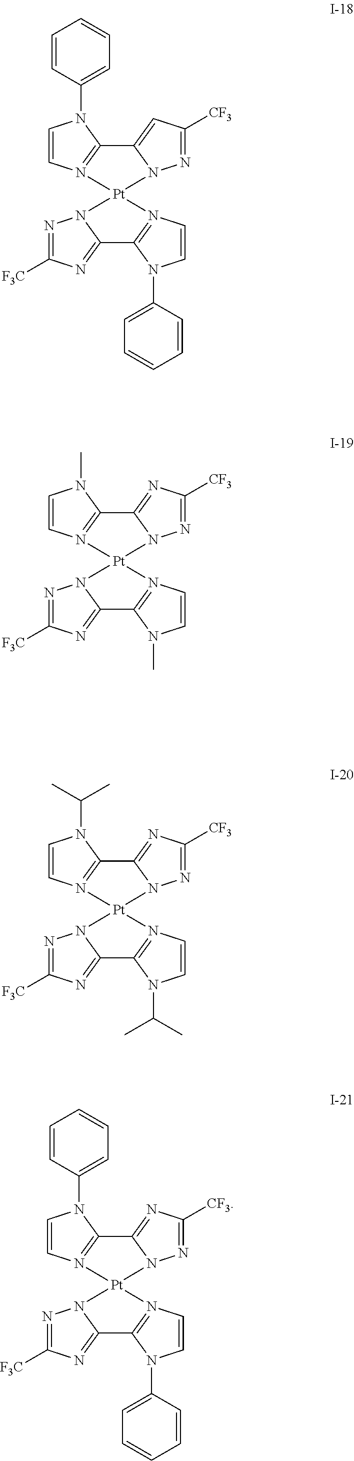

8. The platinum complex of claim 3, wherein L₁ is the second nitrogen-containing heterocyclic bidentate ligand containing one five-membered ring and one six-membered ring, and X₁ is carbon.

9. The platinum complex of claim 8, wherein a structure thereof is represented by either one of formula (I-22) to formula (I-75):

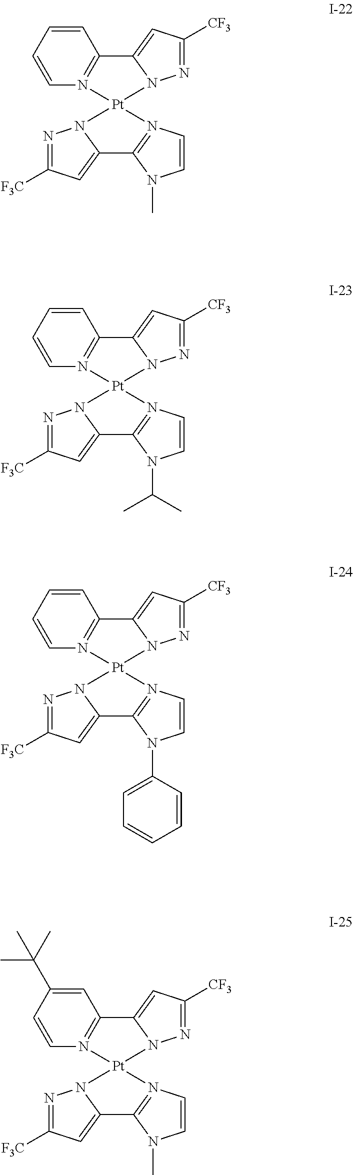

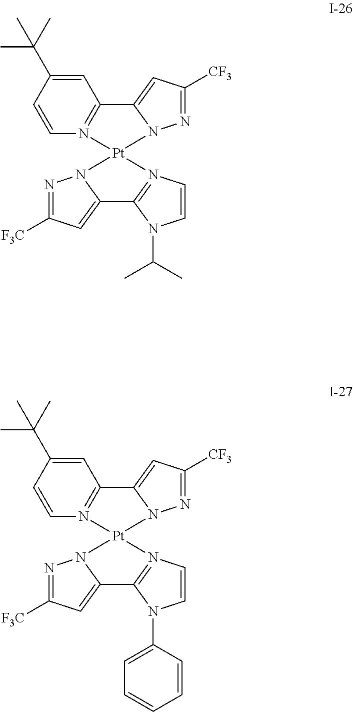

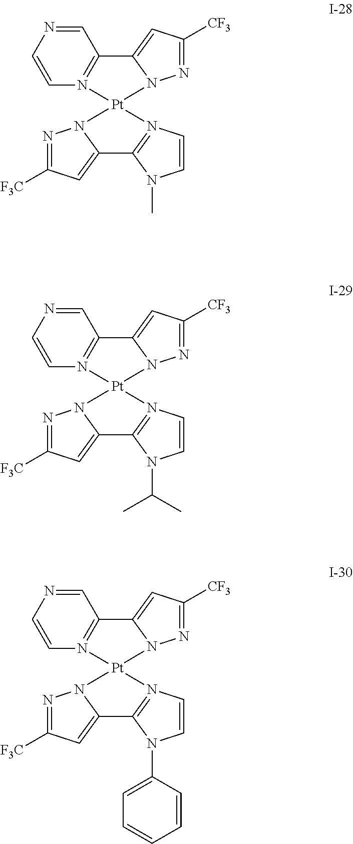

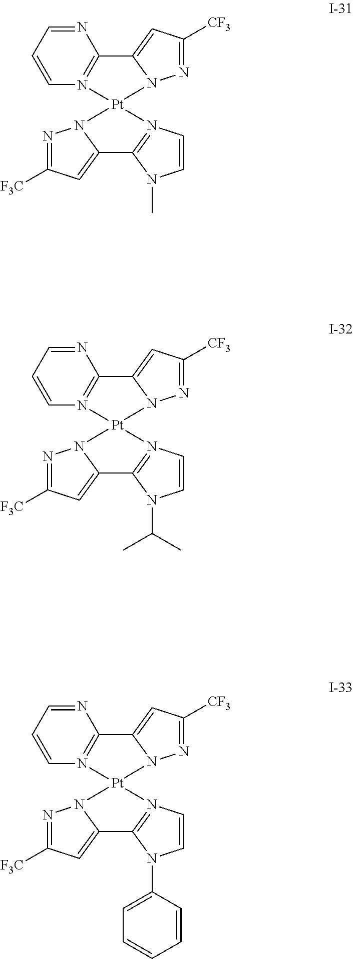

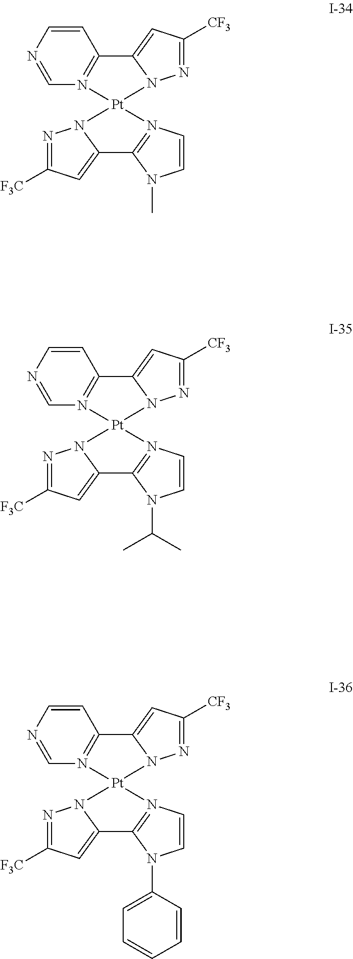

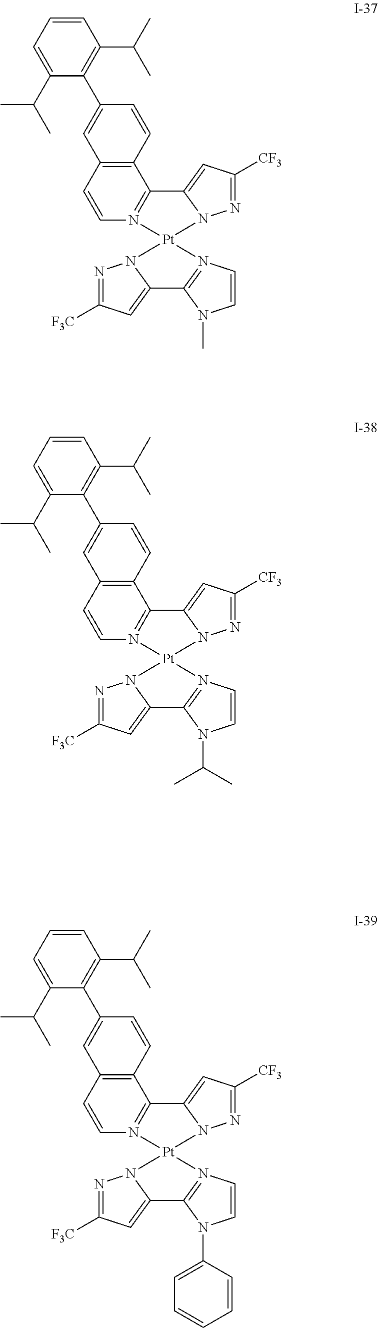

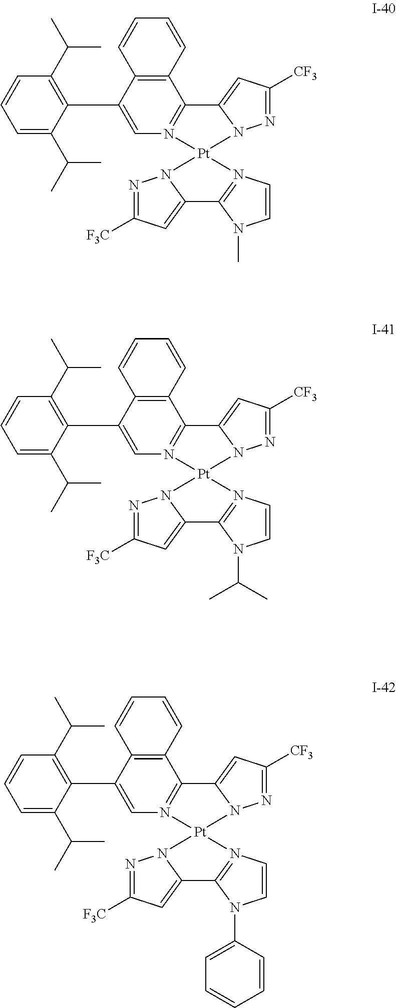

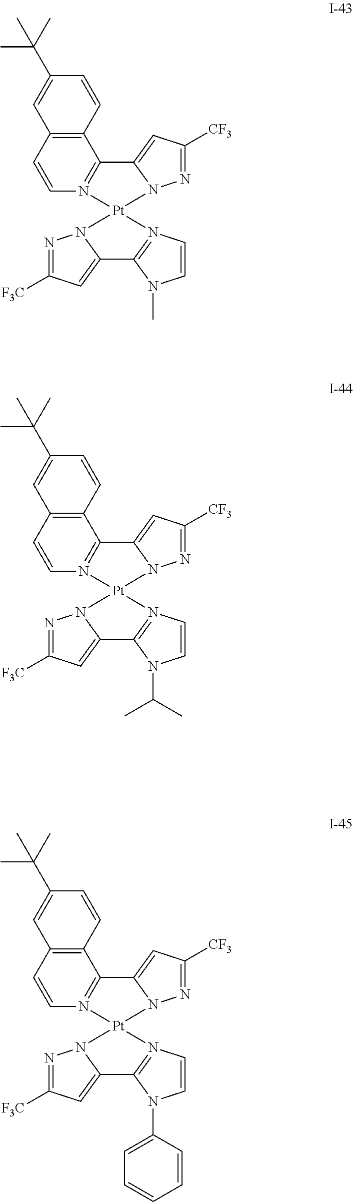

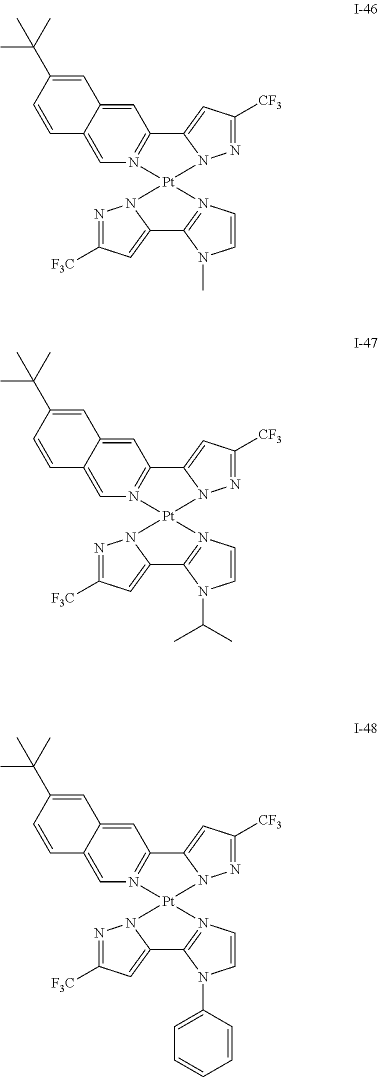

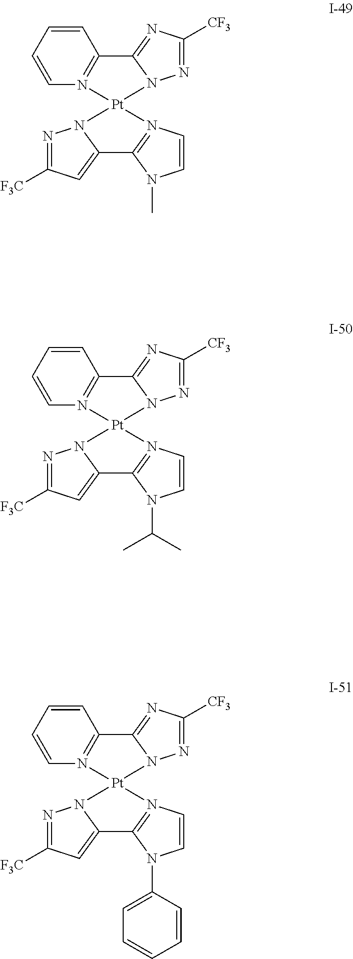

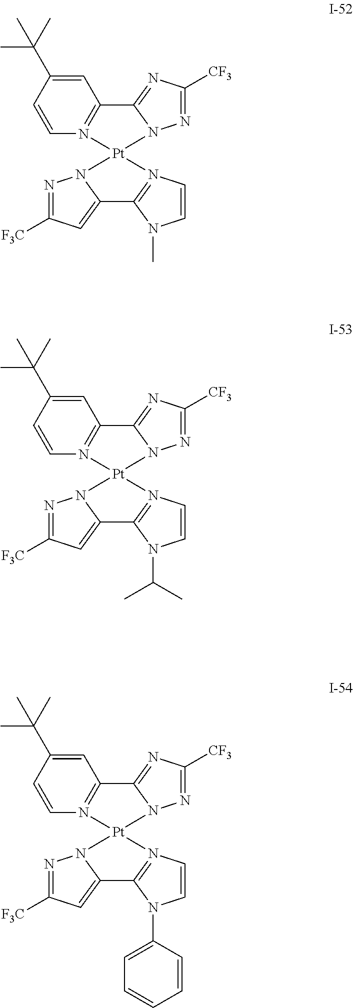

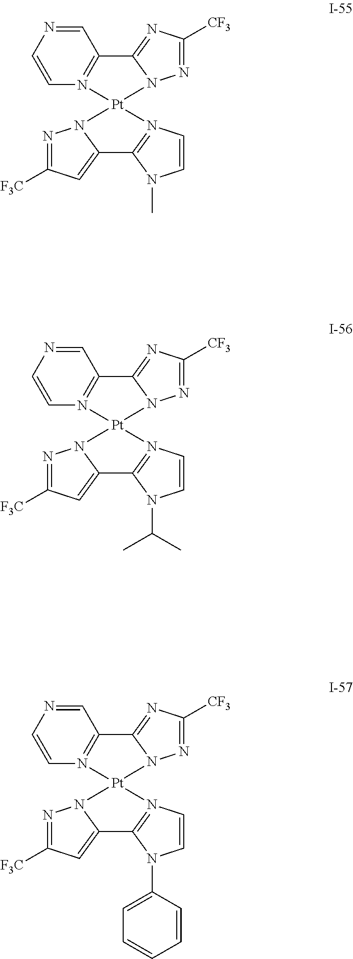

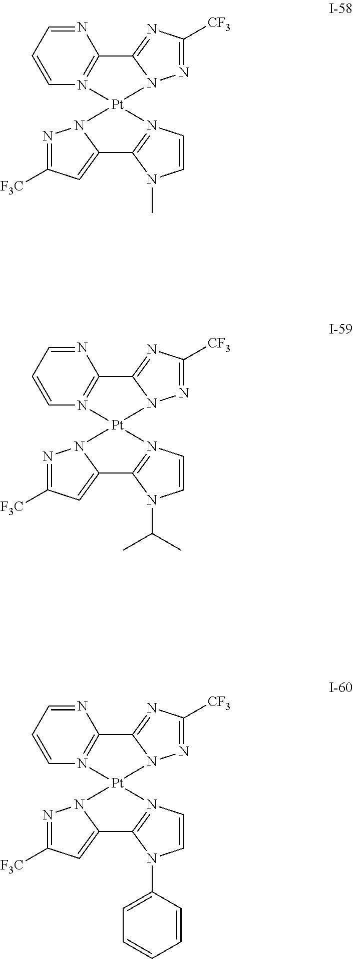

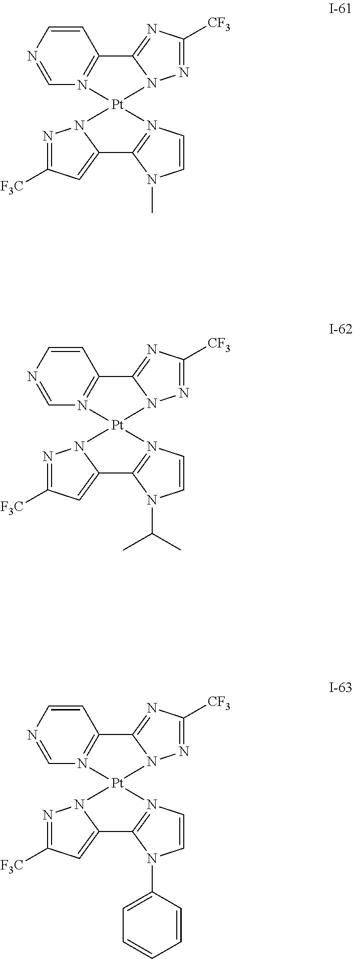

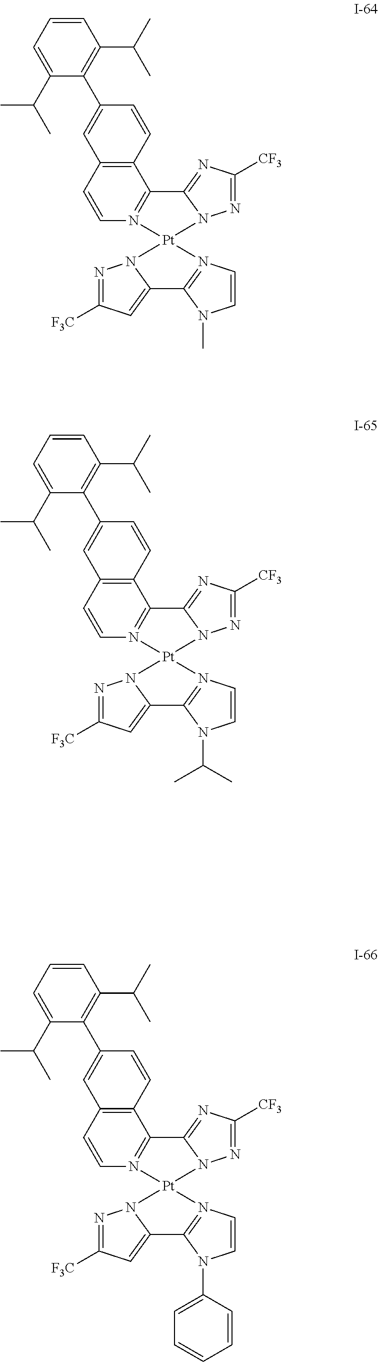

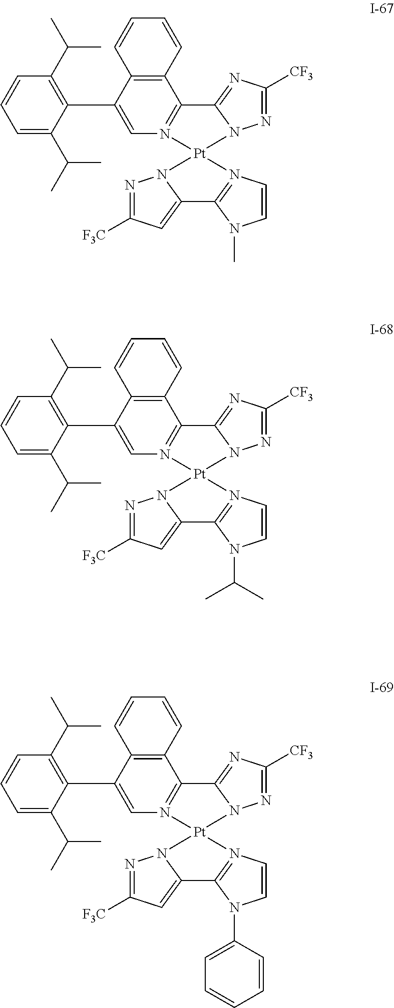

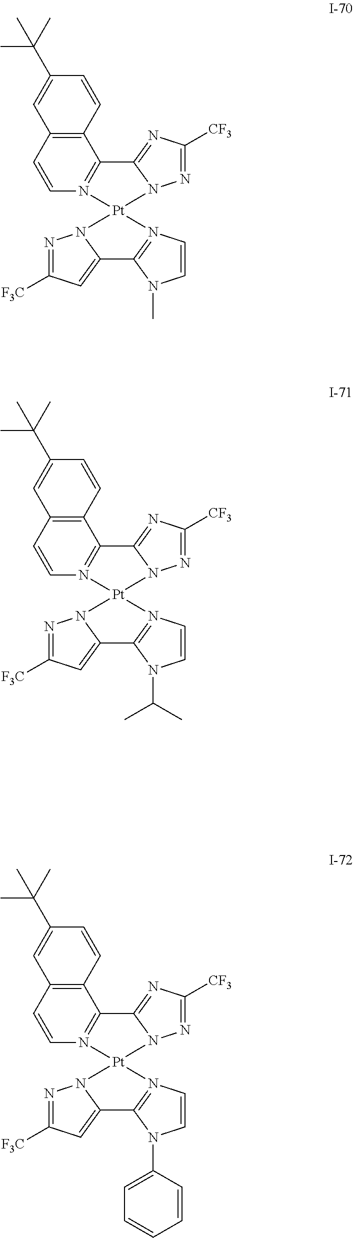

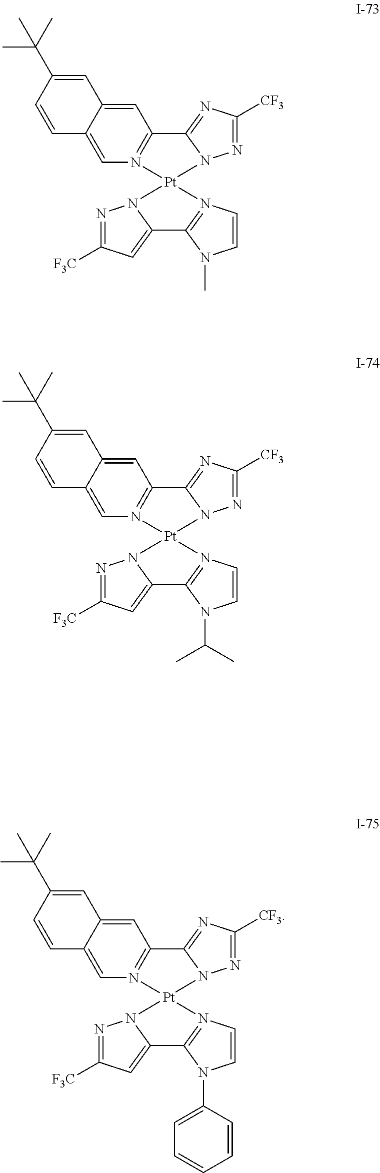

10. The platinum complex of claim 3, wherein L₁ is the second nitrogen-containing heterocyclic bidentate ligand containing one five-membered ring and one six-membered ring, and X₁ is nitrogen.

11. The platinum complex of claim 10, wherein a structure thereof is represented by either one of formula (I-76) to formula (I-129):

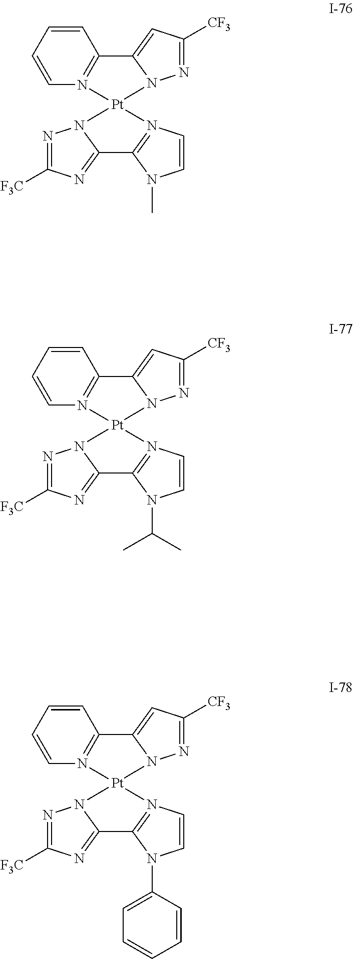

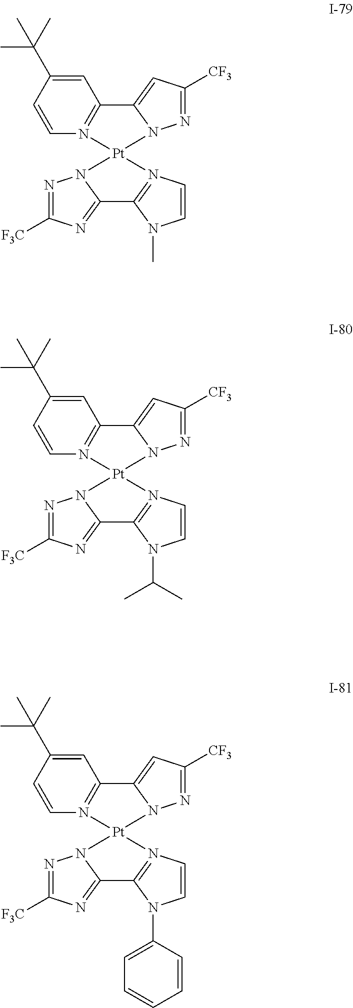

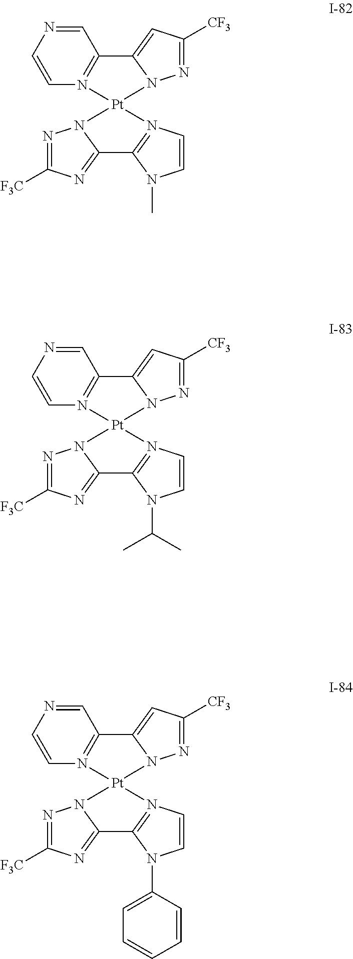

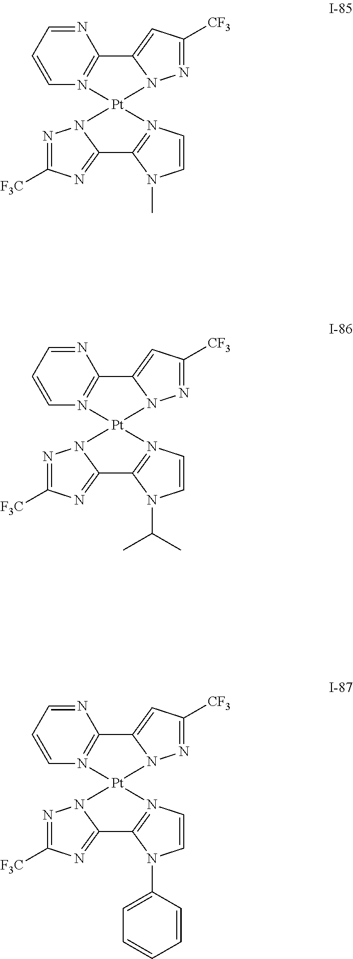

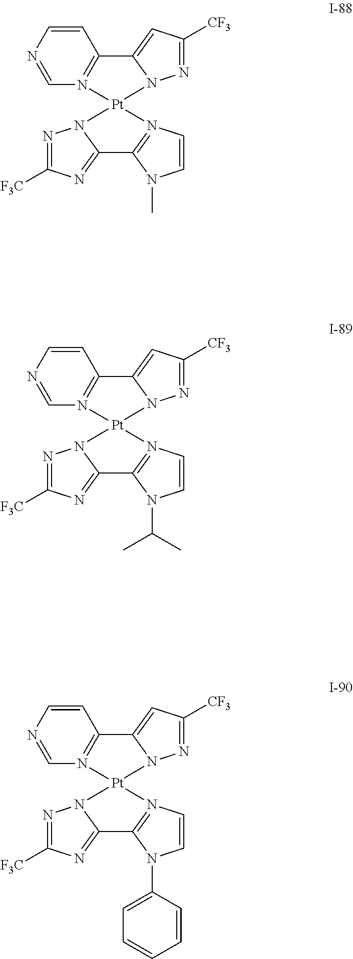

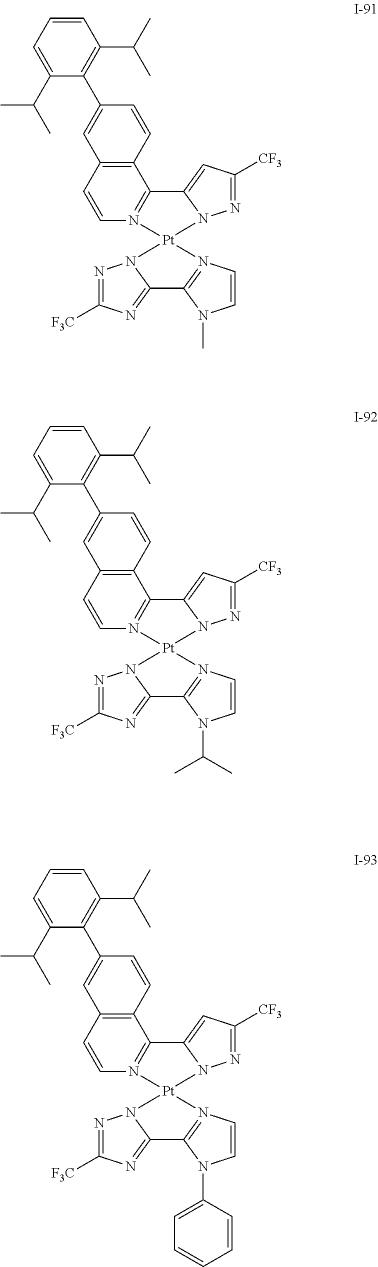

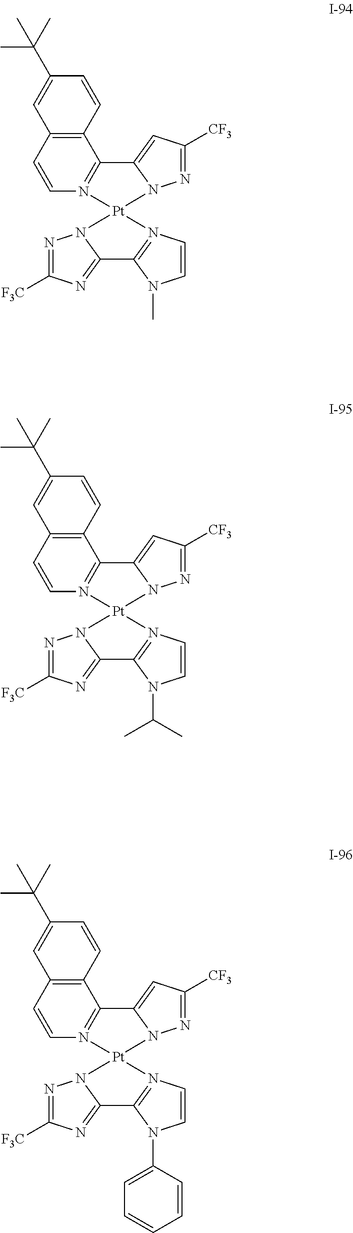

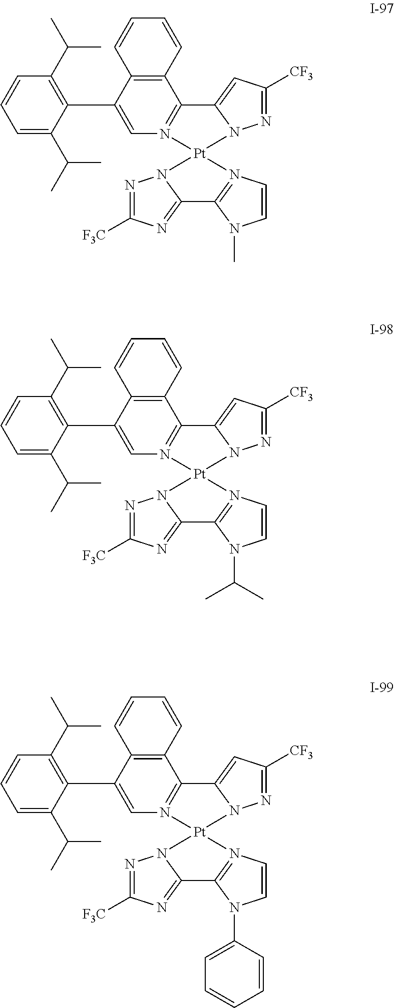

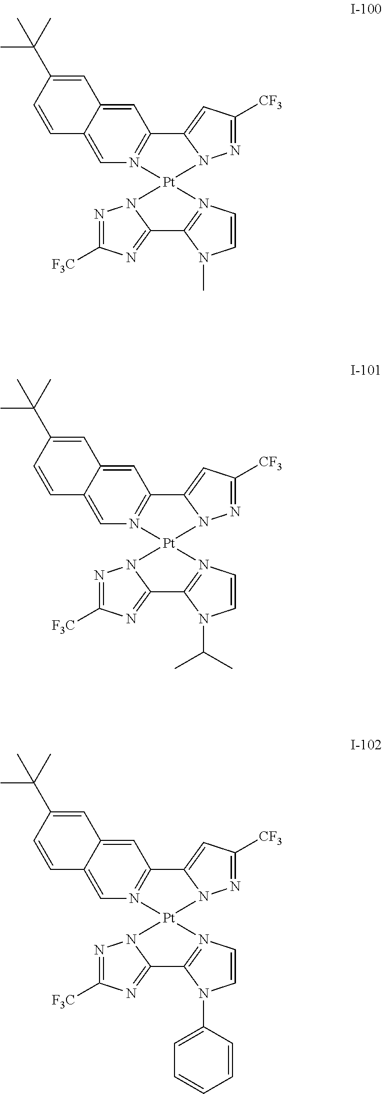

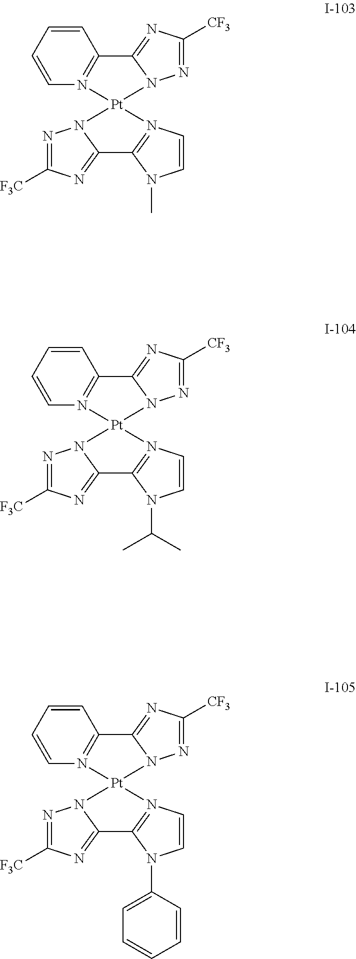

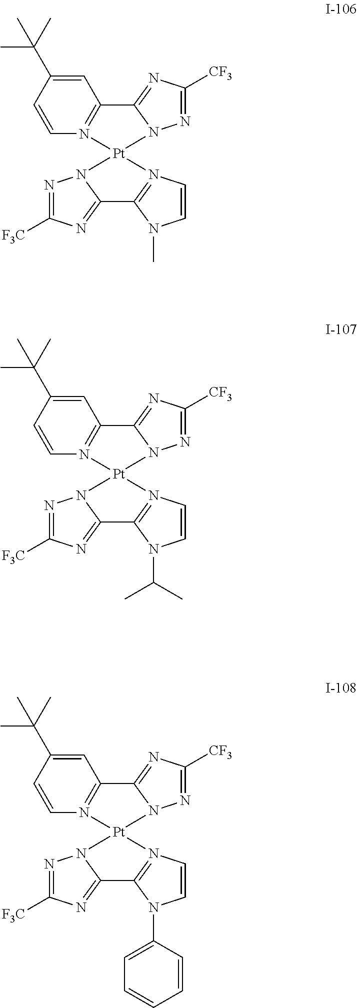

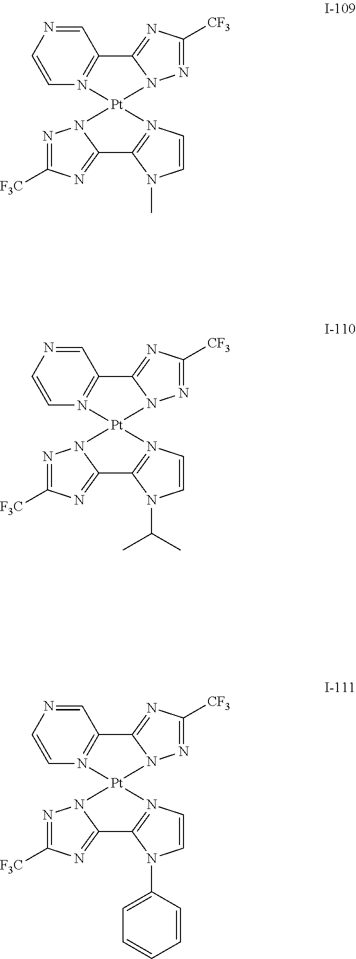

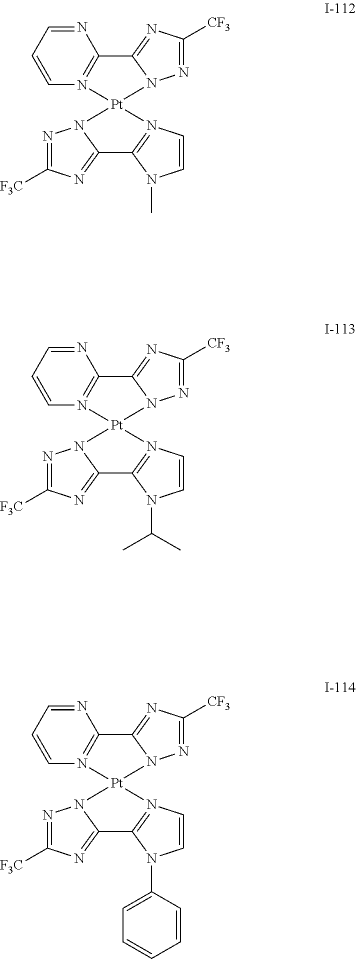

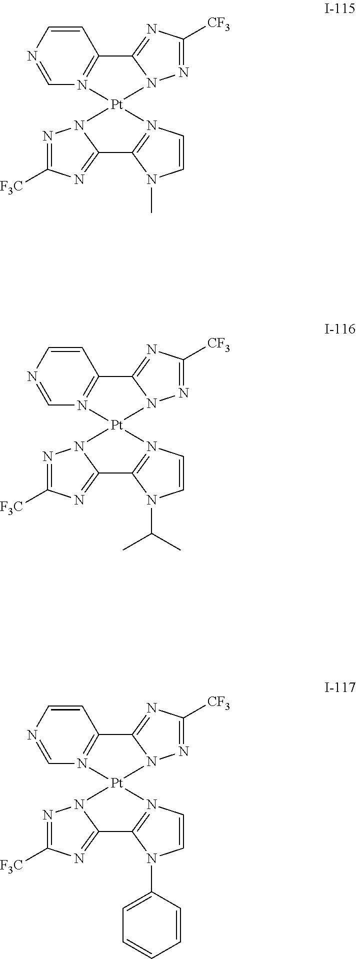

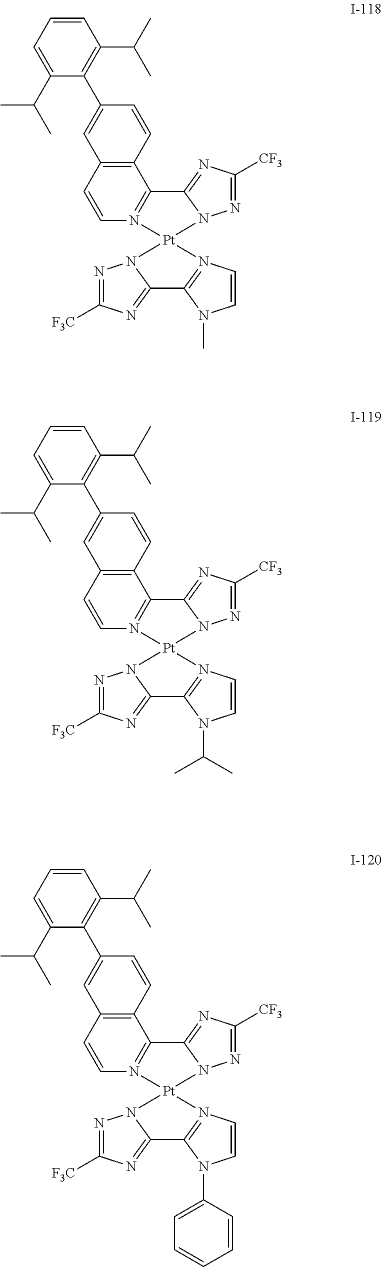

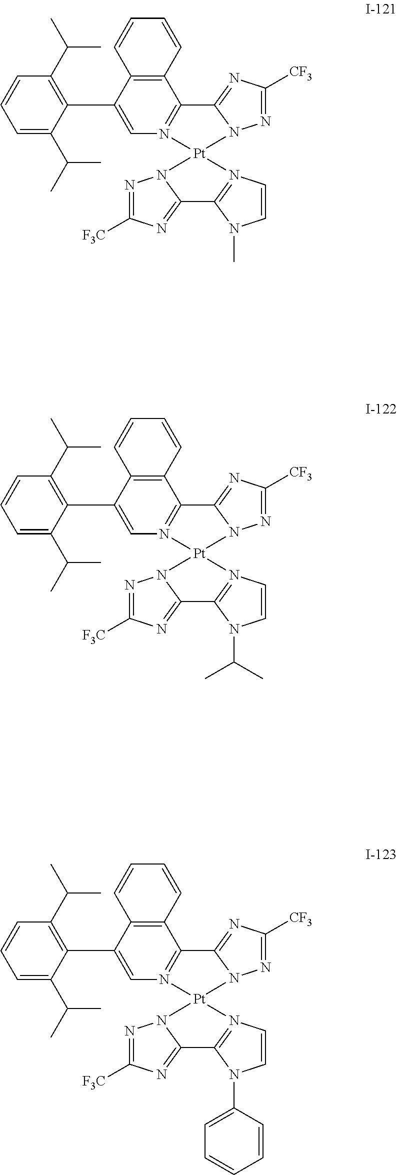

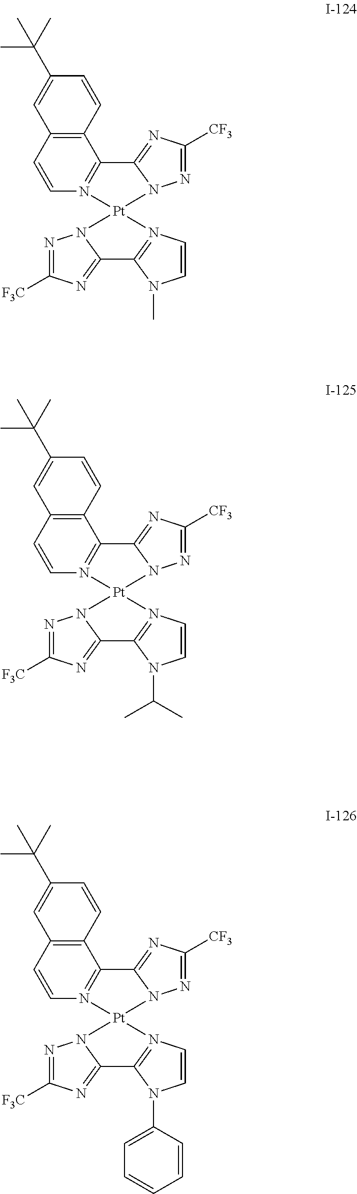

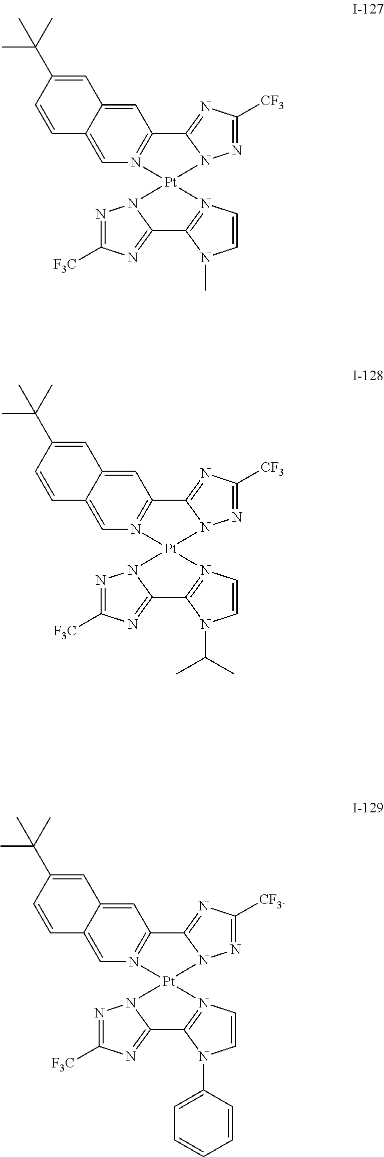

12. The platinum complex of claim 1, wherein L₂ comprises a third nitrogen-containing heterocyclic bidentate ligand containing one five-membered ring and one six-membered ring.

13. The platinum complex of claim 12, wherein a number of nitrogen atoms of L₂ is 3 or less.

14. The platinum complex of claim 13, wherein a structure thereof is represented by either one of formula (II-1) to formula (II-35):

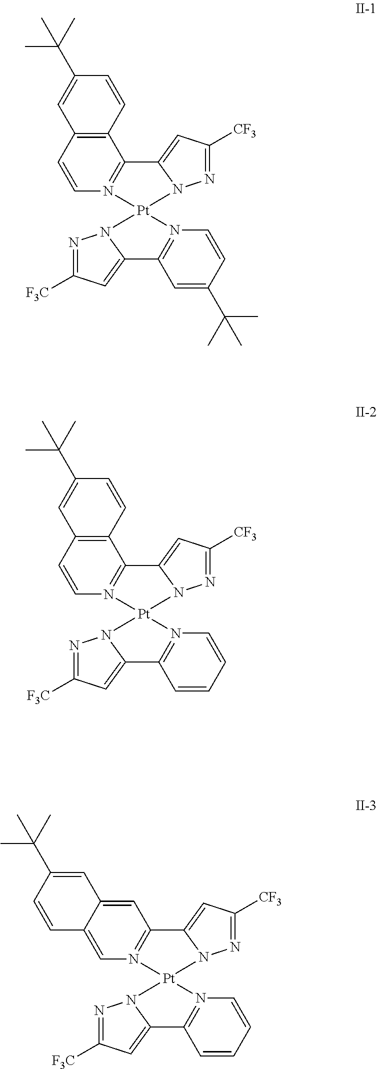

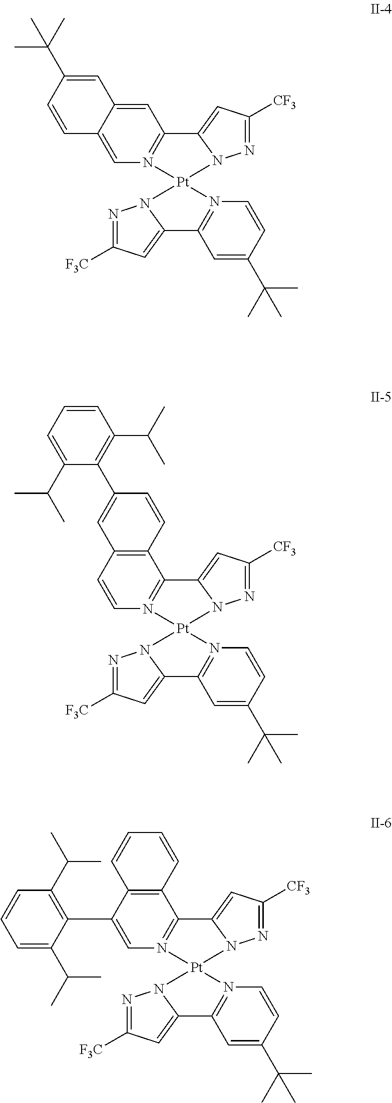

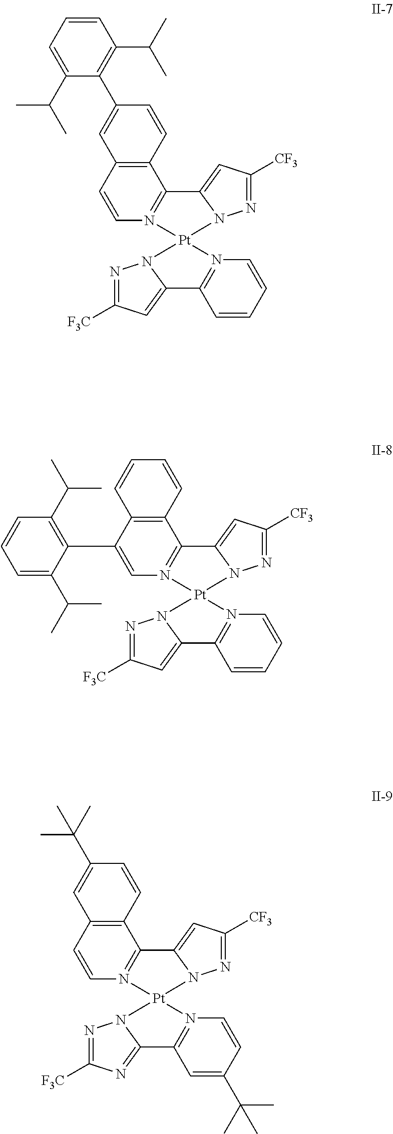

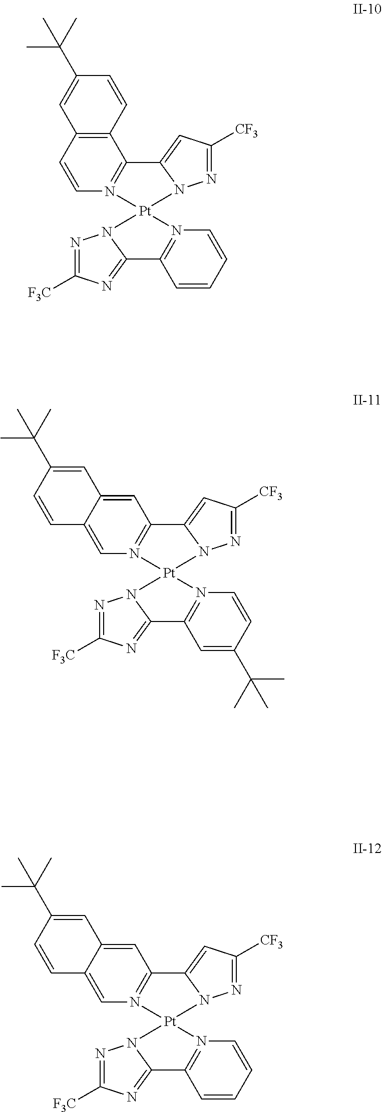

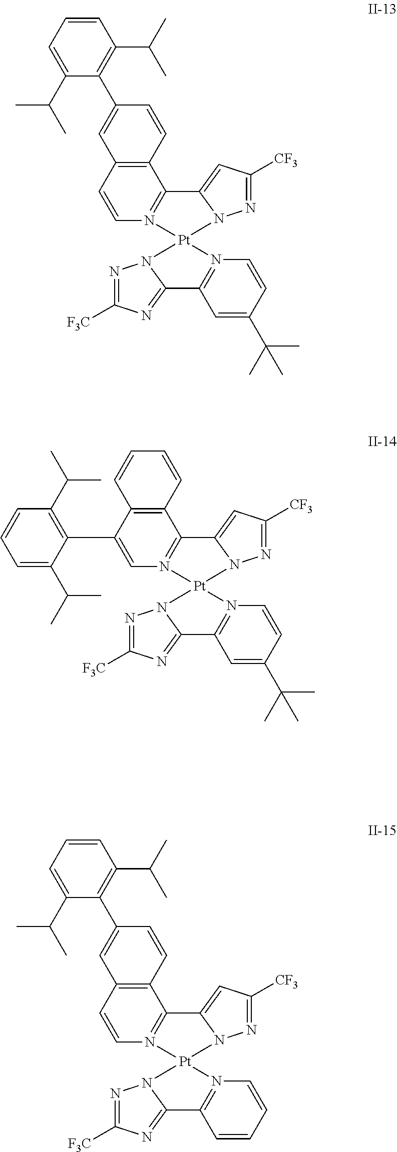

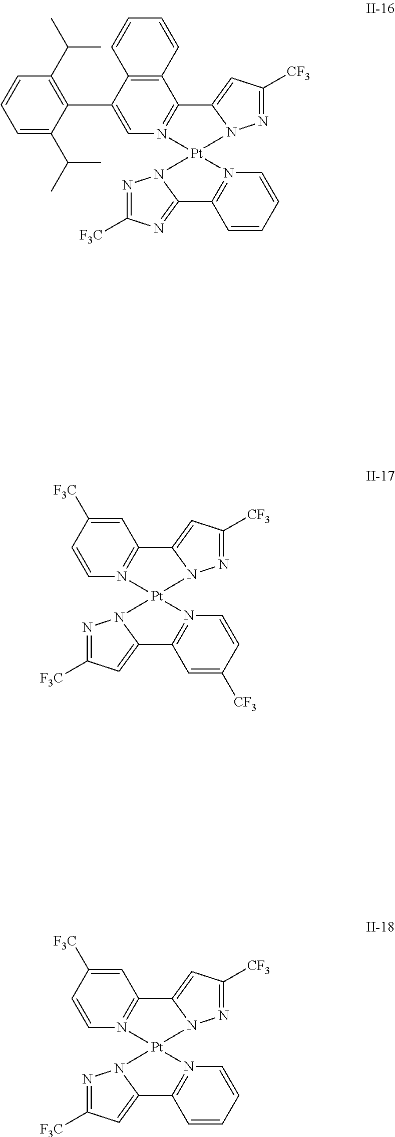

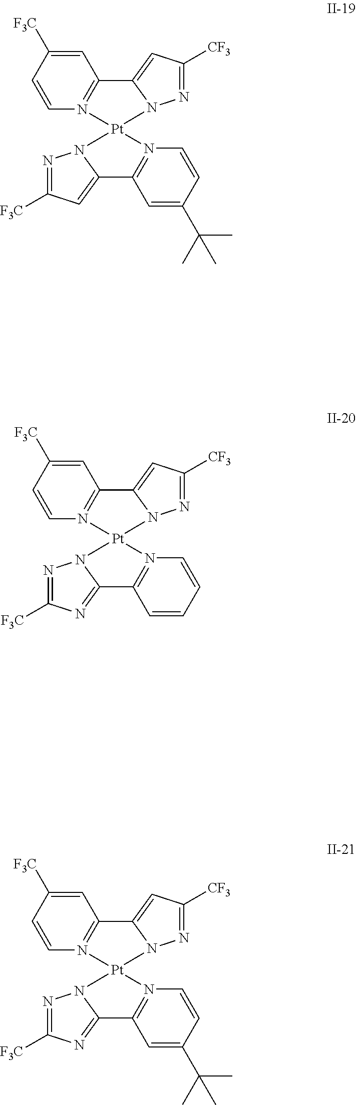

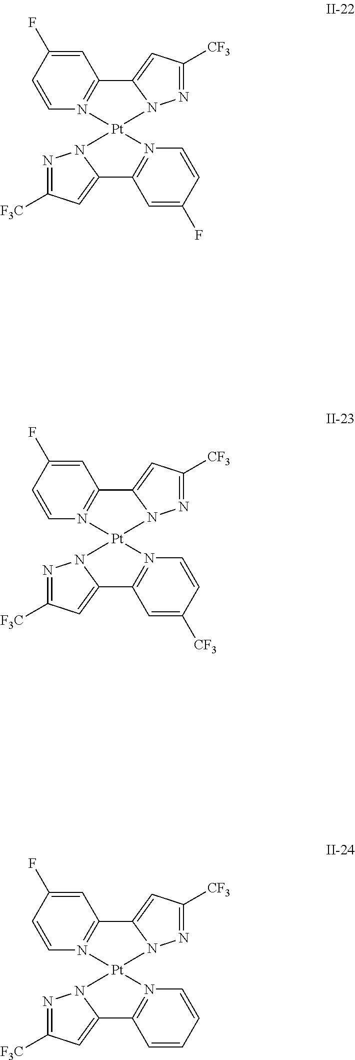

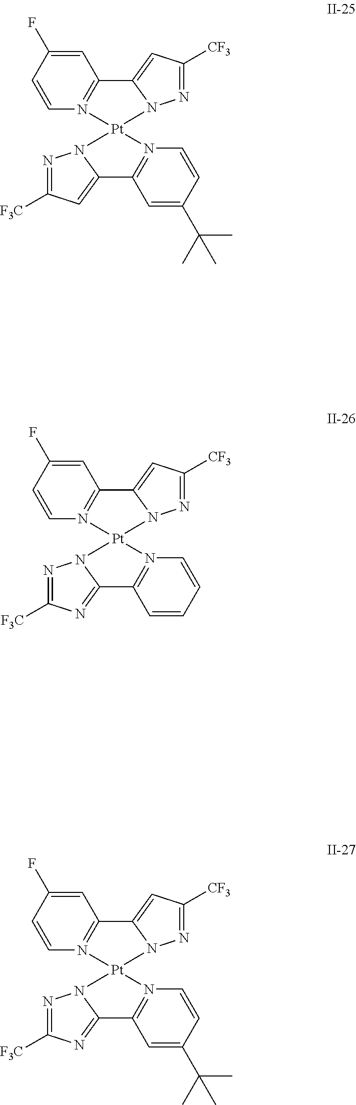

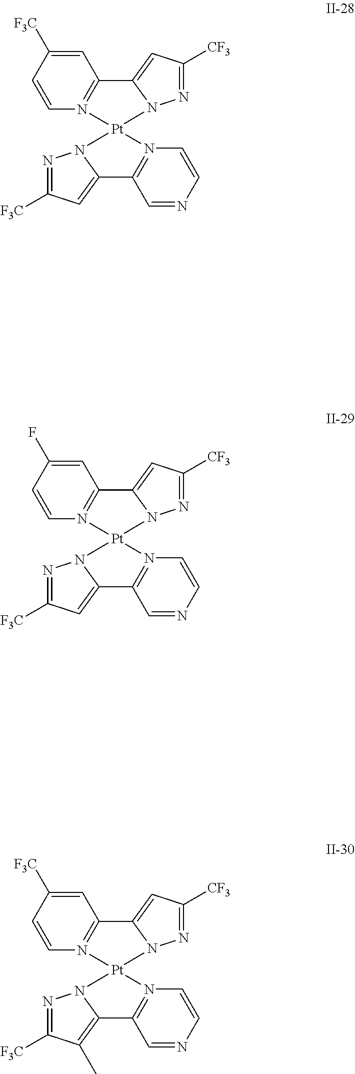

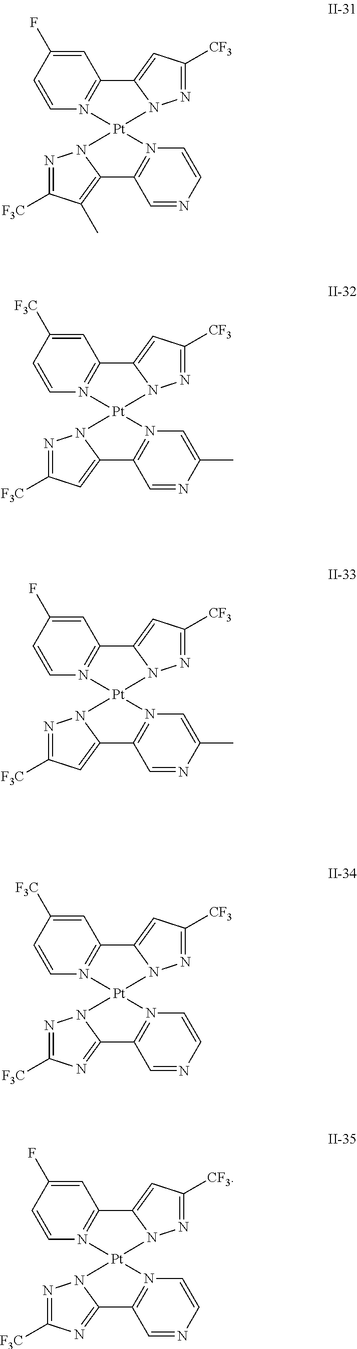

15. The platinum complex of claim 12, wherein a number of nitrogen atoms on L₂ is 4 or more.

16. The platinum complex of claim 15, wherein a structure thereof is represented by either one of formula (II-36) to formula (II-115):

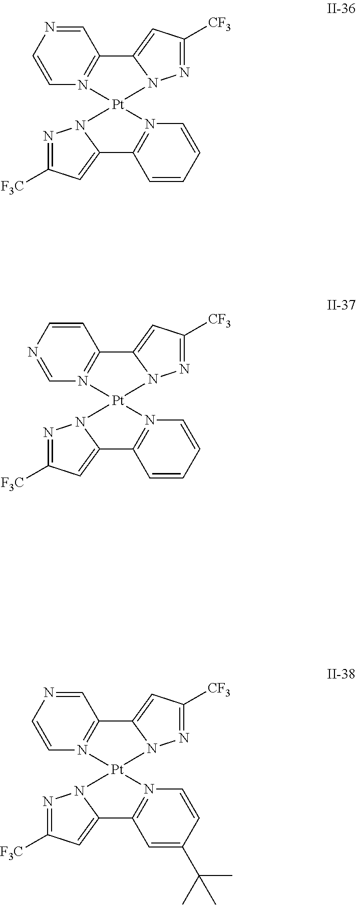

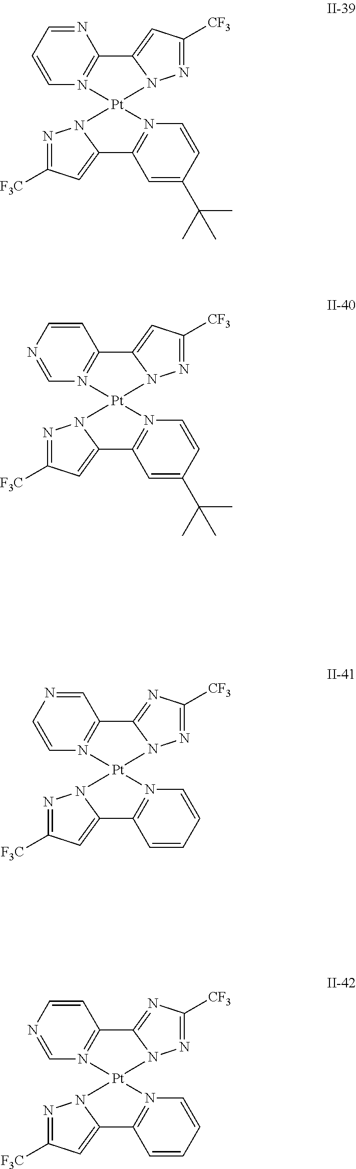

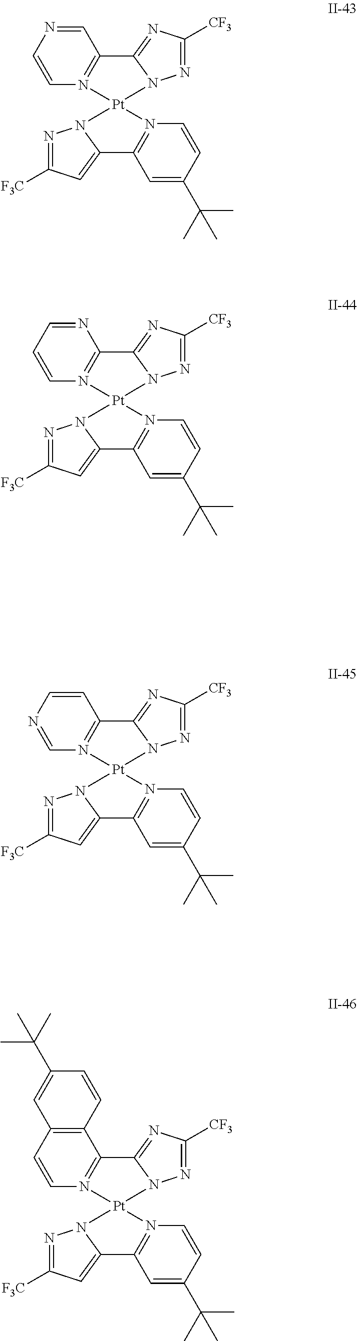

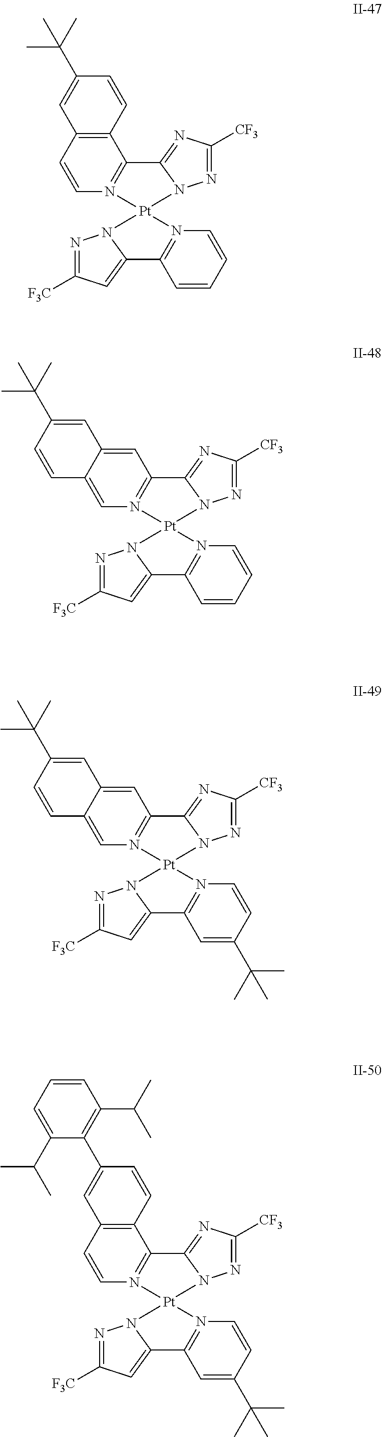

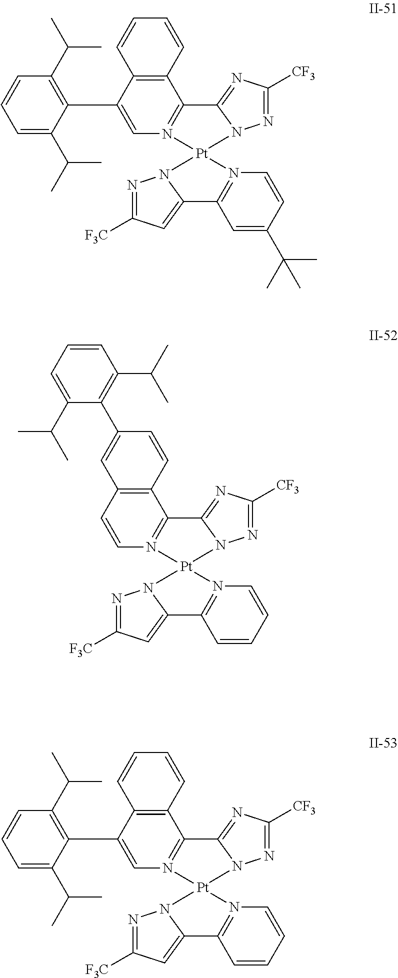

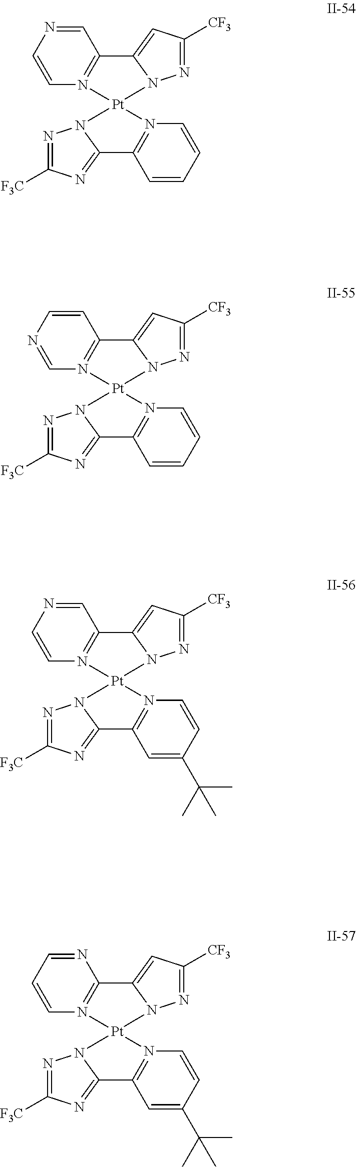

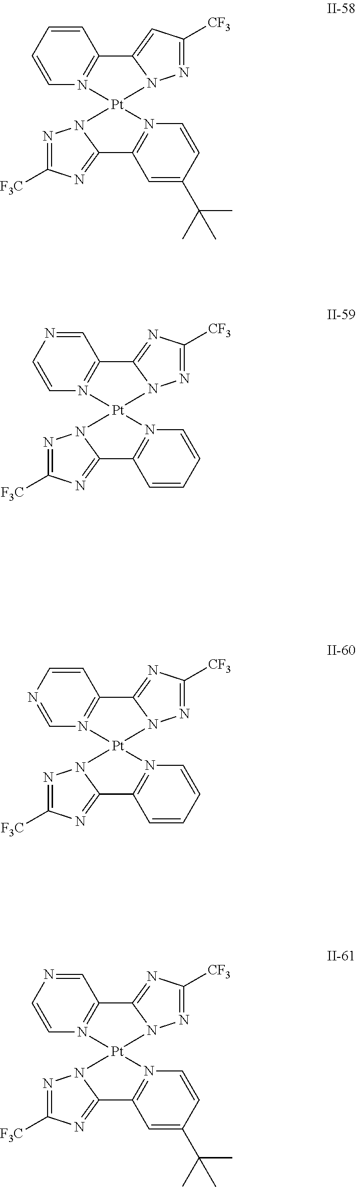

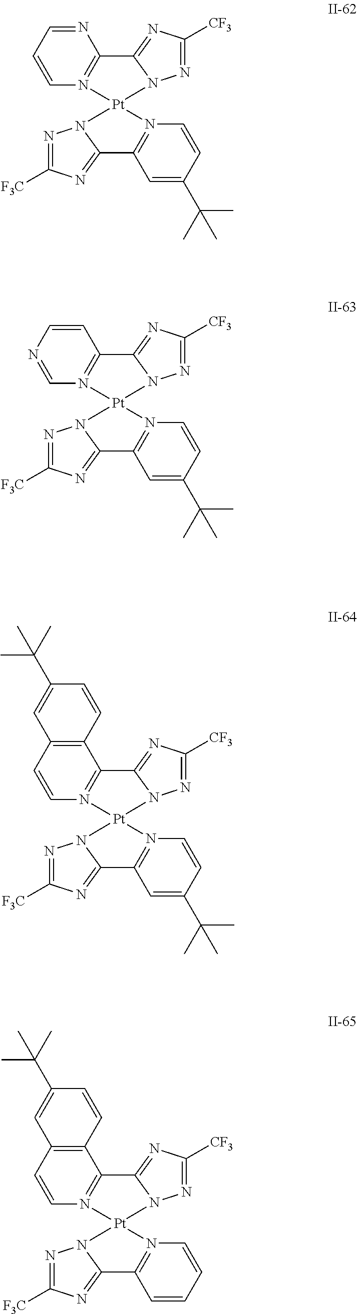

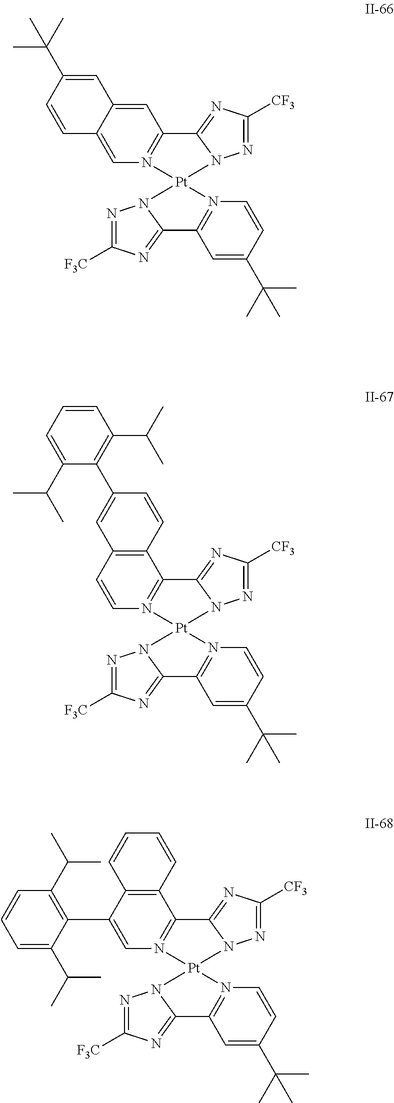

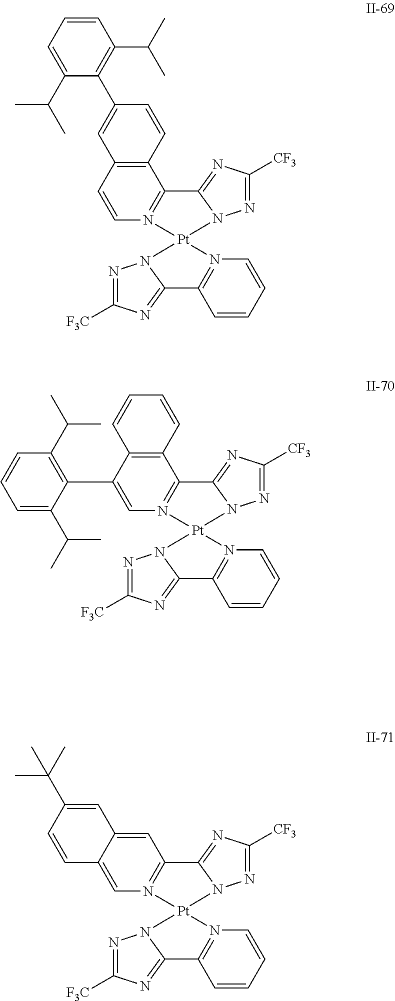

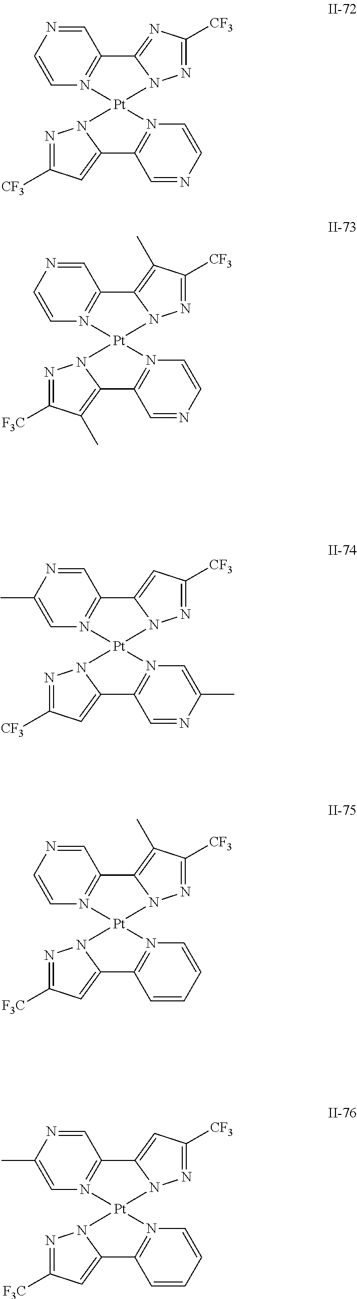

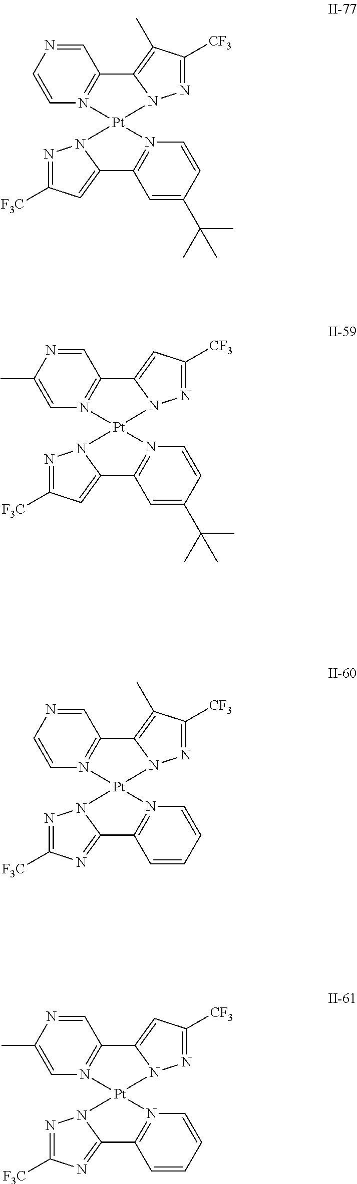

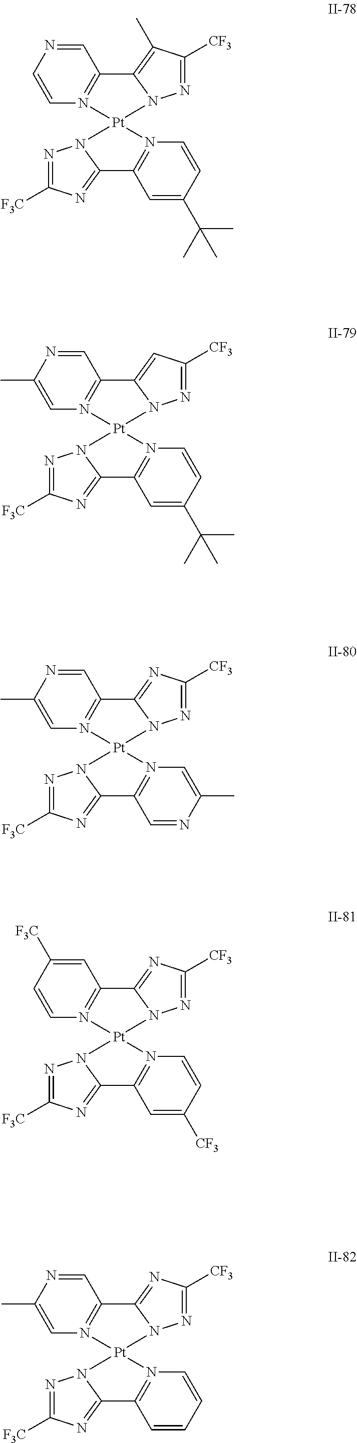

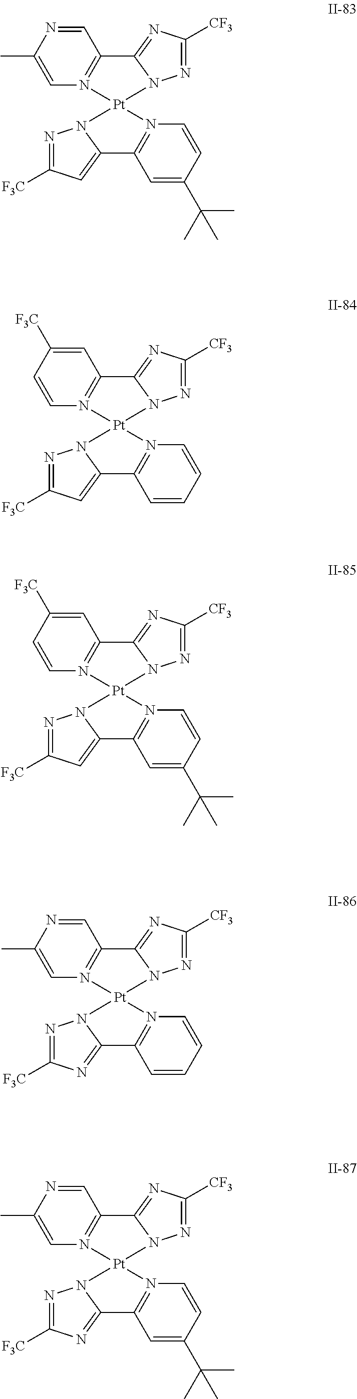

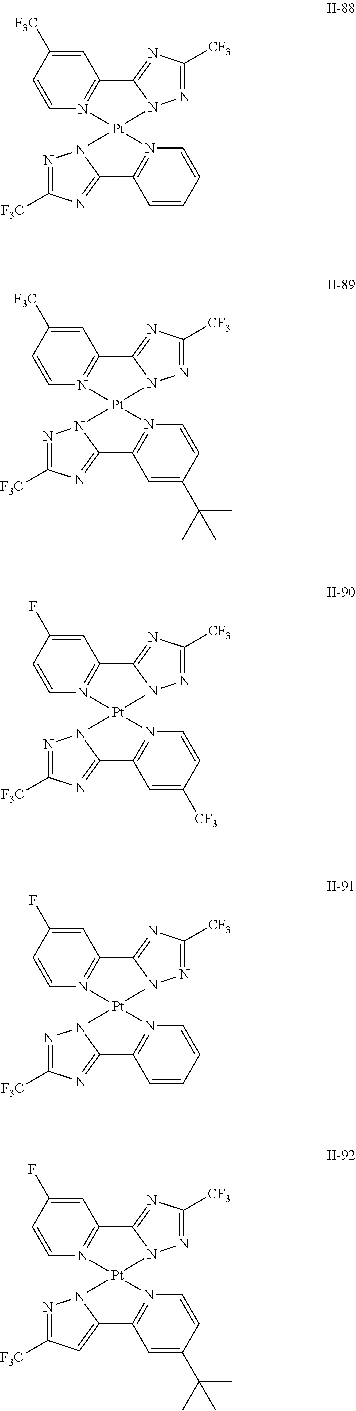

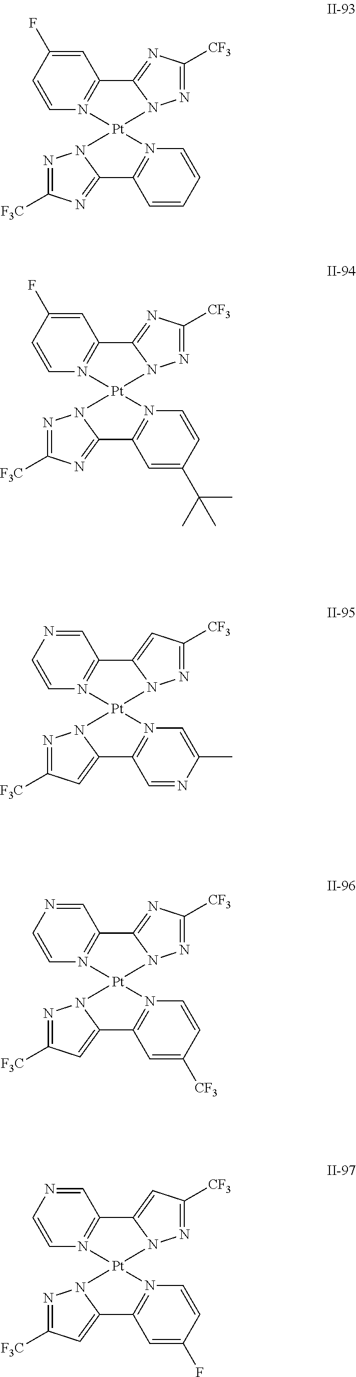

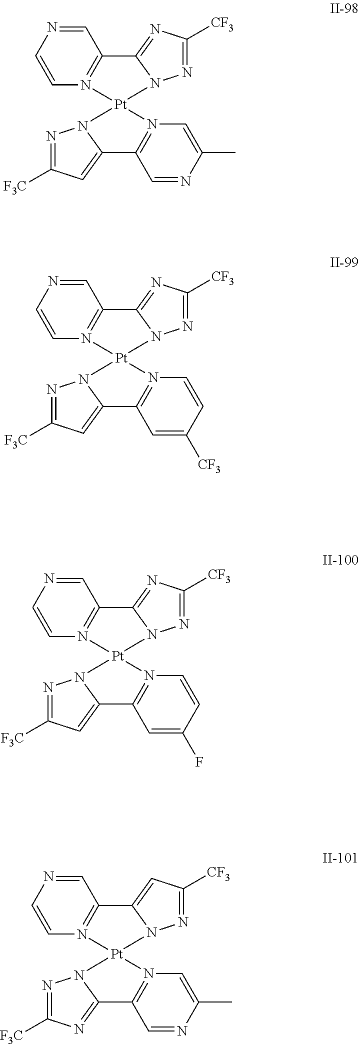

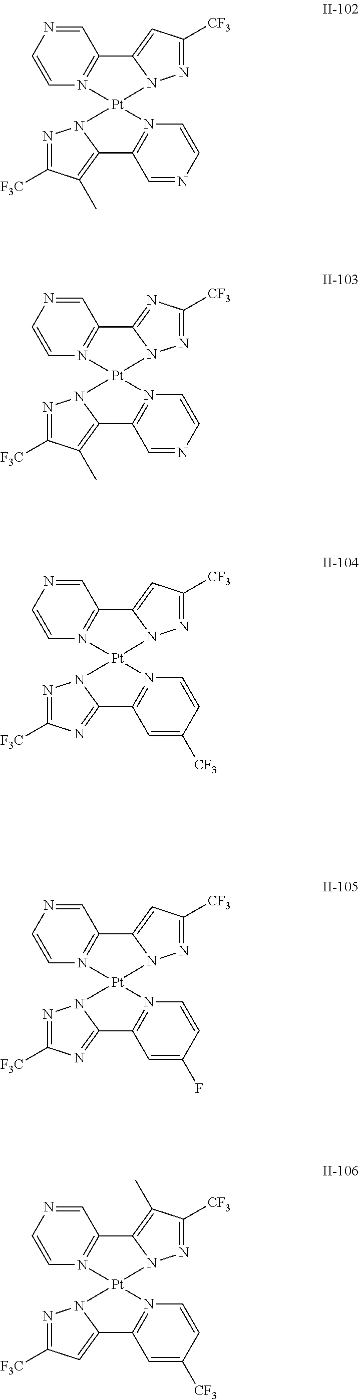

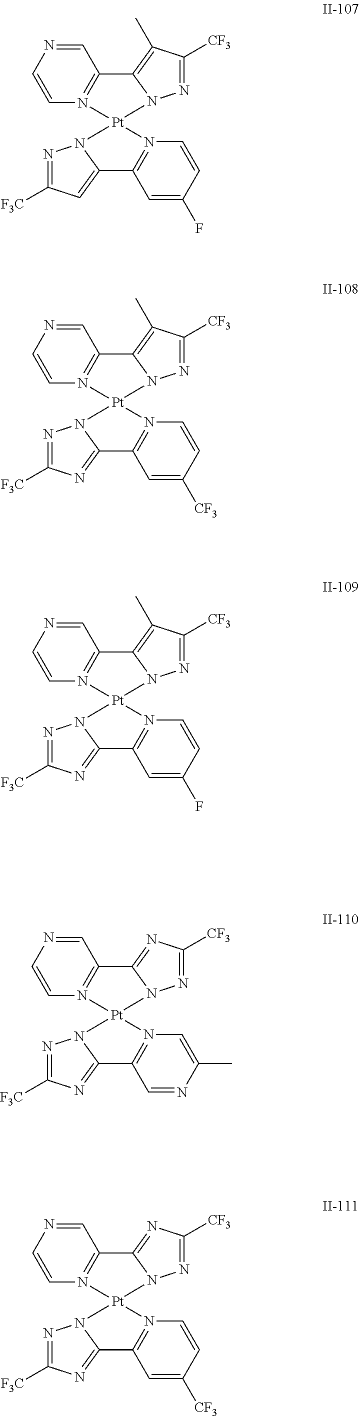

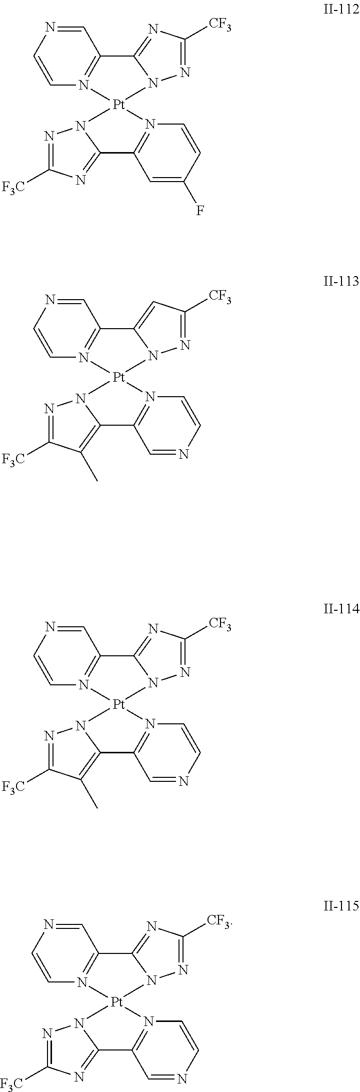

17. An organic light-emitting diode, comprising two electrodes and a light-emitting layer disposed between the two electrodes, wherein the light-emitting layer comprises the platinum complex in claim 1.
